(19) United States
(12) Patent Application Publication
(10) Pub. No.: US 2025/0287743 A1
(43) Pub. Date: Sep. 11, 2025

(54) Phosphor-Converted Red LEDs and Color-Tunable Multi-LED Lighting Devices

(71) Applicant: Bridgelux, Inc., Fremont, CA (US)

(72) Inventors: Yi-Qun Li, Danville, CA (US); Jingqiong Zhang, Xiamen City (CN); Jungang Zhao, Suzhou (CN)

(21) Appl. No.: 19/220,785

(22) Filed: May 28, 2025

Related U.S. Application Data
(63) Continuation-in-part of application No. 18/508,158, filed on Nov. 13, 2023.
Application No. 18/508,158 is a continuation of application No. 18/306,780, filed on Apr. 25, 2023, now Pat. No. 11,817,531.
Application No. 18/306,780 is a continuation-in-part of application No. PCT/US2023/060694, filed on Jan. 13, 2023.
Application No. PCT/US2023/060694 is a continuation of application No. PCT/CN2022/120875, filed on Sep. 23, 2022.
(60) Provisional application No. 63/299,408, filed on Jan. 13, 2022.

(30) Foreign Application Priority Data
Sep. 23, 2022 (WO) PCT/CN2022/120875

(51) Int. Cl. H10H 20/851; C09K 11/02; C09K 11/61; C09K 11/77; H01L 25/075

(52) U.S. Cl. CPC H10H 20/8513; C09K 11/02; C09K 11/617; C09K 11/77342; C09K 11/77348; H01L 25/0753

(57) ABSTRACT

A light emitting device comprising: at least one first LED for generating red light; at least one second LED for generating green light; at least one third LED for generating blue light; at least one fourth LED for generating light of a CCT in a range from 1800K to 5000K; and first package and a second package that in combination comprise the at least one first LED, the at least one second LED, the at least one third LED, and the at least one fourth LED, and wherein the at least one first LED comprises a phosphor-converted LED comprising a narrowband red phosphor with a FWHM less than 55 nm.

### CROSS REFERENCE TO RELATED APPLICATIONS

This application is a Continuation-In-Part application of U.S. application Ser. No. 18/508,158, filed Nov. 13, 2023, entitled “Phosphor-Converted Red LEDs and Color-Tunable Multi-LED Lighting Devices”, which is itself a Continuation of U.S. application Ser. No. 18/306,780, filed Apr. 25, 2023, entitled “Phosphor-Converted Red LEDs and Color-Tunable Multi-LED Lighting Devices”, which is itself a Continuation-In-Part bypass application of PCT application No. PCT/US2023/060694, filed Jan. 13, 2023, entitled “Phosphor-Converted Red LEDs and Color-Tunable Multi-LED Lighting Devices” which claims the benefit of priority to: (i) International Patent Application PCT/CN2022/120875, filed Sep. 23, 2022, entitled “Phosphor-Converted Red LEDs and Color-Tunable Multi-LED Packaged Light Emitting Devices” and (ii) U.S. Provisional application No. 63/299,408, filed Jan. 13, 2022, entitled “Phosphor-Converted Red LEDs”, each of which are hereby incorporated by reference in their entirety.

### FIELD OF THE INVENTION

A first aspect of the invention relates generally to Phosphor-Converted (PC) Color LEDs that generate light of a selected color. More particularly, embodiments of the invention concern Phosphor-Converted Red LEDs (PC Red LEDs) for generating narrowband red light. Another aspect of the invention concerns color-tunable multi-LED (Light Emitting Diode) lighting devices that can generate light with a color temperature from 2200K to 6500K and optionally light of colors from red to blue. More particularly, though not exclusively, the invention concerns color-tunable multi-LED lighting devices and packaging arrangements that utilize PC Red LEDs.

### BACKGROUND OF THE INVENTION

Phosphor-Converted Color LEDs (Light Emitting Diodes), also known as “PC Color LEDs”, typically comprise a blue LED chip and a phosphor (photoluminescence) material that converts substantially all of the excitation light generated by the LED chip to light of a selected color such as, for example, green, yellow, orange or red through a process of photoluminescence wavelength conversion. Since all light generated by the LED chip is converted to light of a selected color, such PC Color LEDs can be referred to as Fully Phosphor-Converted (FPC) Color LEDs. PC Color LEDs are to be contrasted with PC White LEDs in which there is only partial conversion of blue light generated by the LED chip, with the remainder of the blue light contributing to the final white light emission product. Light produced by a PC Color LED is typically broadband and has a FWHM (Full Width at Half Maximum) of 70 nm to 120 nm depending on the phosphor composition. The color (peak emission wavelength) of light generated by a PC Color LED depends on the phosphor material composition.

PC Color LEDs are to be contrasted with Direct-Emitting “Color LEDs” that directly generate substantially monochromatic light (FWHM≈20 to 25 nm) without photoluminescence (phosphor) wavelength conversion, with the color of the light being determined by the semiconductor material system of the LED chip. For example, Direct-Emitting Green LEDs use a InGaN-based (indium gallium nitride) LED chip, Direct-Emitting Red LEDs use an AlInGaP-based (aluminum indium gallium phosphide) LED chip, and Direct-Emitting Blue LEDs use an InGaN-based (indium gallium nitride) LED chip.

Due to their narrowband emission characteristics, Direct-Emitting red, green and blue Color LEDs find particular utility in RGB (Red Green Blue) systems, such as, for example, display backlights, for improving the color gamut of the display and color-tunable multi-LED packages (multi-LED packaged lighting devices) for general lighting. Current color-tunable multi-LED lighting devices typically contain red, green, and blue Direct-Emitting “Color LED” chips.

An example of a known color-tunable multi-LED packaged lighting device (Surface Mount Device—SMD) is shown in FIGS. 1A and 1B in which FIG. 1A shows a top view and FIG. 1B shows a sectional side view through A-A of the multi-LED package. The known multi-LED device 1 comprises a lead frame 2 for providing power to the red, green and blue direct-emitting LED chips 3R, 3G, 3B. A housing 4 is molded onto the lead frame and comprises a single cavity (recess) 5 (e.g., circular in shape). The red, green, and blue LED direct-emitting LED chips 3R, 3G, 3B are mounted on the floor of the cavity 5 and electrically connected to the lead frame 2. To protect the LED chips 3 from the external environment, the cavity 5 is typically filled with a light-transmissive encapsulant 6 such as a silicone material. Portions of the lead frame 2 extend laterally to the outside edges of the housing 4 and form respective electrical terminals 7R, 7G, 7B, 8R, 8G, 8B along opposing edges and base of the package allowing electrical power to be independently (individually) applied to the anode and cathode of each of the red, green and blue direct-emitting LED chips 3R, 3G, 3B. PC white LEDs are to be contrasted with Direct-Emitting Color LED chips, wherein PC white LEDs comprise a Direct-Emitting blue LED chip and a photoluminescence material, typically a phosphor material, that converts a portion blue excitation light generated by the LED chip, with the remainder of the blue light contributing to the final white emission product. The phosphor material can be incorporated in a light-transmissive encapsulant used to fill the cavity 5, for example.

A disadvantage of multi-LED lighting devices based on Direct-Emitting Color LEDs, however, is that, since they are based on different semiconductor material systems, each Color LED typically has different characteristics relating to thermal stability, ageing characteristics, drive requirements etc. As a result of these different characteristics, the light output of Red, Green and Blue LEDs will change differently to one another with temperature and time. The color composition of light generated by an RGB system based on Color LEDs will consequently change with temperature and time and such RGB systems may employ complex drive circuitry to compensate for these differing characteristics which can lead to additional cost during manufacture and maintenance. In contrast, PC Color LEDs eliminate the need for such measures since they are all based on blue LED chips with the same semiconductor material and have the same drive requirements, thermal stability etc.

Current PC Red LEDs typically use broadband red nitride phosphors and have a peak emission wavelength from 620 nm to 630 nm. In many applications, including, for example, display backlighting, brake lights and turn signals for vehicles, traffic signals, emergency vehicle lights etc., it is desirable if they could generate narrowband red light with a FWHM comparable with, or shorter than, that of direct-emitting Color LEDs (FWHM≈20 to 25 nm).

Narrowband red phosphors such as, for example, manganese-activated fluoride-based phosphors (narrowband red fluoride phosphors) such as K₂SiF₆:Mn⁴⁺ (KSF), K₂TiF₆: Mn⁴⁺ (KTF), and K₂GeF₆: Mn⁴⁺ (KGF) have a very narrow red emission spectrum (Full Width at Half Maximum of less than 10 nm for their main emission line spectrum) which makes them highly desirable for attaining high brightness and luminous efficacy in PC White LEDs (about 25% brighter than broadband red phosphors such as europium-activated red nitride phosphor materials such as CASN-CaAlSiN₃:Eu). While narrowband red fluoride phosphors appear on the face of it to be an ideal choice for PC Red LEDs, there are drawbacks that make their use in PC Red LEDs challenging. For example, the absorption efficiency of narrowband red fluoride phosphors is substantially lower (typically about a tenth) than that of red nitride phosphors currently used in PC Red LEDs. Thus, to attain full conversion of blue light to red light would require 5 to 20 times a greater amount of usage of narrowband red fluoride phosphor compared with the usage amount of red nitride phosphor. Such an increase in the amount of overall phosphor usage would significantly increase the cost of manufacture and particularly since narrowband red fluoride phosphors are significantly more expensive than europium-activated red nitride phosphors (e.g., at least five times more expensive) making them prohibitively expensive for use in PC Red LEDs.

Moreover, it is found that the very low absorption efficiency of narrowband red fluoride phosphors can result in unconverted blue light generated by the LED chip ending up in the emission product, so called “blue pass through”, that reduces the “color purity” of the red-light emission. While “blue pass through” may be acceptable in white light systems, such as, for example, display backlighting, where blue light is a constituent component of the white light, for applications requiring a “pure red” (substantially monochromatic) light—“blue pass through” will degrade the color purity of the red light and is, therefore, highly undesirable.

Another problem with utilizing, in terms of photoluminescence material, only narrowband red fluoride phosphors is that, while they provide a narrowband red emission, they suffer from readily reacting with water or moisture causing damage to the dopant manganese which leads to a reduction, or loss, of the photoluminescence emission (i.e., quantum efficiency) of the phosphor. Moreover, the reaction of the fluoride-based compound with water can generate very corrosive hydrofluoric acid that can react with LED packaging material, such as for example bond wires, thereby leading to premature device failure.

The present invention intends to address and/or overcome the limitations discussed above by presenting new designs and methods not hitherto contemplated nor possible by known constructions. More particularly, although not exclusively, embodiments of the invention concern improvements relating to increasing the luminous efficacy of color tunable multi-LED lighting devices, increasing color purity of PC red LEDs by reducing “blue pass through”; reducing narrowband red fluoride phosphor usage; and isolating narrowband red fluoride phosphor from water/moisture in the surrounding environment through innovative phosphor packaging structures that effectively improve the blue absorption efficiency of narrowband red fluoride phosphors.

### SUMMARY OF THE INVENTION

A first aspect of the invention relates generally to PC Red LEDs utilizing InGaN-based blue emitting LEDs that contain a combination of a narrowband red fluoride phosphor (e.g., manganese-activated fluoride narrowband red phosphor) and a red phosphor having a higher absorption efficiency such as, for example, a broadband red phosphor. The inclusion of a broadband red phosphor having a higher absorption efficiency than the narrowband red fluoride phosphor converts blue light that is not converted by the narrowband red fluoride phosphor to red light and substantially reduces, or even eliminates, blue pass through and improves color purity. It could be said that the inclusion of the red phosphor having a higher absorption efficiency than the narrowband red fluoride phosphor compensates for the lower absorption efficiency of the narrowband red fluoride phosphor in this way. The combination of a narrowband red fluoride phosphor (e.g., manganese-activated fluoride narrowband red phosphor) and a red phosphor having a higher absorption efficiency such as, for example, a broadband red phosphor thus providing a synergistic effect of at least improved color purity, for instance.

The broadband red phosphor and the narrowband red fluoride phosphor can be provided in the same (single) layer, for example as a mixture. This may improve the ease by which the PC Red LEDs can be manufactured by simplifying the process, thus reducing manufacturing costs and time.

In other embodiments, the broadband red phosphor and narrowband red fluoride phosphor can each be provided in a respective layer with the layer containing the narrowband red fluoride phosphor being disposed in closer proximity to the LED chip than the layer containing the broadband red phosphor. Such an arrangement can effectively increase the absorption efficiency of the narrowband red fluoride phosphor and substantially reduces usage amount of the narrowband red fluoride phosphor. The layer containing the narrowband red fluoride phosphor can be in direct contact with at least one of the light emitting faces of the LED chip. The layer containing the broadband red phosphor can be in direct contact with and may completely cover (encapsulate) the layer containing the narrowband red fluoride phosphor. Such a configuration/arrangement can provide environmental protection to the layer containing the narrowband red fluoride phosphor and improve overall device reliability.

According to an aspect of the invention, there is provided a red-light emitting device comprising: an LED chip having a peak emission from 400 nm to 500 nm; and a photoluminescence material comprising a narrowband red fluoride phosphor and a broadband red phosphor.

In embodiments, the narrowband red fluoride phosphor and broadband red phosphor may be constituted as a single-layer photoluminescence structure. The phosphors can be provided in the same layer, for instance. The phosphors can be provided in a single layer, typically as a mixture, and the layer may be in direct contact with the LED chip. In this specification, “direct contact” means without an air gap or photoluminescence material containing layer. It may be that the device comprises a light transmissive layer disposed between the photoluminescence material containing layer and the LED chip. The light transmissive layer provides passivation to the LED chip and provides a barrier to the LED chip from the possible effects of the narrowband red fluoride phosphor. Such an arrangement can improve device reliability.

To further improve the absorption efficiency of the narrowband red fluoride phosphor, the narrowband red fluoride phosphor can be disposed in closer proximity to the LED chip than the broadband red phosphor. By locating the narrowband red fluoride phosphor closer to the LED chip this effectively increases the absorption efficiency of the narrowband red fluoride phosphor as it is not having to compete with the broadband red phosphor for blue photons.

In embodiments, the red-light emitting device may comprise a double-layer photoluminescence structure comprising a first layer containing the narrowband red fluoride phosphor disposed adjacent to the LED chip and a second layer containing the broadband red phosphor material that is disposed on, and covers, the first layer. The second layer can partially or completely cover the first layer.

Compared with a single-layer photoluminescence structure, a double-layer photoluminescence structure having a first layer containing, in terms of photoluminescence material, only, or substantially only (at least 90 wt % for example), narrowband red fluoride phosphor that is covered by the second layer can provide a number of benefits, including but not limited to: (1) a substantial reduction in narrowband red fluoride phosphor usage (at least 40% reduction), (2) the second layer provides environmental protection to the first layer thereby reducing the chance of water/moisture reaching and degrading the narrowband red fluoride phosphor, and (3) substantially reduce, or even eliminate “blue pass through” leading to better color purity of red light generated by the device.

The first layer can be in direct contact with at least one light emitting face (surface) of the LED chip.

The second layer can be in direct contact with the first layer.

To further reduce narrowband red fluoride phosphor usage, the first layer can further comprise particles of a light scattering material such as for example particles of zinc oxide; silicon dioxide; titanium dioxide; magnesium oxide; barium sulfate; aluminum oxide and combinations thereof.

The narrowband red fluoride phosphor can include one, or more, of K₂SiF₆:Mn⁴⁺, K₂GeF₆: Mn⁴⁺, and K₂TiF₆:Mn⁴⁺, or may be selected from the group consisting of K₂SiF₆:Mn⁴⁺, K₂GeF₆:Mn⁴⁺, and K₂TiF₆:Mn⁴⁺.

To reduce the FWHM of the red-light emission product of the device, the peak emission wavelength of the broadband red phosphor can be selected to be substantially the same as the peak emission wavelength of the narrowband red fluoride phosphor. In embodiments, the peak emission wavelength of the broadband red phosphor can be within 5 nm of the peak emission wavelength of the narrowband red fluoride phosphor. The broadband red phosphor may have a peak emission wavelength from 620 nm to 640 nm and can comprise a europium activated nitride phosphor of general composition AAlSiN₃:Eu²⁺ where A is at least one of Ca, Sr or Ba.

In embodiments, the red-light emitting device generates red light with a color purity of at least 90% and a FWHM of less than 30 nm, a FWHM of less than 20 nm, or a FWHM of less than 10 nm.

According to another aspect of the invention, there is contemplated a red-light emitting device that comprises: an LED flip chip having a peak emission from 400 nm to 500 nm; and a photoluminescence material in direct contact with at least one light emitting face of the LED flip chip, wherein the photoluminescence material comprises a narrowband red fluoride phosphor and a broadband red phosphor. In this specification, “direct contact” means without an air gap or photoluminescence material containing layer. In embodiments, the device may comprise a light transmissive layer disposed between the photoluminescence containing layer and the LED chip. The light transmissive layer provides passivation to the LED chip and provides a barrier to the LED chip from the possible effects of the narrowband red fluoride phosphor.

In embodiments, the narrowband red fluoride phosphor and broadband red phosphor may be constituted as a single-layer photoluminescence structure. The phosphors can be located (contained) in the same layer. The phosphors can be located (contained) in a single layer, typically as a mixture, and the layer may be in direct contact with the at least one light emitting face of the LED flip.

In embodiments, the narrowband red fluoride phosphor and broadband red phosphor may be constituted as a double-layer photoluminescence structure. In one arrangement, the red-light emitting device comprises a first layer containing the narrowband red fluoride phosphor that is adjacent to the LED chip, and a second layer containing the broadband red phosphor material that is on the first layer. The first layer can be in direct contact with at least one light emitting face (surface) of the LED flip chip, and the second layer can be in direct contact with the first layer.

Phosphor-Converted Red LEDs (PC Red LEDs) in accordance with embodiments of invention find utility as a red-light source in light emitting devices (lighting devices) such as, for example, RGB (Red Green Blue) Multi-LED lighting devices comprising a Red LED, Green LED, and Blue LED. RGB light emitting devices find utility in color-tunable light sources.

Other aspects of the invention relate generally to color-tunable multi-LED (Light Emitting Diode) lighting devices that can, preferably, generate light with a color temperature from 2200K to 6500K and optionally light of colors from red to blue. More particularly, though not exclusively, embodiments concern multi-LED lighting devices that utilize PC Red LEDs comprising a narrowband red phosphor such as K₂SiF₆:Mn⁴⁺, K₂GeF₆:Mn⁴⁺, or K₂TiF₆:Mn⁴⁺ or PC Red LEDs as described herein. According to one aspect a multi-LED lighting device comprises four LEDs: a Red LED, a Green LED, a Blue LED and a White LED. The lighting device may comprise a packaged lighting device comprising a package for housing the four LEDs. The Red, Green, Blue and White LEDs may comprise CSP (Chip Scale Packaged) LEDs comprising LED flip chips. In embodiments where the LEDs comprise CSP LEDs, the lighting device may comprise a substrate, such as a circuit board, on which the LEDs are provided. Such a packaging arrangement is termed a COB (Chip On Board) arrangement.

According to an aspect of the invention, there is contemplated a lighting device comprising: a first LED having a wavelength of maximum emission intensity (peak emission wavelength) from 620 nm to 640 nm (i.e. orange to red); a second LED having a wavelength of maximum emission intensity (peak emission wavelength) from 500 nm to 565 nm (i.e. green); a third LED having a wavelength of maximum emission intensity (peak emission wavelength) from 430 nm to 480 nm (i.e. violet to blue); and a fourth LED for generating light comprising a CCT in a range from 1800K to 5000K; wherein the first LED comprises a phosphor-converted LED that comprises a first LED chip having a wavelength of maximum emission intensity (peak emission wavelength) from 400 nm to 480 nm, and a narrowband red phosphor with a FWHM less than 55 nm; and wherein light generated by the device comprises a combination of light generated by the first, second, third, and fourth LEDs and wherein a CCT of light generated by the device is tunable over a range by independently controlling power to the first, second, third, and fourth LEDs.

The CCT of light generated by the device is tunable over a range of CCTs, and it may be that a CCT of light generated by the device is tunable in a range from 1800K to 8000K. It will be understood that the CCT may be anywhere within the range from 1800K to 8000K; for instance, the range may be 2200K to 6500K, or a different range falling within the range of 1800K to 8000K. It may be that light generated by the device has a CRI Ra from 80 to 98.

The narrowband red phosphor may comprise at least one of: K₂SiF₆:Mn⁴⁺ K₂GeF₆:Mn⁴⁺, or K₂TiF₆:Mn⁴⁺.

The first LED may further comprise a broadband red phosphor. The narrowband red phosphor and broadband red phosphor may be located (contained) in a single layer. Alternatively, the narrowband red phosphor can be located (contained) in a first layer and the broadband red phosphor can be located (contained) in a second layer. It may be that the first layer is in direct contact with a light emitting face of the first LED chip and the second layer is in direct contact with the first layer.

The first LED may generate light with a color purity of least 90%.

The second LED may comprise a phosphor-converted LED comprising a second LED chip having a wavelength of maximum intensity from 400 nm to 480 nm (i.e., violet to blue), and a green phosphor.

The third LED may comprise a Direct-Emitting Blue LED.

The fourth LED may comprise a fourth LED chip having a wavelength of maximum intensity from 400 nm to 480 nm, and green to red phosphors.

It may be that light generated by the device has a chromaticity that is within 0.006 Δuv, preferably 0.003 Δuv, of the black body locus over the range of CCTs, for example from 1800K to 6500K. It may be that light generated by the device has a CRI Ra from 80 to 98. In this specification, “chromaticity” of light, “color of light”, and “color point” of light may be used interchangeably and refer to the chromaticity/color of light as represented by chromaticity coordinates on a CIE 1931 chromaticity diagram. Δuv (Delta uv) is a metric that quantifies how close light of a given color temperature is to the black body locus. As is known, Δuv is the Euclidean difference of chromaticity coordinate uv between a test light source to the closest point on the black body locus and is defined in ANSI_NEMA_ANSLG C78.377-2008: American National Standard for electric lamps—Specifications for the Chromaticity of Solid State Lighting Products. Δuv is on the 1976 CIE u, v chromaticity diagram, a measure of the distance of the color point of light of a given CCT (Correlated Color Temperature) from the black body locus (Planckian locus of black body radiation) along the iso-CCT line (Lines of Constant Color Temperature). A positive Δuv value indicates that the color point is above the black body locus (i.e., on a 1931 CIE x, y chromaticity diagram CIE y is greater than the CIE y value of the black body locus) with a yellowish/greenish color shift from the black body locus. A negative value the color point is below the black body locus (i.e., on a 1931 CIE x, y chromaticity diagram CIE y is less than the CIE y value of the black body locus) with a pinkish color shift from the black body locus.

In embodiments, at least one of the first LED, second LED, third LED or fourth LED may comprise an LED flip chip or an LED chip comprising a plurality of serially connected LEDs (LED junctions). An LED chip having multiple LED junctions has a greater forward drive voltage and can be beneficial where the lighting device is operating at line voltage of 110 to 240V.

It may be that the lighting device comprises a package comprising a lead frame; and a housing comprising a first cup (recess) having the first LED, a second cup (recess) having the second LED, a third cup (recess) having the third LED, and a fourth cup (recess) having the fourth LED; and wherein the lead frame comprises a common cathode electrode to each cup and a respective anode electrode to each cup.

It may be that the lighting device comprises a package comprising a lead frame; and a housing comprising a first cup having the first LED, a second cup having the second LED, a third cup having the third LED, and a fourth cup having the fourth LED; and wherein the lead frame comprises a respective cathode electrode to each cup and a respective anode electrode to each cup. It may be that each cup comprises an anode terminal connected to the anode electrode and a cathode terminal connected to the cathode electrode and wherein the anode and cathode terminals for each recess are located on opposing edges of the housing across from one another.

It may be that the at least one of the first LED, second LED, third LED and fourth LED comprises a chip scale packaged LED.

According to another aspect, a lighting device comprises: a first LED; a second LED; a third LED; and a fourth LED of different chromaticity, wherein light generated by the device comprises a combination of light generated by the first LED, second LED, third LED, and fourth LED and wherein a CCT of light generated by the device is tunable in a range from 1800K to at least 6500K by independently controlling power to the first, second, third, and fourth LEDs, wherein a chromaticity of light generated by the device is within 0.006 Δuv, preferably 0.003 Δuv, of the black body locus, and wherein at least one of the LEDs comprises narrowband red phosphor with a FWHM of less than 55 nm.

The narrowband red phosphor may comprise at least one of K₂SiF₆:Mn⁴⁺, K₂GeF₆:Mn⁴⁺, and K₂TiF₆:Mn⁴⁺.

In embodiments, the first LED has a wavelength of maximum intensity from 620 nm to 640 nm (i.e., orange to red); the second LED has a wavelength of maximum intensity from 500 nm to 565 nm (i.e., green); the third LED has a wavelength of maximum intensity from 430 nm to 480 nm (i.e., violet to blue): and the fourth LED is for generating light with a CCT of at least 1800K.

According to a further aspect, the invention provides a lighting arrangement comprising: a substrate (circuit board) and a plurality of lighting devices as defined herein mounted on the substrate. It may be that the lighting arrangement is a linear lighting device.

It may be that each of said lighting devices comprises: a first LED having a wavelength of maximum intensity from 620 nm to 640 nm; a second LED having a wavelength of maximum intensity from 500 nm to 565 nm; a third LED having a wavelength of maximum intensity from 430 nm to 480 nm; and a fourth LED for generating light comprising a CCT in a range from 1800K to 5000K; wherein the first LED comprises a phosphor-converted LED comprising a first LED chip having a wavelength of maximum intensity from 400 nm to 480 nm, and a narrowband red phosphor with a FWHM less than 55 nm; and wherein light generated by the device comprises a combination of light generated by the first, second, third, and fourth LEDs and a color or CCT of light generated by the device is tunable over a range by independently controlling power to the first, second, third, and fourth LEDs.

It may be that each of said lighting devices comprises: a first LED, second LED, third LED, and fourth LED for generating light of a different chromaticity, wherein light generated by the device comprises a combination of light generated by the first LED, second LED, third LED, and fourth LED and wherein a CCT of light generated by the device is tunable in a range of CCTs by independently controlling power to the first, second, third, and fourth LEDs, wherein a chromaticity of light generated by the device is within 0.006 Δuv of the black body locus, and wherein at least one of the LEDs comprises narrowband red phosphor with a FWHM of less than 55 nm.

It may be that the circuit board comprises a flexible circuit board.

According to an aspect, a multi-LED lighting device comprises at least three LEDs: a Red LED, a Green LED, and a White LED. The lighting device may comprise a packaged lighting device comprising a package for housing the at least three LEDs. The Red, Green, and White LEDs may comprise CSP (Chip Scale Packaged) LEDs comprising LED flip chips. In embodiments where the LEDs comprise CSP LEDs, the lighting device may comprise a substrate, such a circuit board, on which the LEDs are provided. Such a packaging arrangement is termed a COB (Chip On Board) arrangement.

According to an aspect of the invention, there is contemplated a lighting device comprising: a first LED having a peak emission wavelength from 620 nm to 640 nm; a second LED having a peak emission wavelength from 500 nm to 565 nm; and a third LED having a CCT of at least 1800K; wherein the first LED comprises a phosphor-converted LED that comprises an LED chip having a dominant wavelength from 400 nm to 480 nm, and a narrowband red phosphor with a FWHM less than 55 nm.

The narrowband red phosphor may comprise at least one of: K₂SiF₆:Mn⁴⁺, K₂GeF₆:Mn⁴⁺, and K₂TiF₆:Mn⁴⁺.

The first LED may further comprise a broadband red phosphor. The narrowband red phosphor and broadband red phosphor may be located (contained) in a single layer. Alternatively, the narrowband red phosphor can be located (contained) in a first layer and the broadband red phosphor can be located (contained) in a second layer.

The first LED may generate light with a color purity of least 90%.

The second LED may comprise a phosphor-converted LED comprising a second LED chip having a dominant wavelength from 400 nm to 480 nm (i.e., violet to blue), and a green phosphor.

The third LED may comprise a third LED chip having a dominant wavelength from 400 nm to 480 nm, and green to red phosphors and may generate light with a CCT from 1800K to 5000K.

The lighting device may comprise a packaged device or a COB device.

It may be that the lighting device comprises a package comprising a lead frame; and a housing comprising a first cup (recess) having the first LED, a second cup (recess) having the second LED, a third cup (recess) having the third LED, and a fourth cup (recess) having the fourth LED; and wherein the lead frame comprises a common cathode electrode to each cup and a respective anode electrode to each cup.

It may be that the lighting device comprises a package comprising a lead frame; and a housing comprising a first cup having the first LED, a second cup having the second LED, a third cup having the third LED, and a fourth cup having the fourth LED; and wherein the lead frame comprises a respective cathode electrode to each cup and a respective anode electrode to each cup. It may be that each cup comprises an anode terminal connected to the anode electrode and a cathode terminal connected to the cathode electrode and wherein the anode and cathode terminals for each recess are located on opposing edges of the housing across from one another.

It may be that the at least one of the first LED, second LED, and third LED comprises a chip scale packaged LED.

According to a further aspect, the invention provides a lighting device comprising: a substrate (circuit board) and a plurality of lighting devices as defined herein mounted on the substrate. It may be that the lighting device is a linear lighting device. The substrate may comprise a flexible circuit board.

According to an aspect of the invention, there is contemplated a light emitting device comprising: at least one first LED for generating red light; at least one second LED for generating green light; at least one third LED for generating blue light; at least one fourth LED for generating light of a CCT in a range from 1800K to 5000K; and a first package and a second package that in combination comprise the at least one first LED, the at least one second LED, the at least one third LED, and the at least one fourth LED, and wherein the at least one first LED comprises a phosphor-converted LED comprising a narrowband red phosphor with a FWHM less than 55 nm.

According to another aspect of the invention, there is envisaged a lighting arrangement comprising: a substrate and a plurality of light emitting devices, wherein each of the plurality of light emitting devices comprises: at least one first LED for generating red light; at least one second LED for generating green light; at least one third LED for generating blue light; at least one fourth LED for generating light of a CCT in a range from 1800K to 5000K; and a first package and a second package that in combination comprise the at least one first LED, the at least one second LED, the at least one third LED, and the at least one fourth LED, and wherein the at least one first LED comprises a phosphor-converted LED comprising a narrowband red phosphor with a FWHM less than 55 nm.

It may be that the choice of LED colors (red, green, blue, and/or white) in the first and second packages can be used to improve the thermal characteristics of the color tunable Multi-LED lighting device (of the light emitting device and/or lighting arrangement). For example, the choice of LED color may determine the power that needs to be provided to each package to generate light of a desired/nominal CRI Ra, for instance, for nominal CCTs ranging from 1800K to 6500K, for example. It may be that the percentage of power received by a 1^{st} LED package and a 2^{nd} LED package, of the total RGBW power received by the light emitting device, is attributable to which LED colors (i.e., the at least one first LED for generating red light, the at least one second LED for generating green light, the at least one third LED for generating blue light, and/or the at least one fourth LED for generating light of a CCT in a range from 1800K to 5000K) are contained in the 1^{st} and 2^{nd} packages.

In some embodiments, for instance, it may be that the thermal characteristics of one light emitting device (light emitting device A, for example) are found to be superior to those of another light emitting device (light emitting device B, for example) due to the color choice of LEDs in the first and second LED packages used therein. For instance, the power to (received by) the 1^{st} and 2^{nd} packages of light emitting device A may be more balanced, that is the total device power for each color temperature over the full range of CCTs may be shared substantially equally between the 1^{st} and 2^{nd} LED packages. In such an arrangement, since it may be desirable that each of the LED packages be capable of dissipating heat of about the same amount (up to a similar/same mW value, for instance), the same packages can be used for the 1^{st} and 2^{nd} LED packages. The same package may be in terms of the size of lead frame, for instance. That is packages that have the same size lead frame may be utilized in the manufacture of the light emitting device and/or lighting arrangement. This is advantageous in that it significantly reduces complexity of manufacturing, thereby reducing overall manufacturing costs, material costs, and assembly time and costs of the light emitting device and/or lighting arrangement.

Particularly beneficial power distribution and heat dissipation may be had in light emitting devices in which, for example, the 1^{st} package comprises a Red and Green LED, and in which the 2^{nd} package comprises a Blue and White LED. The inventors have identified, therefore, that the provision of a light emitting device and/or lighting arrangement in which the 1^{st} package comprises a Red and Green LED, and in which the 2^{nd} package comprises a Blue and White LED exhibits particularly advantageous benefits by way of enhanced thermal management, reduced manufacturing costs due to the sufficiency of substantially equally sized smaller 1^{st} and 2^{nd} LED packages/lead frames to provide the desired performance.

It may be that the first package comprises the first and second LEDs and the second package comprises the third and fourth LEDs.

The first package may comprise the first and fourth LEDs and the second package may comprise the second and third LEDs.

It may be that at least one of the first and second packages comprise: two cups for receiving a respective LED; or one cup for receiving at least two LEDs.

The second LED may comprise a phosphor-converted LED comprising a green phosphor.

The narrowband red phosphor may be selected from the group consisting of: K₂SiF₆:Mn⁴⁺, K₂GeF₆:Mn⁴⁺, and K₂TiF₆: Mn⁴⁺.

The first LED may further comprise a broadband red phosphor.

The narrowband red phosphor and the broadband red phosphor may be constituted in a single layer, or the narrowband red phosphor and the broadband red phosphor may be constituted in a respective layer.

The first LED may be for generating light with a color purity of least 90%.

It may be that at least one of the first LED, second LED, third LED or fourth LED comprises an LED flip chip.

The circuit board may comprise a flexible circuit board.

### BRIEF DESCRIPTION OF THE DRAWINGS

These and other aspects and features of the present invention will become apparent to those ordinarily skilled in the art upon review of the following description of specific embodiments of the invention in conjunction with the accompanying figures, wherein:

FIGS. 1A and 1B are schematic representations of a known tunable Surface Mount multi-LED packaged lighting device in which FIG. 1A shows a top view and FIG. 1B shows a sectional side view through A-A;

FIG. 2 is a schematic sectional side view of a packaged single-layer red-light emitting device in accordance with an embodiment of the invention;

FIG. 3 is a schematic sectional side view of a packaged single-layer red-light emitting device in accordance with an embodiment of the invention;

FIG. 4 is a schematic sectional side view of a packaged double-layer red-light emitting device in accordance with an embodiment of the invention;

FIG. 5 is a schematic sectional side view of a packaged double-layer red-light emitting device in accordance with an embodiment of the invention;

FIG. 6 is a schematic sectional side view of a CSP (Chip Scale Packaged) double-layer red-light emitting device in accordance with an embodiment of the invention;

FIG. 7 is a schematic sectional side view of a CSP (Chip Scale Packaged) double-layer red-light emitting device in accordance with an embodiment of the invention;

FIG. 8 is a CIE 1931 chromaticity diagram illustrating calculation of color purity and dominant wavelength of light of a given chromaticity (color);

FIGS. 9A and 9B are measured spectra, intensity (a.u.) versus wavelength (nm), for (i) a comparative packaged red light emitting device Com.1 containing broadband red phosphor (thick solid line), (ii) a comparative packaged red light emitting device Com.2 containing narrowband red fluoride phosphor (thin solid line), (iii) a packaged single-layer red light emitting device Dev. 1 in accordance with an embodiment of the invention (dashed line), and (iv) a packaged double-layer red light emitting device Dev. 2 in accordance with an embodiment of the invention (dotted line)—FIG. 9A shows the wavelength portion of the spectra for wavelengths from 550 nm to 700 nm (i.e. green to red region), and FIG. 9B shows the wavelength portion of the spectra for wavelengths from 400 nm to 600 nm (i.e. violet to yellow) and illustrates “blue pass through”;

FIG. 9C is a CIE 1931 chromaticity diagram illustrating the chromaticity (color) of light generated by (i) comparative packaged red light emitting device Com.1 (solid circle), (ii) comparative packaged red light emitting device Com.2 (cross), (iii) packaged single-layer red light emitting device Dev. 1 (solid triangle), (iv) packaged double-layer red light emitting device Dev. 2 (solid diamond), black body locus (dashed line), and chromaticity gamut boundary (solid line);

FIG. 10A is a schematic plan view of a color-tunable multi-LED packaged lighting device utilizing a CSP (Chip Scale Packaged) double-layer red-light emitting device in accordance with an embodiment of the invention;

FIG. 10B is a CIE 1931 chromaticity diagram illustrating the gamut of light that the color-tunable multi-LED packaged lighting device of FIG. 10A can generate;

FIG. 11 is a schematic plan view of a color-tunable multi-LED packaged lighting device utilizing a CSP (Chip Scale Packaged) double-layer red-light emitting device in accordance with an embodiment of the invention;

FIG. 12 is a schematic plan view of a color-tunable multi-LED packaged lighting device utilizing a packaged red-light emitting device in accordance with an embodiment of the invention;

FIGS. 13A to 13C are schematic representations of a color-tunable multi-LED packaged lighting device comprising a PC Red LED, a Green LED, a blue LED and a White LED in accordance with an embodiment of the invention in which FIG. 13A shows a top view, FIG. 13B shows a sectional side view through A-A, and FIG. 13C shows a sectional side view through B-B;

FIG. 13D is a CIE 1931 chromaticity diagram illustrating the gamut of light that the color-tunable multi-LED packaged lighting device of FIG. 13A to 13C can generate;

FIGS. 14A to 14C are schematic representations of a color-tunable multi-LED packaged lighting device comprising a CSP PC Red LED, a CSP PC Green LED, a blue LED flip chip and a CSP White LED in accordance with an embodiment of the invention in which FIG. 4A shows a top view, FIG. 14B shows a sectional side view through A-A, and FIG. 14C shows a sectional side view through B-B;

FIGS. 14D to 14F are schematic representations of a color-tunable multi-LED COB (Chip On Board) lighting device 1450 comprising a CSP PC Red LED, a CSP PC Green LED, a blue LED flip chip and a CSP White LED in accordance with an embodiment of the invention in which FIG. 14D shows a top view FIG. 14E shows a sectional side view through C-C and FIG. 14F shows a sectional side view through D-D;

FIG. 15A is a schematic top view of a color-tunable multi-LED packaged lighting device comprising a PC Red LED, a PC Green LED, and two PC Cool White (CW) LEDs in accordance with an embodiment of the invention;

FIG. 15B is a CIE 1931 chromaticity diagram illustrating the gamut of light that the color-tunable multi-LED packaged lighting device of FIG. 15A can generate;

FIG. 16 is a schematic representation of a color-tunable linear lighting device in accordance with an embodiment of the invention;

FIGS. 17A to 17C are measured characteristics for a color-tunable multi-LED packaged lighting device (Pack.1) comprising a PC Red LED (Red), a PC Green LED (Green), a blue LED (Blue) and a White LED (White) in which FIG. 17A shows spectra, normalized intensity (a.u.) versus wavelength (nm), for the PC Red LED (thick solid line), the PC Green LED (dashed dotted line), the Blue LED (dotted line) and the White LED (dashed line), FIG. 17B is a CIE 1931 chromaticity diagram illustrating the chromaticity (color) of light generated by the PC Red LED (square), the PC Green LED (diamond), the Blue LED (triangle), the White LED (cross), ANSI CCT center points (solid circle), color gamut of device (solid line), and black body locus (dashed line), and FIG. 17C is a CIE 1931 chromaticity diagram illustrating calculation of color purity of light generated by the PC Red LED, PC Green LED, the Blue LED, and the White LED;

FIGS. 18A to 18C are measured emission characteristics for the color-tunable multi-LED packaged lighting device (Pack.1) operable to generate light with a nominal CCT from 2700K to 6500K and a CRI Ra of 90 in which FIG. 18A shows spectra, normalized emission intensity (a.u.) versus wavelength (nm), for a CCT of 2700K (dotted line), a CCT of 3000K (dashed line), and a CCT of 4000K, FIG. 18B shows spectra, normalized emission intensity (a.u.) versus wavelength (nm), for a CCT of 5000K (dotted line), a CCT of 5700K (dashed line), and a CCT of 6500K, and FIG. 18C is a CIE 1931 chromaticity diagram illustrating the chromaticity (color) of light generated by the color-tunable multi-LED packaged light emitting device (Pack.1) for nominal CCTs of 2700K, 3000K, 4000K, 5000K, 5700K, and 6500K, light emission locus (solid line) for CCTs from 2700K to 6500K, black body locus (dashed line), and Mac Adam ellipses (SDCM—Standard Deviation Color Matching);

FIG. 19 is measured optical characteristics for a color-tunable multi-LED packaged lighting device (Pack.2) in which FIG. 19 is a CIE 1931 chromaticity diagram illustrating the chromaticity (color point) of light generated by the PC Red LED (square), the PC Green LED (diamond), the Blue LED (triangle), the White LED (cross), ANSI CCT center points (solid circle), color gamut of device (solid line), and black body locus (dashed line);

FIGS. 20A to 20D are schematic representation of a multi-LED, multi-cavity, package in accordance with an embodiment of the invention comprising a common cathode terminal arrangement in which FIG. 20A shows a top view, FIG. 20B shows a sectional side view through A-A, FIG. 20C shows a sectional side view through B-B, and FIG. 20D is a top view of the lead frame of the multi-LED package;

FIGS. 21A to 21D are schematic representations of a multi-LED, four-LED, package in accordance with an embodiment of the invention comprising a respective pair of anode and cathode electrical terminals for each LED in which FIG. 21A shows a top view, FIG. 21B shows a sectional side view through A-A, FIG. 21C shows a sectional side view through B-B, and FIG. 21D is a plan view of the lead frame of the multi-LED package;

FIGS. 22A and 22B are schematic representations of a multi-LED (Four-LED) package in accordance with another embodiment of the invention in which FIG. 22A shows a top view, and FIG. 22B is top view of the lead frame of the multi-LED package;

FIGS. 23A and 23B are schematic representations of Multi-LED (at least Two-LED) packages in which FIG. 23A shows a top view of a Two-Cavity (dual-cavity) Two-LED package, and FIG. 23B shows a top view of a Single-Cavity Two-LED package;

FIG. 24 is a schematic representation of a color tunable Multi-LED lighting device comprising a combination of a first Two-LED packaged device comprising Red and green LEDs and a second Two-LED packaged device comprising Blue and White LEDs;

FIGS. 25A and 25B are schematic representations of Two-LED packaged devices in which FIG. 25A shows a top view of a Dual-Cavity Two-LED packaged device comprising a PC (Phosphor Converted) Red LED and a PC (Phosphor Converted) Green LED, and FIG. 25B shows a top view of a Dual-Cavity packaged device comprising a PC (Phosphor Converted) Red LED and a Direct Emitting Green LED;

FIG. 26 shows a schematic top view of a Two-LED packaged device comprising a PC (Phosphor Converted) White LED and a Direct Emitting Blue LED;

FIGS. 27A and 27B are schematic representations of a color-tunable linear lighting device in accordance with an embodiment of the invention comprising the Two-LED packaged devices of FIGS. 25A and 26;

FIG. 28 is a schematic representation of a color tunable Multi-LED lighting device comprising a combination of a first Two-LED packaged device comprising White and Red LEDs and a second Two-LED packaged device comprising Green and Blue LEDs

FIG. 29 shows a schematic top view of a Two-LED packaged device comprising a PC (Phosphor Converted) White LED and a PC (Phosphor Converted) Red LED;

FIGS. 30A to 30C are schematic representations of Two-LED packaged devices in which FIG. 30A shows a top view of a Dual-Cavity Two-LED packaged device comprising a PC (Phosphor Converted) Green LED and a Direct Emitting Blue LED, FIG. 30B shows a top view of a Dual-Cavity Two-LED packaged device comprising a Direct Emitting Green LED and a Direct Emitting Blue LED, and FIG. 30C shows a top view of a Single-Cavity Two-LED packaged device comprising a Direct Emitting Green LED and a Direct Emitting Blue LED; and

FIGS. 31A to 31C are schematic representations of color-tunable linear lighting devices in accordance with an embodiment of the invention in which FIG. 31A shows a top view of a color-tunable linear lighting device in accordance with an embodiment of the invention comprising the Dual-Cavity Two-LED packaged devices of FIGS. 29 and 30A, FIG. 31B shows a top view of a color-tunable linear lighting device in accordance with an embodiment of the invention comprising the Dual-Cavity Two-LED packaged devices of FIGS. 29 and 30B, and FIG. 31C shows a top view of a color-tunable linear lighting device in accordance with an embodiment of the invention comprising the Dual-Cavity Two-LED packaged devices of FIGS. 29 and 30C.

### DETAILED DESCRIPTION OF THE INVENTION

### Packaged PC Red LEDs

In embodiments, particles of the broadband red phosphor and narrowband red fluoride phosphor can be provided as a mixture in a single layer and/or same layer. Since such devices comprise only one photoluminescence layer, they will be referred to as “single-layer” structured photoluminescence devices.

In other embodiments, the broadband red phosphor and narrowband red fluoride phosphor can be included in a respective layer with the layer containing the narrowband red fluoride phosphor being disposed in closer proximity to the LED chip than the layer containing the broadband red phosphor. Since such devices comprise two photoluminescence layers, they will be referred to as “double-layer” photoluminescence structured devices.

### Packaged Single-Layer PC Red LEDs

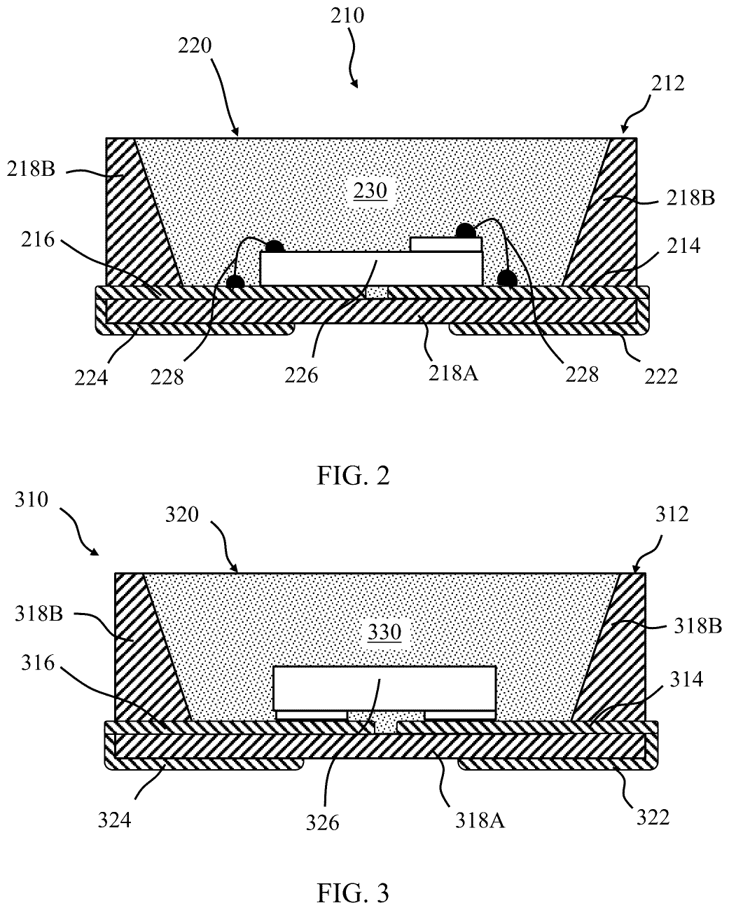

A packaged single-layer red-light emitting device (PC Red LED) 210 in accordance with an embodiment of the invention will now be described with reference to FIG. 2 which shows a schematic sectional side view of the device 210. The light emitting device 210, as illustrated, may comprise a SMD (Surface Mounted Device) such as for example a 2835 LED package.

The light emitting device 210 comprises a package 212 comprising a lead frame 214 onto which a housing 218 is molded. The lead frame comprises anode 214 and cathode 216 regions. The housing 218 comprises a base portion 218A and side wall portions 218B that extend upwardly from opposing edges of the base portion 218A. The interior surfaces of the side wall portions 218B slope inwardly to their vertical axis in a direction towards the base and, together with the interior surface (floor) of the base portion 218A, define a cavity (cup, recess) 220 in the shape of an inverted frustum of a pyramid or inverted frustrum of a cone.

Portions of the anode lead frame region 214 and cathode lead frame region 216 extend laterally to the outside edges of the housing 218 and form respective electrical anode and cathode terminals 222, 224 along opposing edges of the package 212 allowing electrical power to the anode (A) and cathode (C) of each LED chip.

The cavity (cup) 220 contains one or more InGaN-based LED dies (violet to blue LED chips) 226 mounted on the floor (interior surface of the base) of the cavity 220. As indicated, the LED chips 226 can be electrically connected to the lead frame 214 by bond wires 228. The device 210 may comprise three InGaN-based LED chips and have a rated driving condition of 100 mA, 9 V.

The cavity (cup) 220 is filled with red-light emitting photoluminescence material 230 which constitutes a single-layer photoluminescence structure. The photoluminescence material layer 230 may comprise a light transmissive (transparent) optical encapsulant, such as silicone material, with the red-light emitting photoluminescence material 230 dispersed therein.

In accordance with an embodiment of the invention, the red photoluminescence material 230 comprises a combination of a narrowband red fluoride phosphor and a red phosphor that has a higher absorption efficiency than that of the narrowband red fluoride phosphor such as, for example, a broadband red phosphor. Details of suitable narrowband red fluoride and broadband red phosphors are given below. The photoluminescence layer 230 may contain materials other than photoluminescence (phosphor) material such as light scattering particles or light diffusive material, for example.

The single-layer device 210 can be manufactured by dispensing a curable light transmissive liquid material, silicone for example, containing a mixture of the narrowband red fluoride and broadband red phosphors to fill the cavity (cup) 220.

Referring to FIG. 3, there is shown a packaged single-layer red-light emitting device 310 formed according to another embodiment of the invention. This embodiment differs from FIG. 2 only in that the LED chip(s) 326 comprise an LED flip chip.

### Packaged Double-Layer PC Red LEDs

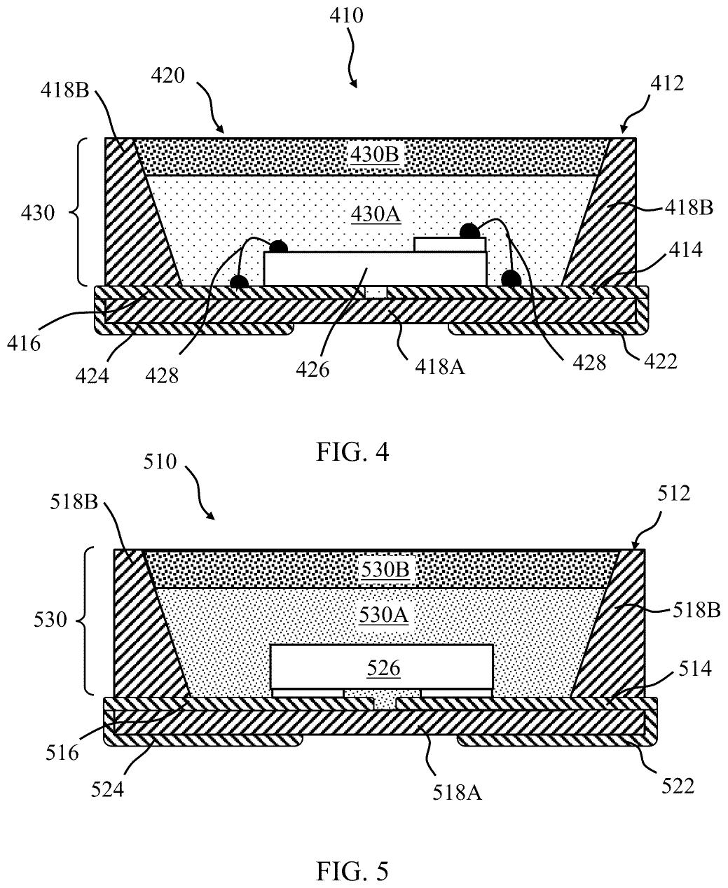

A packaged double-layer red-light emitting device (PC Red LED) 410 in accordance with an embodiment of the invention will now be described with reference to FIG. 4 which shows a schematic sectional side view of the device 410.

This embodiment differs from the single-layer device 210 of FIG. 2 in that the photoluminescence material layer 430 is constituted by a double-layer photoluminescence structure comprising a first photoluminescence layer 430A and a second photoluminescence layer 430B. The first photoluminescence layer 430A is in closer proximity to the LED chip(s) 426 than the second photoluminescence material layer 430B; that is the first photoluminescence layer 430A is proximal (i.e., a proximal layer) to the LED chip(s) 426, while the second photoluminescence material layer 430B is distal (i.e., a distal layer) to the LED chip(s) 426.

In terms of photoluminescence (phosphor) material, the first photoluminescence layer 430A contains, in terms of photoluminescence material, only, or substantially only (at least 90 wt %), narrowband red fluoride phosphor. More particularly, in embodiments, the first photoluminescence layer 430A contains, in terms of photoluminescence material, only K₂SiF₆:Mn⁴⁺ (KSF), and no other photoluminescence materials. It will be appreciated, however, that other materials such as a light diffusive (scattering) material can be added into the first photoluminescence layer 430A, but the amount of the other material(s) is typically no more than 30% weight of the narrowband red fluoride phosphor. Further, in this embodiment, the first photoluminescence layer 430A can be constituted by K₂SiF₆:Mn⁴⁺ dispersed in an encapsulant, such as dimethyl silicone. The first photoluminescence layer 430A is directly adjacent to the LED chip(s) 426 and may, as indicated in FIG. 4, be in direct contact the LED chip(s) 426. In this example, for instance, there are no other photoluminescence materials or photoluminescence material containing layers between the first photoluminescence layer 430A and the LED chip(s) 426.

The second photoluminescence layer 430B contains broadband red phosphor and is dispensed on top of the first photoluminescence layer 430A to fill the cavity (cup) 420.

Comparing the single-layer device 210, as shown for example in FIG. 2, in a single-layer light emitting device, the narrowband red fluoride and broadband red phosphors, which comprise a mixture, have equal exposure to excitation light, for example blue excitation light, as each is located in the same location (layer) relative to the LED chip(s). Since narrowband red fluoride phosphor has a much lower blue light absorption efficiency (capability) than broadband red phosphor, a greater amount of narrowband red fluoride phosphor is necessary to convert enough blue light to the required red emission attributable to the narrowband red fluoride phosphor. By contrast, in the double-layer light emitting device 410, the narrowband red fluoride phosphor, in its separate individual layer 430A, is exposed to blue excitation light individually; thus, more of the blue excitation light from the blue LED chip(s) 426 can be absorbed by the narrowband red fluoride phosphor and remaining (unabsorbed, for example) blue excitation light can penetrate through to the second photoluminescence layer 430B containing the broadband red phosphor. Advantageously, with a double-layer photoluminescence structure, the first photoluminescence layer 430A can more effectively convert the blue excitation light to a narrowband red light and the amount/usage of a narrowband red fluoride phosphor can be significantly reduced (up to about 40%) compared with the single-layer photoluminescence arrangement (FIG. 2). A further benefit of the double-layer photoluminescence structure is that since the second photoluminescence layer 430B completely covers the first photoluminescence layer 430A this effectively isolates the narrowband red fluoride phosphor located (contained) in the first photoluminescence layer 430A from direct contact with water/moisture in the surrounding environment. Such a double-layer structure provides an effective solution to address the poor moisture reliability of narrowband red fluoride phosphors.

Referring to FIG. 5, there is shown a packaged double-layer packaged light emitting device 510 formed according to another embodiment of the invention. This embodiment differs from FIG. 4 only in that the LED chip(s) 526 comprise an LED flip chip.

### CSP (Chip Scale Packaged) PC Red LEDs

While the foregoing embodiments have been described in relation to packaged PC red LED devices, embodiments of the invention find utility for chip scale packaged light emitting devices. In this specification, a CSP arrangement is a packaging arrangement on a chip scale and does not include a lead frame. In a CSP arrangement, the LED chip may comprise an integral component of the package. For example, one or more layers of material can be applied directly to a face, or faces, of the flip chip to form a packaged device. A particular advantage of a CSP arrangement is the small size of the packaged device, which may be comparable to the chip size.

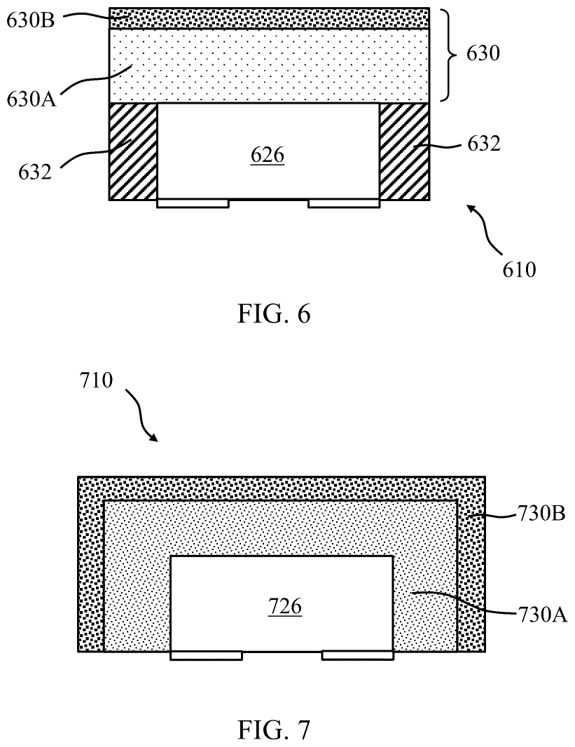

FIG. 6 show a side view of a CSP double-layer red-light emitting devices 610 in accordance with embodiments of the invention. There is provided a photoluminescence material layer 630 which is constituted by a double-layer photoluminescence structure comprising, in this embodiment, a first photoluminescence layer 630A containing narrowband red fluoride phosphor is applied or deposited (fabricated) as a uniform thickness layer directly onto and covers at least the principle (top as illustrated) light emitting face of an LED flip chip 626; and a second photoluminescence material layer 630B containing broadband red phosphor is applied or deposited (fabricated) as a uniform thickness layer onto and covers the first photoluminescence layer 630A. As indicated, the device 610 can further comprise a light reflective layer 632, for example white silicone or epoxy, covering the four side faces of the LED chip to prevent emission (and wastage) of excitation light therefrom. In other embodiments, the light reflective layer may cover the edges of the first and second photoluminescence layers to prevent emission of excitation light therefrom.

FIG. 7 shows a side view of a CSP double-layer red-light emitting devices 710 in accordance with embodiments of the invention. In this embodiment, a first photoluminescence layer 730A containing narrowband red fluoride phosphor is applied or deposited (fabricated) as a uniform thickness layer directly onto and covers at least the principle (top as illustrated) light emitting face and four light emitting side faces of an LED flip chip 726. A second photoluminescence material layer 730B containing broadband red phosphor is applied or deposited (fabricated) as a uniform thickness layer onto and covers the top and side faces of the first photoluminescence layer 730A. In this embodiment, the photoluminescence material layer 730B envelops the first photoluminescence layer 730A. The first and second photoluminescence layers 730A, 730B can be in the form of a conformal coating.

### Narrowband Red Fluoride Phosphors

In this patent specification, a narrowband red phosphor refers to a photoluminescence material which, in response to stimulation by excitation light, generates red light having a Full Width at Half Maximum (FWHM) emission intensity from about 5 nm to about 20 nm. As described herein, the narrowband red phosphor can comprise a manganese-activated fluoride narrowband red phosphor such as manganese-activated potassium hexafluorosilicate phosphor (KSF)-K₂SiF₆:Mn⁴⁺ (KSF) which has a peak emission wavelength λₚ of about 631-632 nm. Other manganese-activated fluoride narrowband red phosphors can include manganese-activated potassium hexafluorogermate phosphor (KGF)-K₂GeF₆:Mn⁴⁺ and/or manganese-activated potassium hexafluorotitanate phosphor (KTF)-K₂TiF₆:Mn⁴⁺.

### Broadband Red Phosphors

In this patent specification, a broadband red phosphor refers to a photoluminescence material which, in response to stimulation by excitation light, generates red light having a full width at half maximum (FWHM) emission intensity from about 50 nm to about 120 nm. As described above, the broadband red phosphor may comprise a rare-earth activated broadband red phosphor that is excitable by blue light and in response emit light with a peak emission wavelength λₚ in a range from about 620 nm to about 640 nm, i.e., in the red region of the visible spectrum. Rare-earth-activated red photoluminescence material can include, for example, a europium-activated silicon nitride-based phosphor, a europium-activated Group IIA/IIB selenide sulfide-based phosphor or europium-activated silicate-based phosphors. Examples of broadband red phosphors are given in TABLE 1.

In some embodiments, the europium-activated silicon nitride-based phosphor comprises a Calcium Aluminum Silicon Nitride phosphor (CASN) of general formula CaAlSiN₃: Eu²⁺ (1:1:1:3 Nitride). The CASN phosphor can be doped with other elements such as strontium (Sr), general formula (Sr,Ca)AlSiN₃:Eu²⁺.

Alternatively, the rare-earth-activated red phosphor can comprise a nitride-based phosphor of general composition (Sr,Ba)₂Si₅N₈:Eu²⁺ (2:5:8 Nitride).

Rare-earth-activated red phosphors can also include Group IIA/IIB selenide sulfide-based phosphors. A first example of a Group IIA/IIB selenide sulfide-based phosphor material has a composition MSe₁₋ₓSₓ:Eu, wherein M is at least one of Mg, Ca, Sr, Ba and Zn and 0<x<1.0. A particular example of this phosphor material is CSS phosphor (CaSe₁₋ₓSₓ:Eu). The emission peak wavelength of the CSS phosphor can be tuned from 600 nm to 650 nm by altering the S/Se ratio in the composition.

In some embodiments, the rare-earth-activated red phosphor can comprise a silicate-based phosphor of general composition (Sr₁₋ₓMₓ)_{y}Eu_{z}SiO₅ where 0<x≤0.5, 2.6≤y≤3.3, 0.001≤z≤0.5 and M is one or more divalent metal selected from the group consisting of Ba, Mg, Ca, and Zn.

TABLE 1
Example broadband red phosphors

| | | | Wavelength |
|---|---|---|---|
| Phosphor | General Composition | | λₚ (nm) |
| CASN (1:1:1:3) | (Ca₁₋ₓSrₓ)AlSiN₃:Eu | 0.5 < x ≤ 1 | 600-650 |
| 2:5:8 Nitride | Ba₂₋ₓSrₓSi₅N₈:Eu | 0 ≤ x ≤ 2 | 580-650 |
| Group IIA/IIB | MSe₁₋ₓSₓ:Eu | M = Mg, Ca, Sr, Ba, | 600-650 |
| Selenide Sulfide | | Zn | |
| | | 0 < x < 1.0 | |
| CSS | CaSe₁₋ₓSₓ:Eu | 0 < x < 1.0 | 600-650 |
| Silicate | (Sr₁₋ₓMₓ)_{y}Eu_{z}SiO₅ | M = Ba, Mg, Ca, Zn | 565-650 |
| | | 0 < x ≤ 0.5, | |
| | | 2.6 ≤ y ≤ 3.3, | |
| | | 0.001 ≤ z ≤ 0.5 | |

### Color Purity and Dominant Wavelength

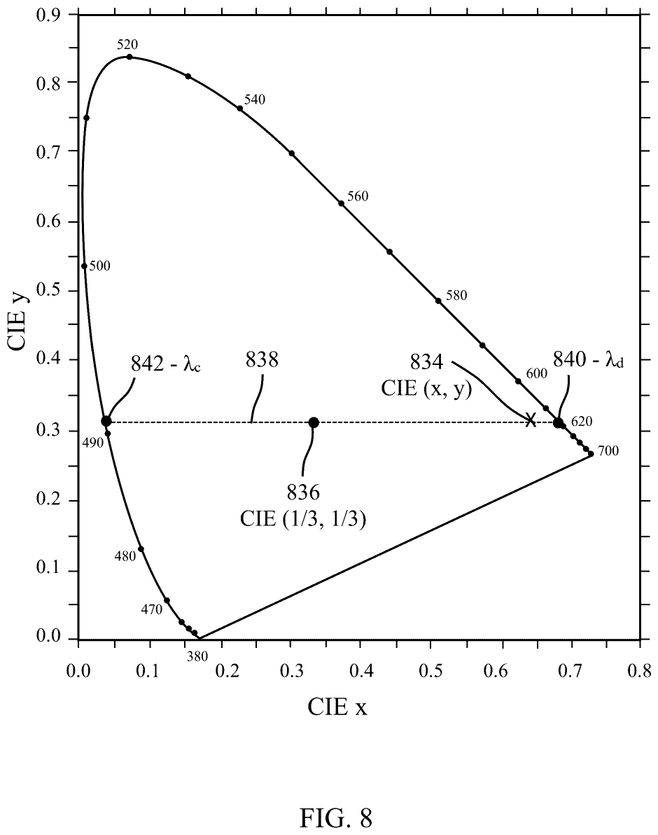

Color purity, or color saturation, provides a measure of how close the color hue of light of a given color (chromaticity) is to a spectral (monochromatic) color corresponding to light of dominant wavelength λ_{d}. Color purity can have a value from 0 to 100%. FIG. 8 is a CIE 1931 chromaticity diagram illustrating how color purity and dominant wavelength of light of a given chromaticity (color) are calculated.

Referring to FIG. 8, the color point (chromaticity) for the given color of light is indicated on the chromaticity diagram by cross 834 and a “white standard illuminant” is indicated by dot 836. The “white standard illuminant” used in this specification is the equal-energy (flat spectrum) and has color space coordinates CIE (1/3, 1/3). A straight line 838 (dashed line) connecting the chromaticity color points 834 and 836 is extended so that it intersects the outer curved boundary (perimeter) of the CIE color space at two points. The point of intersection 840 nearer to the given color CIE (x, y) 834 corresponds to the dominant wavelength λ_{d} of the color as the wavelength of the pure spectral (monochromatic) color at that intersection point. The point of intersection 842 on the opposite side of the color space corresponds to the complementary wavelength λ_{c}, which when added to the given color in the correct proportion will yield the color of the white standard illuminant.

The outer curved boundary of the chromaticity diagram is the monochromatic (spectral) locus with the numbers indicating the wavelengths in nanometers (nm). The color purity of monochromatic light (i.e., those lying on the spectral locus) is 100 while the color purity of light of the “white standard illuminant” 836 is zero. The color purity of light of chromaticity coordinates CIE (x, y) 834 plotted on the chromaticity diagram is the ratio of the distance from the “white standard illuminant” 836 to the color point 834 to the distance from the “white standard illuminant” 836 to the point of intersection 840 corresponding to the dominant wavelength λ_{d}.

### Experimental Test Data

In this specification, the following nomenclature is used to denote PC Red light emitting devices: Com.# denotes a comparative PC red light emitting device comprising a single red phosphor (i.e., a broadband red or a narrowband red fluoride phosphor) and Dev.# denotes a PC red light emitting device in accordance with the invention that comprises a combination of narrowband red fluoride phosphor and broadband red phosphor.

Comparative PC Red light emitting devices (Com.#) and PC Red light emitting devices in accordance with the invention (Dev.#) comprise SMD 2835 packaged devices containing four serially connected blue LED chips. Each device is a nominal 1.2 W device (rated driving condition is 100 mA and a forward drive voltage V_{f} of 12 V).

The red phosphors used in the test devices are KSF (K₂SiF₆:Mn⁴⁺) narrowband red fluoride phosphor and CASN (Ca₁₋ₓSrₓAlSiN₃:Eu) broadband red phosphor.

For comparative devices, Com.# the red phosphor (KSF or CASN) is incorporated in a phenyl silicone and the mixture dispensed into the 2835 package to fill the LED cavity.

For the single-layer device (Dev.1): a mixture of KSF and CASN phosphors is incorporated in a phenyl silicone and dispensed into the 2835 package to fill the LED cavity.

For the double-layer device (Dev.2): KSF phosphor is incorporated in a phenyl silicone and dispensed into the 2835 package to partially fill the LED cavity. The KSF phosphor layer is cured in an oven. CASN phosphor is mixed with a phenyl silicone and then dispensed on top of KSF layer to fully fill the LED cavity and then cured in an oven.

### Optical Performance

The test method involves measuring total light emission of the PC Red light emitting devices in an integrating sphere.

TABLE 2 tabulates phosphor composition of comparative devices Com.1 and Com.2 and devices Dev.1 and Dev.2 in accordance with the invention. CASN 630, CASN 650 and CASN 655 indicate a CASN phosphor with a respective peak emission wavelength λₚ of 630 nm, 650 nm and 655 nm. The wt % values in TABLE 2 are the weight % of total phosphor weight. The weight values in TABLE 2 are the weight of KSF phosphor normalized to KSF phosphor weight in comparative PC Red LED Com.2.

As can be seen from TABLE 2, in terms of phosphor composition: Com. 1 comprises a single-layer phosphor structure comprising 100 wt % CASN 630; Com.2 comprises a single-layer phosphor structure comprising 100 wt % KSF; Dev.1 comprises a single-layer phosphor structure containing a combination of 67 wt % KSF and 33 wt % CASN 650; and Dev.2 comprises a double-layer phosphor structure having a first phosphor layer comprising 61 wt % KSF and a second phosphor layer comprising 39 wt % CASN 655.

TABLE 2
Phosphor composition of single-layer comparative devices (Com. 1,
Com. 2), a single-layer device (Dev. 1), and a double-layer device

| | (Dev. 2) 1^{st} phosphor layer | | | | |
|---|---|---|---|---|---|
| | | | CASN | CASN | 2^{nd} phosphor layer |
| | KSF | | 630 | 650 | CASN 655 |
| Device | wt % | weight | wt % | wt % | wt % |
| Com. 1 | — | — | 100 | — | — |
| Com. 2 | 100 | 100 | — | — | — |
| Dev. 1 | 67 | 66 | — | 33 | — |
| Dev. 2 | 61 | 60 | — | — | 39 |

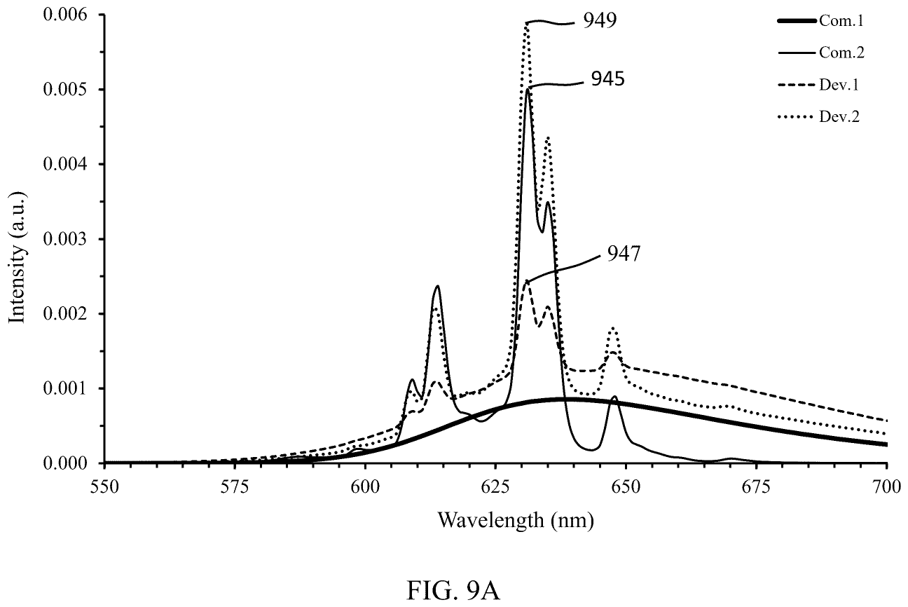

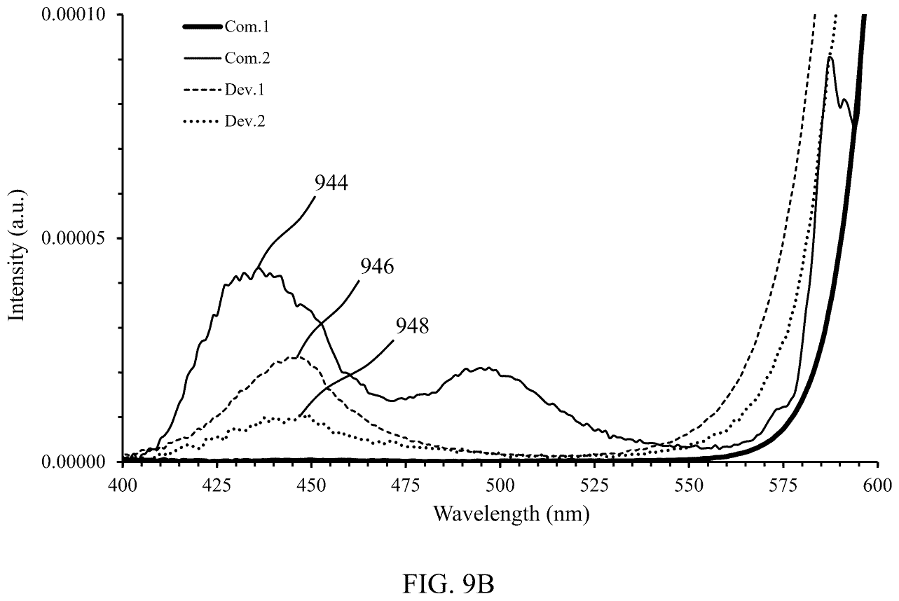

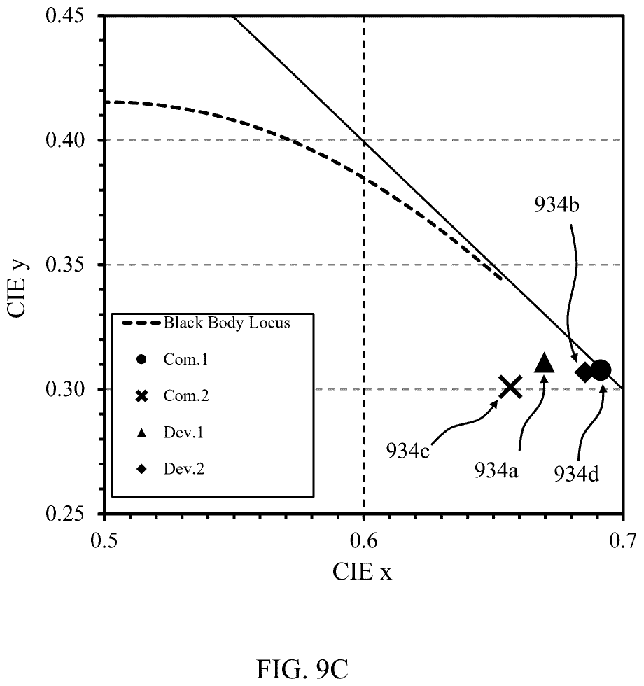

TABLE 3 tabulates the measured optical performance of the PC Red-light emitting devices (PC Red LED) Com.1, Com.2, Dev.1, and Dev.2. FIGS. 9A and 9B are measured spectra, intensity (a.u.) versus wavelength (nm), for comparative packaged red-light emitting device Com.1 containing broadband red phosphor (thick solid line), (ii) comparative packaged red-light emitting device Com.2 containing narrowband red fluoride phosphor (thin solid line), (iii) packaged single-layer red-light emitting device Dev. 1 in accordance with an embodiment of the invention (dashed line), and (iv) packaged double-layer red-light emitting device Dev. 2 in accordance with an embodiment of the invention (dotted line). FIG. 9A shows the wavelength portion of the spectra for wavelengths from 550 nm to 700 nm (i.e., green to red region). FIG. 9B shows the wavelength portion of the spectra for wavelengths from 400 nm to 600 nm (i.e., violet to yellow) and illustrates “blue pass through”. FIG. 9C is a CIE 1931 chromaticity diagram illustrating the chromaticity (color) of light generated by (i) comparative packaged red light emitting device Com.1 (solid circle), (ii) comparative packaged red light emitting device Com.2 (cross), (iii) packaged single-layer red light emitting device Dev. 1 (solid triangle), (iv) packaged double-layer red light emitting device Dev. 2 (solid diamond), black body locus (dashed line), and chromaticity gamut boundary (solid line).

TABLE 3
Optical performance of comparative PC Red LEDs (Com. 1, Com. 2),
single-layer PC Red LEDs (Dev. 1) and two-layer PC Red LED (Dev. 2)

| | Flux | Efficacy | Brightness | λ_{d} | λₚ | FWHM | Purity | CIE | |
|---|---|---|---|---|---|---|---|---|---|
| Device | (lm) | (lm/W) | (%) | (nm) | (nm) | (nm) | (%) | x | Y |
| Com. 1 | 7.29 | 10.0 | 100 | 620.3 | 638.8 | 67.1 | 99.7 | 0.6912 | 0.3078 |
| Com. 2 | 13.89 | 11.5 | 190 | 626.6 | 632.6 | 7.25 | 87.3 | 0.6565 | 0.3011 |
| Dev. 1 | 14.89 | 12.3 | 204 | 619.4 | 632.6 | 27.3 | 94.2 | 0.6696 | 0.3109 |
| Dev. 2 | 17.72 | 14.5 | 243 | 621.1 | 632.4 | 7.49 | 97.7 | 0.6853 | 0.3068 |

As can be seen from TABLE 3, comparative device Com.1, containing, in terms of photoluminescence material, only broadband red phosphor (CASN 630), generates red light with a flux of 7.29 lm (100%) and a luminous efficacy of 10.0 lm/W with a peak emission wavelength λₚ of 639 nm, FWHM of 67 nm, dominant wavelength λ_{d} of 620 nm and a color purity of 99.7%. In comparison, comparative device Com.2, containing, in terms of photoluminescence material, only narrowband red fluoride phosphor (KSF), generates red light with an increased flux of 13.89 lm (190%) and luminous efficacy of 11.5 lm/W with a peak emission wavelength λₚ of 633 nm, FWHM of 7 nm, dominant wavelength λ_{d} of 627 nm and color purity of only 87.3%. It will be noted that use of a narrowband red fluoride phosphor (Com.2) compared with use of a broadband red phosphor (Com.1), as might be expected, results in a substantial (90%) increase in lumen output/efficacy, a reduction in FWHM (67 nm to 7 nm), and a decrease in color purity (87.3% compared with 99.7%).

Referring to FIG. 9B, it is to be noted that for Com.1 there is no evidence of violet/blue light (400-500 nm) in the final emission spectrum (thick solid line) indicating that all of the blue light generated by the LED is converted red light, i.e., there is no evidence of “blue pass through” in the emission product of the device of Com.1. In contrast, for Com.2 the emission spectrum (thin solid line) has a clear peak 944 (λₚ about 435 nm) in the violet/blue region of the spectrum that is attributable to unconverted blue light generated by the LED chip, so-called “blue pass through”. The large reduction in color purity of red light produced by Com.2 compared with Com.1 (87.3% compared with 99.7%) is attributable to the unconverted blue light 944 which causes the chromaticity CIE x of light to decrease moving the chromaticity (chromaticity point 834-FIG. 8) of the light further from the curved boundary of the chromaticity diagram, thereby reducing the color purity. Even increasing the weight loading of narrowband red fluoride phosphor (KSF) to binder (silicone) from 70% to 80% would only increase the color purity of light generated by Com.2 to value of 95%. Thus, a significant increase in the amount of KSF usage alone would increase the cost of manufacturing significantly without offering a significant increase in the performance/purity of light of the device. A combination of a narrowband red fluoride phosphor (e.g., manganese-activated fluoride narrowband red phosphor) and a red phosphor having a higher absorption efficiency such as, for example, a broadband red phosphor is thus advantageous because it produces a synergistic effect.

As can be seen from FIG. 9A, the intensity of the principal peak at approximately 630 nm attributable to narrowband red fluoride phosphor (KSF) of Com.2, Dev.1, and Dev.2 differs in each device. The intensity of this peak is determined by the absorption/conversion of blue light by the narrowband red fluoride phosphor (KSF) and CASN when present and the amount of unconverted blue light-blue pass through. It can be seen from FIG. 9A that Com.2 (single layer comprising only KSF) has a peak 945 at approximately 630 nm with an intensity of approximately 0.005. The intensity of peak 945 is attributable to Com.2 comprising, in terms of photoluminescence material, only narrowband red fluoride phosphor (KSF) and the intensity depends inversely on the amount of blue pass through—unconverted blue light. As can be seen from FIG. 9B, Com.2 has a peak 944 peak with an intensity of approximately 0.00004. It can be seen from FIG. 9A that Dev.1 (single layer comprising mixture of KSF and CASN) has a principal peak 947 with an intensity of approximately 0.0025. The height of this peak is attributable to Dev.1 comprising a mixture of narrowband red fluoride phosphor (KSF) and CASN in a single layer. Since the KSF and CASN are contained in a single layer, CASN and KSF have equal exposure to blue light. Since CASN has a greater absorption efficiency than KSF, the proportion of light attributable KSF is much smaller than that attributable to CASN and as a result, the intensity (0.0025) of peak 947 is lower than the intensity (0.005) of peak 945. As can be seen in FIG. 9B, Dev.1 has a peak 946 with a peak intensity of approximately 0.00002 for blue light since the presence of CASN in the single layer mixture (KSF/CASN) absorbs/converts some blue light into red light thereby reducing blue pass through (unconverted blue light) compared with Com.2. Next, it can be seen from FIG. 9A that Dev.2 (double layer comprising KSF in a proximal layer to LED chip and CASN in distal layer to LED chip) has a peak 949 with an intensity of approximately 0.006 at approximately 630 nm. The intensity of this peak is attributable to Dev.2 comprising, in terms of photoluminescence material, only narrowband red fluoride phosphor (KSF) in one layer and CASN in a separate layer. Since the narrowband red fluoride phosphor is not competing for blue light with another phosphor (i.e., CASN) in the same layer, the absorption/conversion of blue light by the narrowband red fluoride phosphor is enhanced causing the 630 nm peak intensity to be approximately 0.006 higher than Com.2 that comprises KSF alone. FIG. 9B shows that Dev.2 has a peak 948 with an intensity of approximately 0.00001 for blue light since CASN is present in the separate layer to absorb absorb/convert blue light into red light that has not already been converted by the KSF (effectively mopping up any blue light not converted by KSF). Since the conversion/absorption efficiency of blue light by KSF is lower than that of CASN, for example, but CASN is present in a separate layer to absorb any unconverted blue light without competing for the blue light with the KSF in the other layer, Dev.2 demonstrates relatively low blue pass through (unconverted blue light)—this spectral energy being distributed in the KSF peak at 630 nm. Hence, the KSF peak intensity at 630 nm is greater for Dev.2 compared with that of Com.2 (0.006 compared with 0.005) due to the presence of CASN in a separate layer which causes blue light to be scattered back into the KSF (recycling) increasing the number of potential collisions of blue light with the KSF thereby increasing the peak intensity of Dev.2 in the KSF peak region (at approximately 630 nm).

In summary, it will be appreciated that the addition of CASN reduces the amount of blue pass through and improves color purity when using a narrowband red fluoride phosphor. Moreover, by providing the CASN in a separate layer, this further increases the emission intensity of the peak attributable to KSF. This arrangement also reduces the amount/quantity of KSF required by the device to attain a desired emission intensity.

As can be seen from TABLE 3, single-layer device Dev.1 containing a combination of narrowband red fluoride and broadband red phosphor (CASN 650) generates red light with a flux of 14.89 lm (204%) and a luminous efficacy of 12.3 lm/W with a peak emission wavelength λₚ of 633 nm, FWHM of 27 nm, dominant wavelength λ_{d} of 619 nm and color purity 94.2%. Referring to FIG. 9B, while Dev.1 has a peak 946 (λₚ about 445 nm) in the violet/blue region of the spectrum that is attributable to unconverted blue light, “blue pass through”, the intensity of the peak 946 is much smaller (about half) compared with the peak 944 of Com.2. The increase in color purity of red light produced by Dev.1 compared with Com.2 (94.2% compared with 87.3%) is attributable to the reduction of unconverted blue light 946 in the final emission product. As illustrated in FIG. 9C, the reduction of unconverted blue light causes the chromaticity CIE x of light generated by Dev.1 (934a—solid triangle) to increase in value compared with the chromaticity of Com.2 (934c—cross) moving the chromaticity point 934a of the light towards the curved chromaticity gamut boundary (solid line) of the chromaticity diagram thereby increasing the color purity. The increase in color purity of red light produced by Dev.1 compared with Com.2 is attributable to the inclusion of the broadband red phosphor which reduces the intensity of unconverted blue light 946 in the final emission product because more of the blue light is being converted (compared with Com.2 having KSF alone). As can be seen from TABLE 2, the inclusion of the broadband red phosphor also reduces the usage amount (weight) of narrowband red fluoride phosphor (34% weight reduction compared with Com.2).

As can be seen from TABLE 3, double-layer device Dev.2 containing a combination of narrowband red fluoride and broadband red phosphor (CASN 650) generates red light with a flux of 17.72 lm (243%) and a luminous efficacy of 14.5 lm/W with a peak emission wavelength λₚ of 632 nm, FWHM of 7.49 nm, dominant wavelength λ_{d} of 621 nm and color purity 97.7%. Referring to FIG. 9B, it is to be noted that while Dev.2 has a peak 948 (λₚ about 445 nm) in the violet/blue region of the spectrum that is attributable to unconverted blue light—“blue pass through”—the peak 948 is diffuse and of a much smaller intensity (about a quarter) compared with that of peak 944 of Com.2. The increase in color purity of red light produced by double-layer Dev.2 compared with single-layer Dev.1 (97.7% compared with 94.2%) is attributable to the reduction of unconverted blue light 948 in the final emission product. As illustrated in FIG. 9C, the reduction of unconverted blue light causes the chromaticity CIE x of light generated by Dev.2 (934b—diamond) to increase in value compared with the chromaticity of Dev.1 (934a—triangle) moving the chromaticity point 934b of the light towards the curved chromaticity gamut boundary (solid line) of the chromaticity diagram thereby increasing the color purity. The decrease in “blue pass through” is attributable to the double-layer photoluminescence structure in which the narrowband red fluoride phosphor is provided in a separate layer adjacent to the LED chip. Such an arrangement effectively increases the absorption efficiency of the narrowband red fluoride phosphor since the narrow band red fluoride phosphor is not competing with the broadband red phosphor for blue photons as is the case in a single-layer photoluminescence structure. Moreover, as can be seen from TABLE 3, as well as increasing color purity and intensity/luminous efficacy (243% compared with 204%), a double-layer photoluminescence structure can reduce usage amount (weight) of narrowband red fluoride phosphor (40% weight reduction compared with Com.2). FIG. 9C also shows the chromaticity value of Com.1 (934d—solid circle).

In summary, it will be appreciated that red light emitting devices in accordance with embodiments of the invention comprising a combination narrowband red fluoride phosphor and broadband red phosphor can provide number of benefits, including but not limited to: (1) a substantial reduction in narrowband red fluoride phosphor usage (at least about 40%), (2) a substantial reduction, or even elimination of “blue pass through” leading to increased color purity of red light generated by the device, (3) a substantial increase in light intensity/luminous efficacy of the device, and (4) a color purity that is comparable with a PC Red LED that utilizes, in terms of photoluminescence material, only broadband red phosphor or a color purity that is superior to that of a PC Red LED that utilizes only narrowband red phosphor.

### Color-Tunable Multi-LED Lighting Devices

Phosphor-Converted Red LEDs (PC Red LEDs) containing narrowband red phosphor in accordance with embodiments of invention find utility as a red-light source in light emitting devices such as for example RGB (Red Green Blue) Multi-LED lighting devices that comprise a Red LED, Green LED and Blue LED. As described herein, PC Red LEDs can comprise packaged or CSP (Chip Scale Packaged) devices having a single-layer or double-layer photoluminescence structures. The green LED can comprise a packaged or CSP (Chip Scale Packaged) Phosphor-Converted Green LED (PC Green LED) having a single-layer photoluminescence structure comprising a green photoluminescence material (phosphor) covering a violet to blue LED chip. The green phosphor may comprise, for example, a green silicate phosphor ((Sr₁₋ₓBaₓ)₂SiO₄:Eu), β-SiAlON phosphor, or a green emitting YAG phosphor ((Y, Ba)₃₋ₓ(Al_{1-y}Ga_{y})₅O₁₂:Ceₓ). Alternatively, the green LED may comprise a Direct-Emitting green LED chip (e.g., InGaN-based LED chip). The blue LED typically comprises an InGaN-based LED chip or flip chip. The Red, Green, and Blue LEDs can be housed in a package, such as for example, a surface mount package. When the Red LED comprises a PC Red LED and the Green LED comprises a PC Green LED or a Direct-Emitting Green LED, the Red, Green, and Blue LEDs may be mounted on a substrate such as a printed circuit board, a so-called Chip On Board (COB) packaging arrangement.

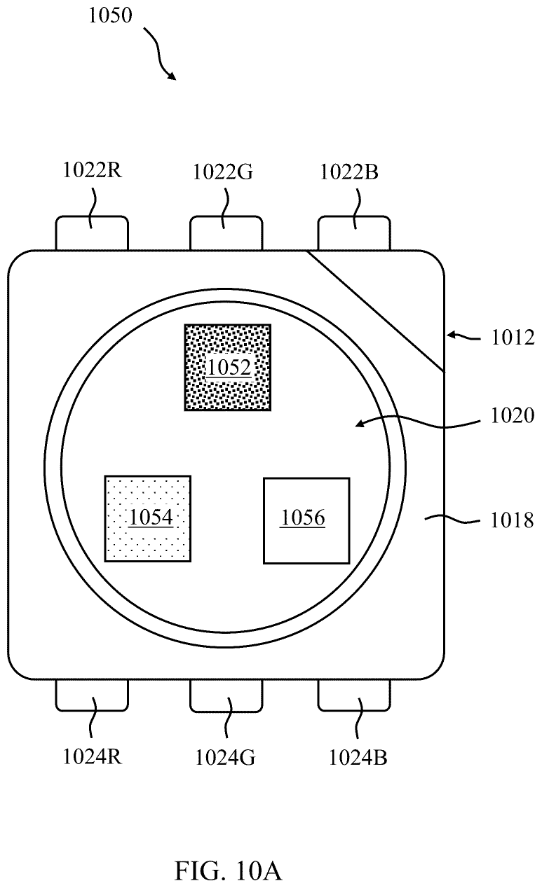

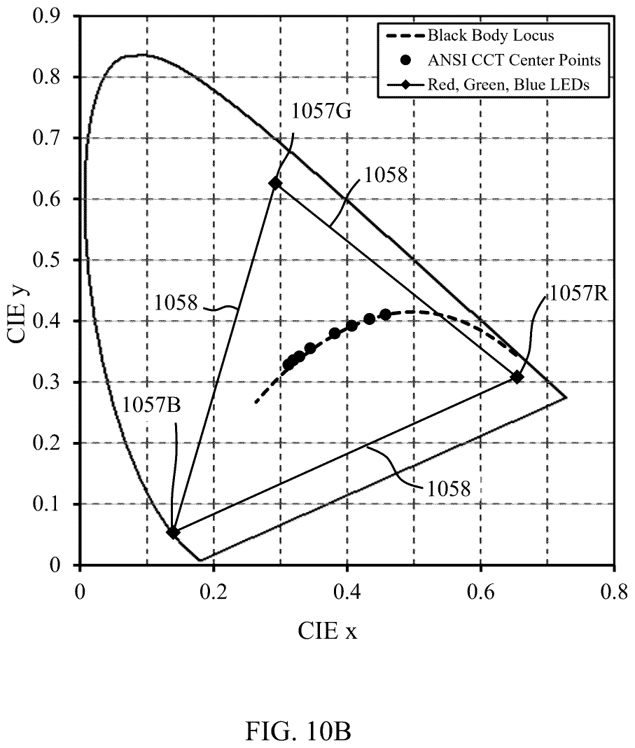

FIG. 10A shows a schematic plan view of a color-tunable multi-LED packaged lighting device 1050 utilizing a red-light emitting device (PC Red LED) 1052. The device 1050 comprises a package (for example a SMD) 1012 comprising a lead frame and a housing 1018 that defines a single cavity (cup/recess) 1020 (e.g. circular as illustrated) containing a PC Red LED 1052, a green LED 1054, and a blue LED 1056. The PC Red LED 1052 may comprise a PC Red LED according to embodiments of the invention such as a single-layer or double-layer CSP (Chip Scale packaged) red light emitting device such as, for example, the CSP device of FIG. 6 or FIG. 7. The green LED 1054 may comprise a CSP PC Green LED comprising a broadband green phosphor covering an LED flip chip. The green phosphor having a peak emission wavelength from 500 nm to 565 nm. Alternatively, the green LED may comprise a Direct-Emitting Green LED chip (e.g. InGaN-based LED chip). The blue LED 1056 typically comprises an InGaN-based LED chip having a dominant wavelength from 430 nm to 480 nm. The cavity (cup) 1020 may be filled with a light transmissive medium (e.g. silicone) to provide environmental protection to the red 1052, green 1054 and blue 1056 LEDs. As illustrated, the package 1012 typically comprises respective anode and cathode electrical terminals 1022, 1024 allowing electrical power to be individually applied to the anode and cathode of each of the red (R), green (G) and blue (B) LEDs 1052, 1054, 1056.

The lighting device 1050 can generate colors of light from blue to red as well as different color temperatures of light. FIG. 10B is a CIE 1931 chromaticity diagram illustrating the gamut (color/color temperatures) of light that the light emitting device 1050 can generate. The CIE chromaticity diagram shows the chromaticity (color point) 1057R of red light generated by the PC Red LED, the chromaticity (color point) 1057G of green light generated by the PC Green LED, and the chromaticity (color point) 1057B of blue light generated by the Blue LED. Straight lines 1058 connecting the points 1057R, 1057G, and 1057B define a triangle that represents the gamut of chromaticities (colors)/color temperatures of light that light emitting device 1050 can generate—i.e., the device can generate any color/color temperature of light within the triangle or lying on the boundary. As will be noted from the chromaticity diagram, the device 1050 can generate color temperatures of light lying on the black body locus (dashed line) and color temperatures corresponding to the ANSI CCT center points that lie within or on the boundary of the triangle.

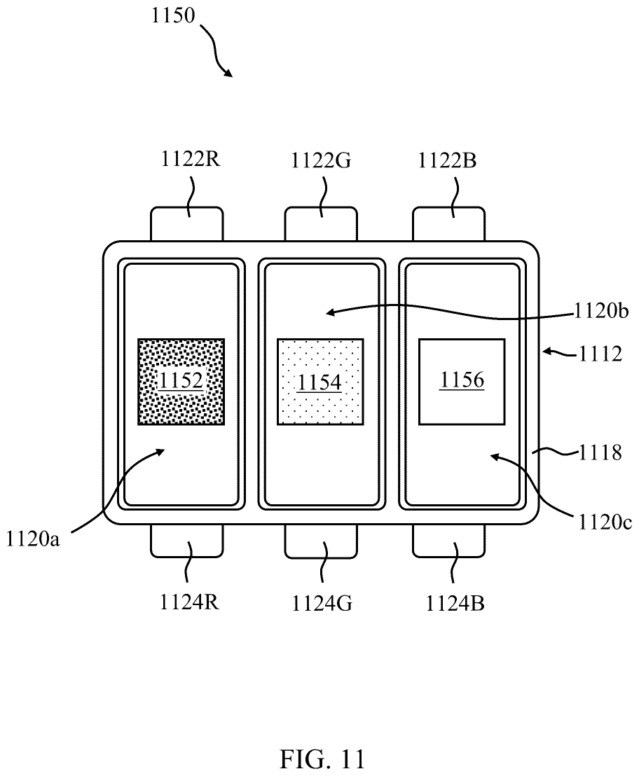

FIG. 11 shows a schematic plan view of a color-tunable multi-LED packaged lighting device 1150 utilizing a red-light emitting device (PC Red LEDs) 1152. The device 1150 comprises a package 1112 having three cavities (cups) 1120a, 1120b, 1120c that respectively contain a PC Red LED 1152, a green LED 1154, and a blue LED 1156. As illustrated, the PC Red LED 1152 may comprise a PC Red LED according to embodiments of the invention such as a single-layer or double-layer CSP (Chip Scale packaged) red-light emitting device such as, for example, the CSP device of FIG. 6 or FIG. 7. The green LED 1154 may comprise a CSP PC Green LED or a Direct-Emitting green LED (e.g., InGaN-based LED chip). The blue LED 1056 typically comprises an InGaN-based LED chip and generates light with a dominant wavelength from 430 nm to 480 nm. Each cavity 1120a, 1120b, 1120c may be filled with a light transmissive medium (e.g., silicone) to provide environmental protection to the red 1152, green 1154 and blue 1156 LEDs. As illustrated, the package 1112 typically comprises respective anode electrical terminals 1122R, 1122G, 1122B and cathode electrical terminals 1124R, 1124G, 1124B, allowing electrical power to be independently applied to the anode and cathode of each of the red (R), green (G) and blue (B) LEDs 1152, 1154, 1156. Like lighting device 1050 of FIG. 10, lighting device 1150 can generate colors of light from blue to red as well as different color temperatures of light that—i.e., generate color/color temperature of light within the triangle or lying on the boundary of the triangle on the chromaticity diagram (FIG. 10B).

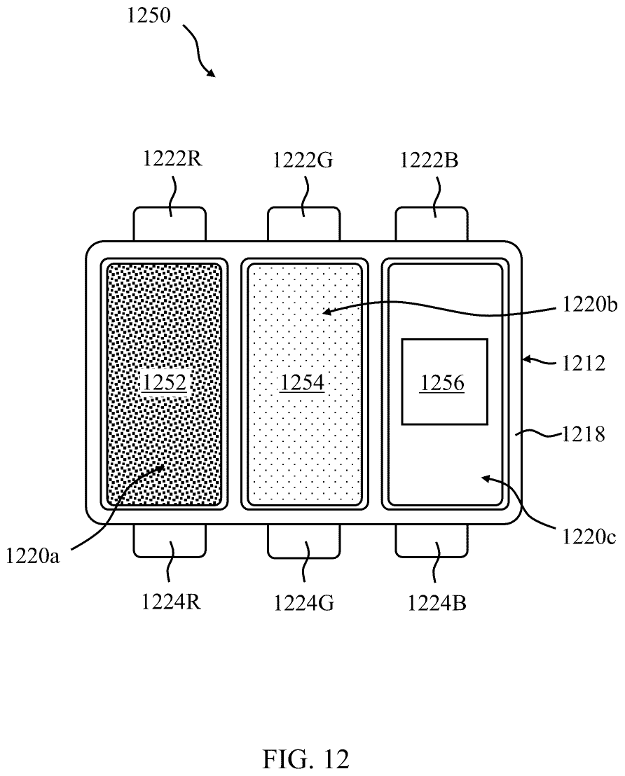

FIG. 12 shows a schematic plan view of a color-tunable multi-LED packaged lighting device 1250 utilizing a red-light emitting device (PC Red LEDs) 1252. The device 1250 comprises a package 1212 having three cavities (cups) 1220a, 1220b, 1220c that respectively contain a PC Red LED 1252, a green LED 1254, and a blue LED chip 1256. As illustrated, the Red LED 1252 may comprise a PC Red LED according to embodiments of the invention such as a single-layer or double-layer red light emitting device such as for example the packaged devices of FIGS. 2 to 5 in which the cavity 1220a is filled with narrowband red fluoride and broadband red phosphor. As illustrated, the green LED 1254 may comprise a PC Green LED such as for example a packaged device in which the cavity 1220b is filled with green phosphor. The blue LED chip 1256 typically comprises an InGaN-based LED chip and generates light with a dominant wavelength from 430 nm to 480 nm. The cavity 1220c may be filled with a light transmissive medium (e.g. silicone) to provide environmental protection to the blue LED chip 1256. As illustrated, the package 1212 typically comprises respective anode electrical terminals 1222R, 1222G, 1222B and cathode electrical terminals 1224R, 1224G, 1224B allowing electrical power to be independently applied to the anode and cathode of each of the red (R), green (G) and blue (B) LEDs 1252, 1254, 1256. Like lighting device 1050 of FIG. 10, lighting device 1250 can generate colors of light from blue to red as well as different color temperatures of light that—i.e. generate color/color temperature of light within the triangle or lying on the boundary of the triangle on the chromaticity diagram (FIG. 10B).

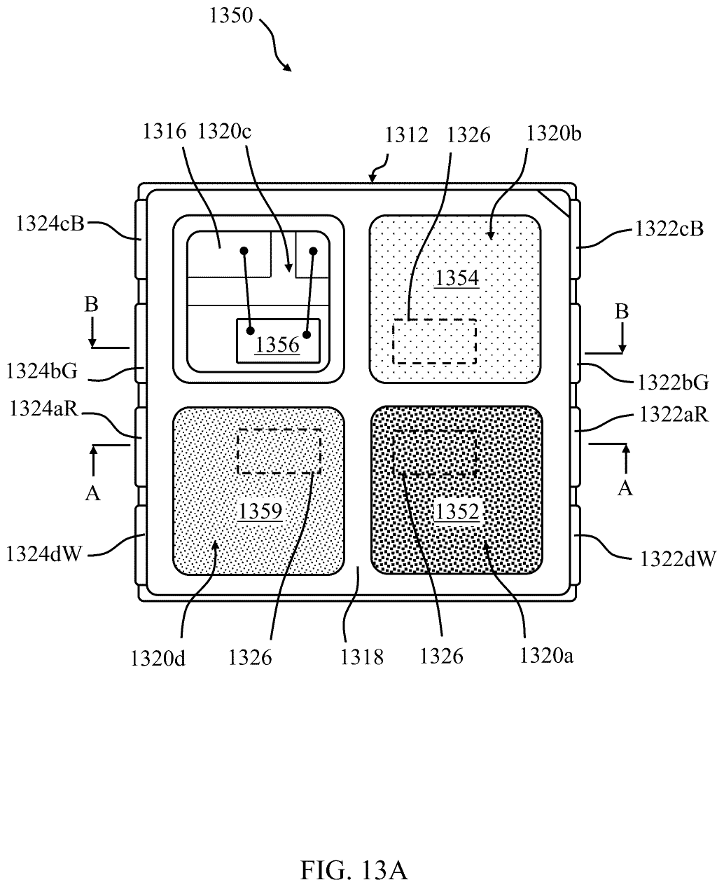

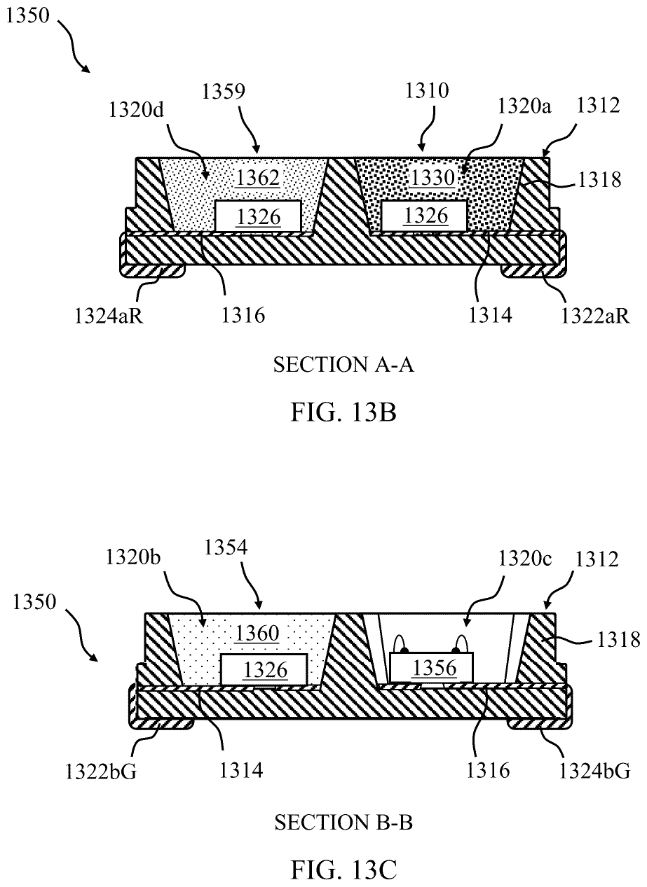

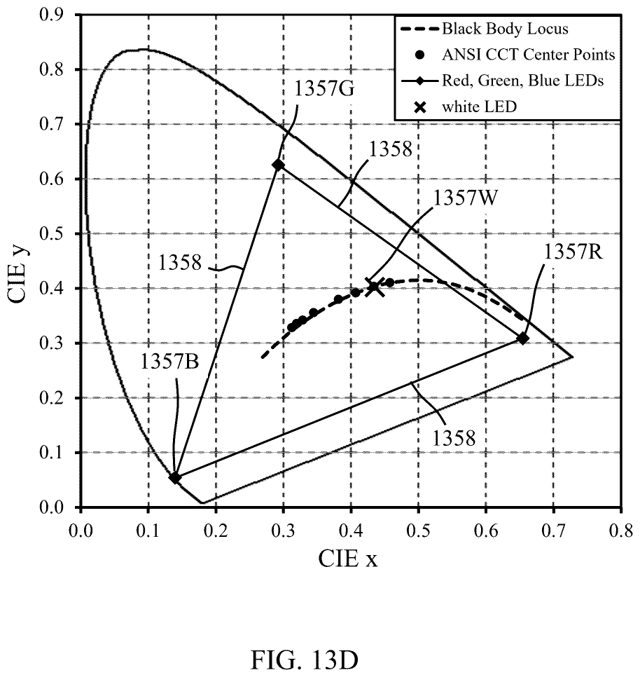

FIGS. 13A to 13C are schematic representations of a color-tunable multi-LED packaged lighting device 1350 comprising a PC Red LED, a Green LED, a blue LED and a PC White LED in accordance with an embodiment of the invention in which FIG. 13A shows a top view, FIG. 13B shows a sectional side view through A-A, and FIG. 13C shows a sectional side view through B-B. The device 1350 comprises a package 1312 comprising a lead frame (anode 1322 and cathode 1324 regions) and a housing 1318 molded onto the lead frame. The housing 1318 comprises a first cavity (cup) 1320a, a second cavity (cup) 1320b, a third cavity (cup) 1320c, and a fourth cavity (cup) 1320d that respectively contain a PC Red LED 1352, a green LED 1354, a blue LED 1356, and a white LED 1359. As illustrated, the package 1314 may comprise a first pair of anode and cathode electrical terminals 1322aR, 1324aR connected to the first cavity 1320a, a second pair of anode and cathode electrical terminals 1322bG, 1324bG connected to the second cavity 1320b, a third pair of anode and cathode electrical terminals 1322cB, 1324cB connected to the third cavity 1320c, and a fourth pair of anode and cathode electrical terminals 1322dW, 1324dW connected to the fourth cavity 1320d allowing electrical power to be independently applied to the anode and cathode of each of the red (R), green (G), blue (B) LEDs, and white (W) LEDs 1352, 1354, 1356, 1359.

As illustrated, the Red LED 1352 may comprise a PC Red LED according to embodiments of the invention such as a single-layer or double-layer red light emitting device such as, for example, the packaged devices of FIGS. 2 to 5 in which the first cavity 1320a contains a violet to blue LED chip 1326 and is filled with narrowband red fluoride and broadband red phosphor photoluminescence layer 1330. As illustrated, the green LED 1354 may comprise a PC Green LED such as for example a packaged device in which the second cavity 1320b contains a violet to blue LED chip 1326 and is filled with green phosphor photoluminescence layer 1360 that covers the blue to violet LED chip 1326. The blue LED 1356 comprises a blue LED chip that generates light with dominant wavelength from 430 nm to 480 nm. The third cavity 1320c may be filled with a light transmissive medium (e.g., silicone) to provide environmental protection to the blue LED chip 1356. As illustrated, the white LED 1359 may comprise a packaged device in which the fourth cavity 1320d contains a violet to blue LED chip 1326 and is filled with green to red phosphor photoluminescence layer 1362 that covers the blue to violet LED chip 1326. The white LED 1359 can be configured to generate Warm White (WW) light with a CCT (Correlated Color Temperature) from 2000K to 4000K.

The lighting device 1350 can generate colors (chromaticities) of light from blue to red as well as different color temperatures of light. FIG. 13D is a CIE 1931 chromaticity diagram illustrating the gamut (color/color temperatures) of light that the light emitting device 1350 can generate. The CIE chromaticity diagram shows the chromaticity (color point) 1357R (solid diamond) of red light generated by the PC Red LED, the chromaticity (color point) 1357G (solid diamond) of green light generated by the PC Green LED, the chromaticity (color point) 1357B (solid diamond) of blue light generated by the Blue LED, and the chromaticity (color point) 1357W (cross) of light generated by the white LED. Straight lines 1358 connecting the points 1357R, 1357G, and 1357B define a triangle that represents the gamut of chromaticities (colors)/color temperatures of light that light emitting device 1350 can generate—i.e., the device can generate any chromaticity (color)/color temperature of light within the triangle or lying on the boundary. It is to be noted that since the color point 1357W for the white LED lies within the triangle, the white LED does not increase the color gamut of the device. The inclusion of a white LED can, however, simplify the generation of light of other color temperatures by the adding of green/blue light to light generated by the white LED and simplify the generation of light with a higher General Color Rendering Index CRI Ra by the adding red light to light generated by the white LED.

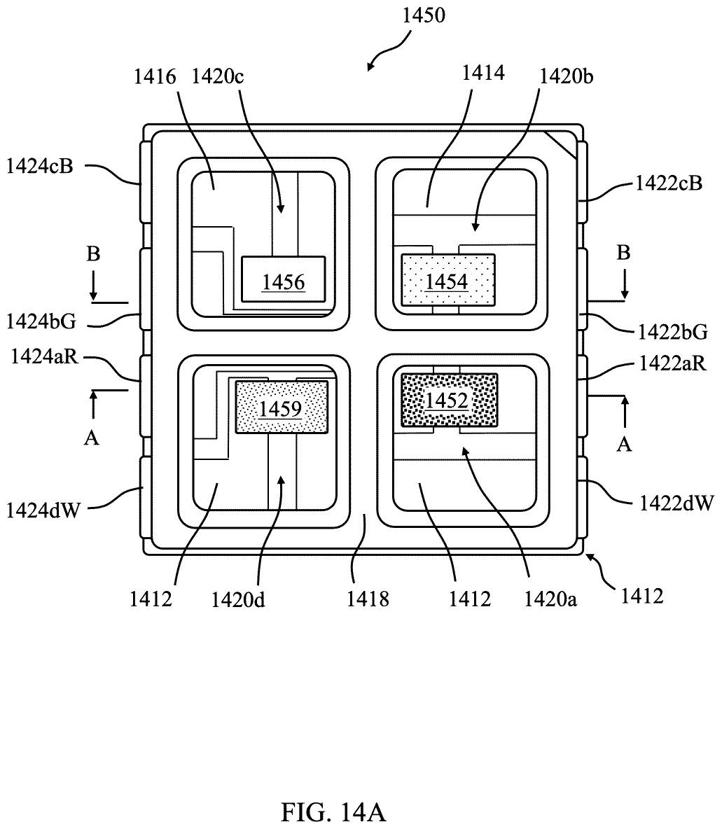

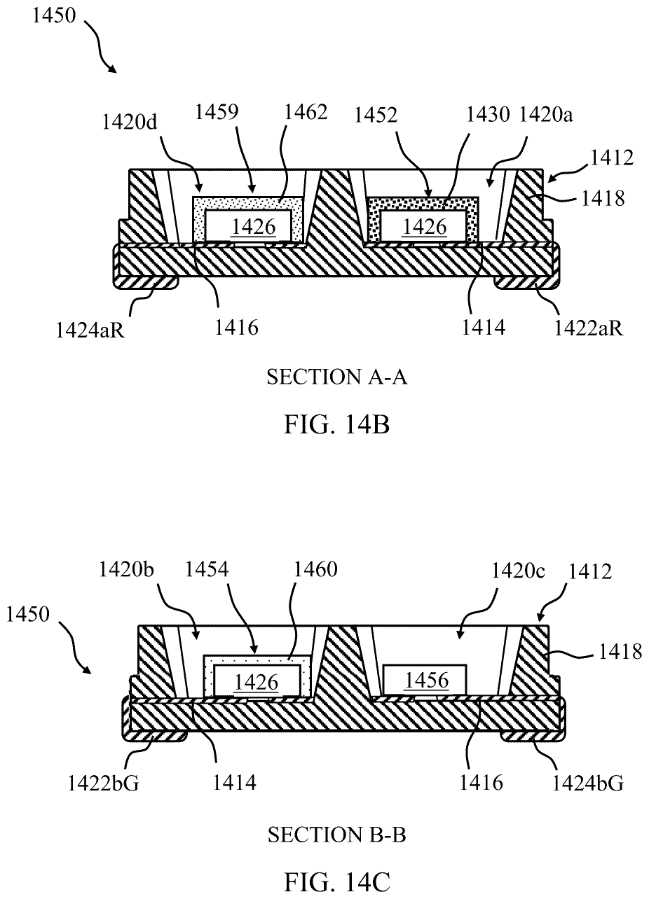

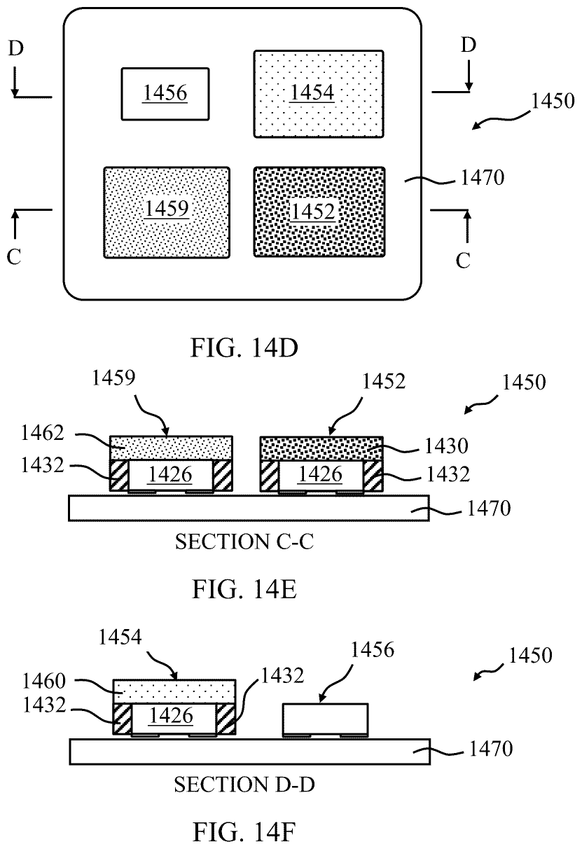

FIGS. 14A to 14C are schematic representations of a color-tunable multi-LED packaged lighting device 1450 comprising a CSP PC Red LED, a CSP PC Green LED, a blue LED flip chip and a CSP White LED in accordance with an embodiment of the invention in which FIG. 14A shows a top view, FIG. 14B shows a sectional side view through A-A, and FIG. 14C shows a sectional side view through B-B. The device 1450 is the same as that of the device 1350 of FIGS. 13A to 13C and comprises Chip Scale Packaged (CSP) LEDs. As illustrated, the Red LED 1452 may comprise a CSP PC Red LED according to embodiments of the invention such as a single-layer or double-layer red light emitting device such as, for example, the CSP devices of FIGS. 6 and 7 in which the CSP PC Red LED comprises a blue to violet LED flip chip 1426 which has layer of narrowband red fluoride and broadband red phosphor photoluminescence layer 1430 on at least a light emitting face of the LED flip chip 1426. The first cavity 1420a may be filled with a light transmissive medium (e.g. silicone) to provide environmental protection to the CSP PC Red LED 1452. As illustrated, the CSP PC green LED 1454 may comprise a violet to blue LED flip chip 1426 which has a green phosphor photoluminescence layer 1460 on at least a light emitting face of the LED flip chip 1426. The second cavity 1420b may be filled with a light transmissive medium (e.g. silicone) to provide environmental protection to the CSP PC Green LED 1454. The blue LED 1456 comprises a blue LED chip that generates light with dominant wavelength from 430 nm to 480 nm. The third cavity 1420c may be filled with a light transmissive medium (e.g. silicone) to provide environmental protection to the blue LED chip 1456. As illustrated, the CSP white LED 1459 may comprise a violet to blue LED flip chip 1426 which has layer of green to red phosphor photoluminescence layer 1462 on at least a light emitting face of the LED flip chip 1426. The fourth cavity 1420d may be filled with a light transmissive medium (e.g., silicone) to provide environmental protection to the CSP white LED 1459. The white LED 1459 can be configured to generate Warm White (WW) light with a CCT (Correlated Color Temperature) from 2000K to 5000K. The package 1412 typically comprises respective anode electrical terminals 1422aR, 1422bG, 1422cB, and 1422dW, and cathode electrical terminals 1424aR, 1424bG, 1424cB, and 1424dW connected to each cavity 1420a, 1420b, 1420c, and 1420d allowing electrical power to be independently applied to the anode and cathode of each of the red (R), green (G), blue (B), and white LEDs 1452, 1454, 1456, 1459. Like lighting device 1350 of FIG. 13A to 13C, lighting device 1450 can generate colors of light from blue to red as well as different color temperatures of light that—i.e., generate color/color temperature of light within the triangle or lying on the boundary of the triangle on the chromaticity diagram (FIG. 10B).

As described herein, when the LEDs (Red, Green, Blue, White) comprise CSP LED (i.e., CSP PC Red, CSP PC Green, CSP White LED) or Direct Emitting (DE) LEDs (i.e. DE green LED, DE Blue LED) the LEDs may be mounted on a substrate such as a printed circuit board, a so-called Chip On Board (COB) packaging arrangement. FIGS. 14D to 14F are schematic representations of a color-tunable multi-LED COB lighting device comprising a CSP PC Red LED, a CSP PC Green LED, a blue LED flip chip and a CSP White LED in accordance with an embodiment of the invention in which FIG. 14D shows a top view FIG. 14E shows a sectional side view through C-C and FIG. 14F shows a sectional side view through D-D. The lighting device 1450 comprises a substrate 1470, for example a printed circuit board, with a CSP PC Red LED 1452, a CSP PC Green LED 1454, a blue LED flip chip 1456 and a CSP White LED 1459 mounted on the same face. As illustrated, the Red LED 1452, Green LED 1454, blue LED 1456 and white LED 1459 may be configured on the substrate as a square array. The Red LED 1452 may comprise a CSP PC Red LED according to embodiments of the invention such as a single-layer or double-layer red light emitting device such as, for example, the CSP devices of FIGS. 6 and 7 in which the CSP PC Red LED comprises a blue to violet LED flip chip 1426 which has layer of narrowband red fluoride and broadband red phosphor photoluminescence layer 1430 on at least a light emitting face of the LED flip chip 1426. The CSP PC green LED 1454 may comprise a violet to blue LED flip chip 1426 which has a green phosphor photoluminescence layer 1460 on at least a light emitting face of the LED flip chip 1426. The blue LED 1456 comprises a blue LED flip chip that generates light with dominant wavelength from 430 nm to 480 nm. The CSP white LED 1459 may comprise a violet to blue LED flip chip 1426 which has layer of green to red phosphor photoluminescence layer 1462 on at least a light emitting face of the LED flip chip 1426. The white LED 1459 can be configured to generate Warm White (WW) light with a CCT (Correlated Color Temperature) from 2000K to 5000K. As illustrated, the Red LED 1452, Green LED 1454, and White LED 1459 a light reflective layer 1432, for example white silicone or epoxy, covering the four side faces of the LED chip 1426 to prevent emission of excitation light therefrom. Like lighting device 1250 of FIG. 12, lighting device 1450 can generate colors of light from blue to red as well as different color temperatures of light that—i.e., generate color/color temperature of light within the triangle or lying on the boundary of the triangle on the chromaticity diagram (FIG. 10B).

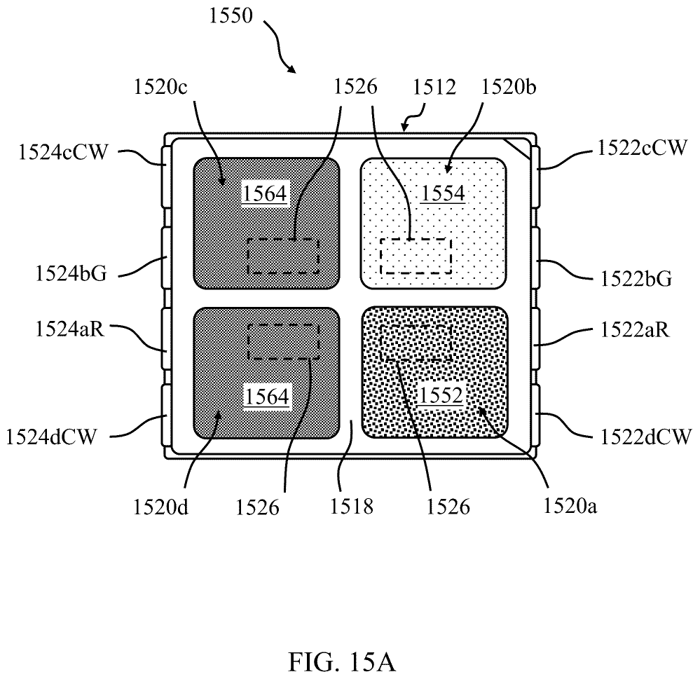

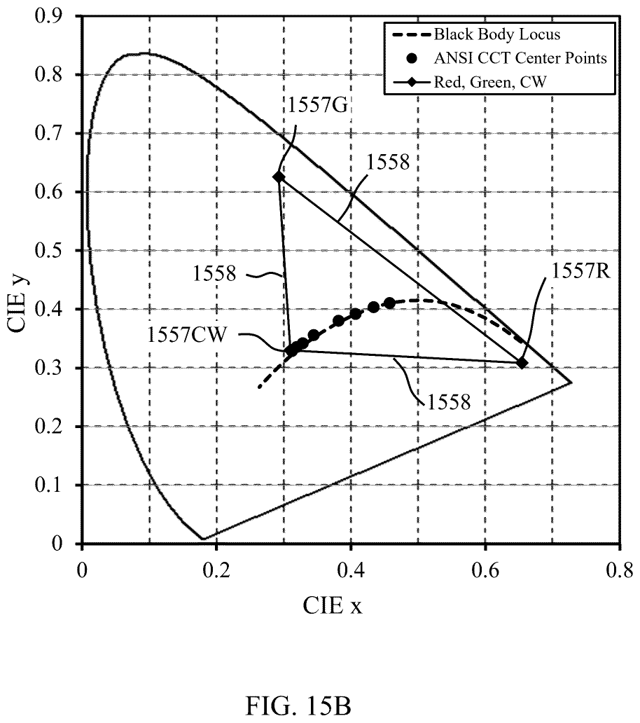

FIGS. 15A is a schematic top view of a color-tunable multi-LED packaged lighting device 1550 comprising a PC Red LED, a PC Green LED, and two Cool White (CW) LEDs in accordance with an embodiment of the invention. The lighting device 1550 comprises a package 1512 comprising a lead frame and a housing 1518 molded onto the lead frame. The housing 1518 comprises a first cavity (cup) 1520a, a second cavity (cup) 1520b, a third cavity (cup) 1520c, and a fourth cavity (cup) 1520d that respectively contain a PC Red LED 1552, a PC Green LED 1554, a first CW LED 1564, and a second CW LED 1564. As illustrated, the Red LED 1552 may comprise a PC Red LED according to embodiments of the invention such as a single-layer or double-layer red light emitting device such as for example the packaged devices of FIGS. 2 to 5 in which the first cavity 1520a contains a violet to blue LED chip 1526 and is filled with narrowband red fluoride and broadband red phosphor photoluminescence layer that covers the violet to blue LED chip 1526. As illustrated, the green LED 1554 may comprise a PC Green LED such as for example a packaged device in which the second cavity 1520b contains a violet to blue LED chip 1526 and is filled with green phosphor photoluminescence layer that covers the violet to blue LED chip 1526. As illustrated, the first and second CW LEDs 1564 may comprise a packaged device in which the third and fourth cavities 1520c, 1520d each contain a violet to blue LED chip 1526 and is filled with green to yellow phosphor photoluminescence layer that cover the violet to blue LED chip 1526. The first and second CW LEDs 1564 can be configured to generate cool white light with a CCT (Correlated Color Temperature) from 5000K to 8000K. The first and second CW LEDs 1564 may generate CW light of the same CCT or CW light of different CCTs. The package 1512 typically comprises respective anode electrical terminals 1522aR, 1522bG, 1522cCW, and 1522dCW and cathode electrical terminals 1524aR, 1524bG, 1524cCW, and 1524dCW connected to each cavity 1520 allowing electrical power to be independently applied to the anode and cathode of each of the red (R), green (G), and first and second CW LEDs 1552, 1554, 1564.

The lighting device 1550 can generate colors of light from green to red as well as different color temperatures of light. FIG. 15B is a CIE 1931 chromaticity diagram illustrating the gamut (color/color temperatures) of light that the light emitting device 1550 can generate. The CIE chromaticity diagram of shows the chromaticity (color point) 1557R (solid diamond) of red light generated by the PC Red LED, the chromaticity (color point) 1557G (solid diamond) of green light generated by the PC Green LED, and the chromaticity (color point) 1557CW (solid diamond) of light generated by the CW LEDs. Straight lines 1558 connecting the points 1557R, 1557G, and 1557CW define a triangle that represents the gamut of chromaticities (colors)/color temperatures (chromaticity) of light that light emitting device 1550 can generate—i.e., the device can generate any chromaticity (color)/color temperature of light within the triangle or lying on the boundary. The inclusion of the CW LEDs can simplify the generation of light of other color temperatures by the adding of green/red light to light generated by the CW LEDs.

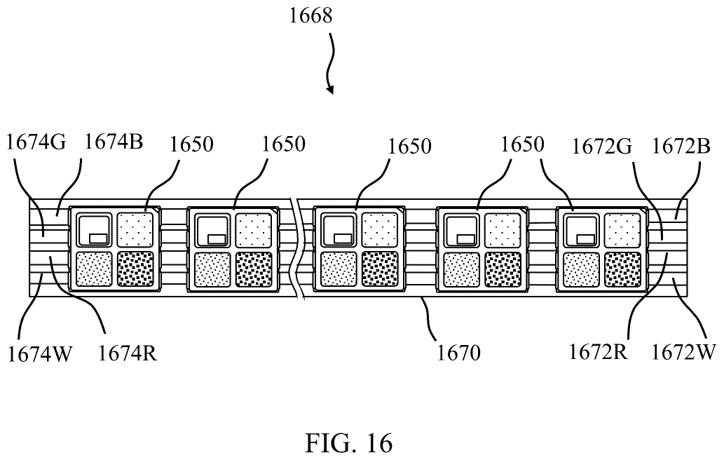

FIG. 16 is a schematic top view of a color-tunable linear light emitting device 1668 in accordance with an embodiment of the invention. The color-tunable linear lighting device 1668 comprises a linear (elongate) substrate 1670, such as for example a strip of Metal Core Printed Circuit Board (MCPCB) or a strip of flexible circuit board, and a plurality of color-tunable multi-LED lighting devices 1650 mounted on and electrically connected to the substrate. As illustrated, the color-tunable multi-LED lighting devices 1650 can be arranged as a linear array in a direction of elongation of the substrate. For the purposes of illustration only, the color-tunable multi-LED lighting devices 1650 are shown as comprising the packaged lighting device of FIGS. 13A to 13C and comprise a PC Red LED (R), a Green LED (G), a blue LED (B) and a White LED (W). It will be appreciated that the lighting devices 1650 may comprise other color-tunable multi-LED lighting emitting devices as described herein. Each LED of a given color may be electrically connected in series with anode electrical connectors 1672R, 1672G, 1672B, and 1672W and cathode electrical connectors 1674R, 1674G, 1674B, and 1674W for each string of LEDs at opposite ends of the substrate.

### Experimental Test Data

In this specification, Pack.# is used to denote a color-tunable multi-LED plighting device (lighting device) in accordance with the invention.

A color-tunable multi-LED packaged lighting device, denoted Pack.1, comprises the device of FIGS. 13A to 13C and comprises a 3838 four cavity (cup) package containing a PC Red LED, a PC Green LED, a blue LED, and a PC white LED. The PC Red LED in the first cavity comprises a single-layer structure comprising a mixture of KSF (K₂SiF₆:Mn⁴⁺) narrowband red fluoride phosphor and CASN (Ca₁₋ₓSrₓAlSiN₃:Eu) broadband red phosphor. The red phosphors (KSF and CASN) are incorporated in a phenyl silicone and the mixture dispensed into the first cavity of the package to completely cover the violet to blue InGaN LED chip. The Green LED in the second cavity comprises a PC Green LED that comprises a violet to blue InGaN LED chip and a green silicate phosphor. The green phosphor ((Ba,Sr)₂SiO₄) is incorporated in a phenyl silicone and the mixture dispensed into the second cavity of the package to cover the violet to blue InGaN LED chip. The blue LED in the third cavity comprises a InGaN blue LED chip. The white LED in the fourth cavity comprises a single-layer PC white LED comprising a mixture of green to red photoluminescence materials (e.g. (Ba,Sr)₂SiO₄ and CASN). The green to red phosphors are incorporated in a phenyl silicone and the mixture dispensed into the fourth cavity of the package to cover the violet to blue InGaN LED chip.

The color-tunable multi-LED lighting devices of the present invention comprising four individual LEDs (Red, Green, Blue, and White) use four independent currents to drive the individual LEDs. When generating white light of different CCTs, light generated by the white LED can be combined with light from the Red LED and/or Green LED and/or Blue LED at different ratio to generate light of any CIE white color point lying on the black body locus which is desirable for meeting ANSI lighting Standards. In contrast, current smart lighting products use one cool white (CW) LED and one warm white (WW) LED and do not additionally blend light from RGB LEDs. Such smart lighting products are capable of tuning the CIE white color point along a straight line connecting the CIE CW color point to the CIE WW color point; for example, CCTs from 2700K (WW) to 6500K (CW). For CIE points between the CIE CW and CIE WW color points, especially those at the midpoint between the color points for CCTs around 4000K, the CIE color point deviates substantially from the blackbody locus. As a result, current smart lighting products cannot generate light with a CIE white color point lying on the blackbody locus over their color temperature operating range and struggle to meet ANSI lighting Standards.

TABLE 4 tabulates measured optical characteristics of the PC Red LED (R), PC Green LED (G), Blue LED (B), and White LED (W) of color-tunable multi-LED packaged lighting device Pack.1. As will be noted from TABLE 4, the PC Red LED generates red light with a dominant wavelength (λ_{d}) of 622 nm and a color purity of 90%, the PC Green LED generates green light with a dominant wavelength of 547 nm and a color purity of 80%, and the blue LED generates blue light with a dominant wavelength of 467 nm and a color purity of 99%. The white LED generates warm white (WW) light with a CCT of 3000K and a general Color Rendering Index (CRI Ra) of 70. For comparison, light generated by the white LED has a dominant wavelength of 585 nm and a color purity of 52%.

TABLE 4
Pack. 1: Measured optical characteristics of PC Red LED (R),
PC Green LED (G), Blue LED (B), and White LED (W)
Measurement: 0.4 W and I_{F} = 120 mA

| | λ_{d} | CIE | | Flux | Color |
|---|---|---|---|---|---|
| LED | (nm) | x | y | (lm) | purity |
| R | 622 | 0.6541 | 0.3084 | 14.8 | 90% |
| G | 547 | 0.2924 | 0.6255 | 64.5 | 80% |
| B | 467 | 0.1396 | 0.0539 | 9.6 | 99% |
| W | 585 | 0.4350 | 0.3068 | 56.1 | 52% |

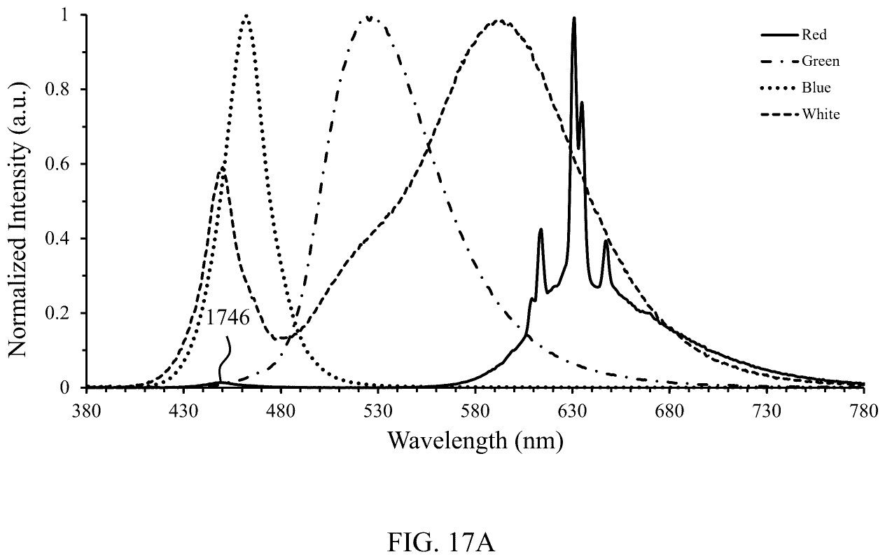

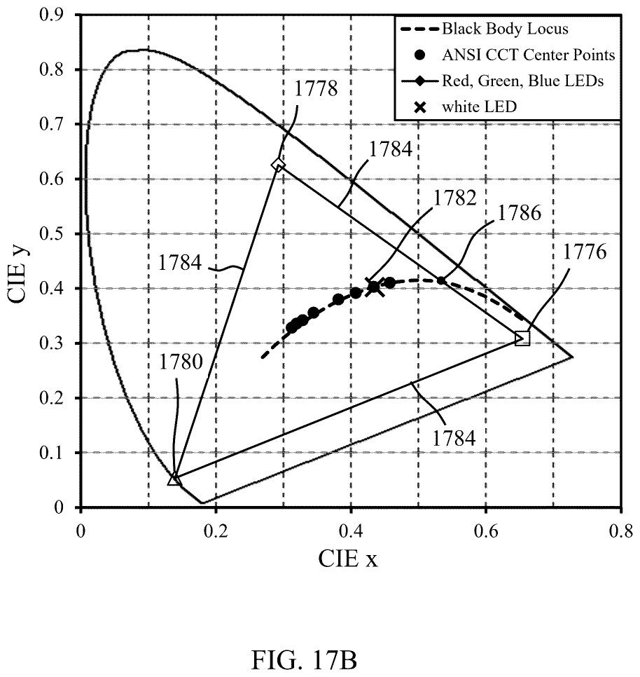

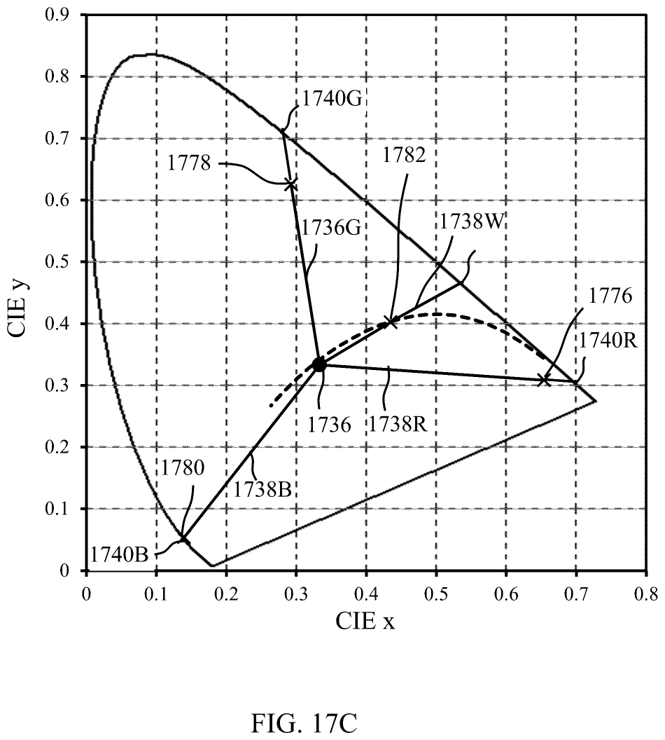

FIG. 17A to 17C are measured optical characteristics for the color-tunable multi-LED packaged lighting device (Pack.1) in which FIG. 17A shows spectra, normalized intensity (a.u.) versus wavelength (nm), for the PC Red LED (thick solid line), the PC Green LED (dashed dotted line), the Blue LED (dotted line) and the White LED (dashed line), FIG. 17B is a CIE 1931 chromaticity diagram illustrating the chromaticity (color point) of light generated by the PC Red LED (square), the PC Green LED (diamond), the Blue LED (triangle), the White LED (cross), ANSI CCT center points (solid circle), color gamut of device (solid line), and black body locus (dashed line), and FIG. 17C is a CIE 1931 chromaticity diagram illustrating calculation of color purity of light generated by the PC Red LED, PC Green LED, the Blue LED, and the White LED.

Referring to FIG. 17A, The PC Red LED shows a low intensity blue peak 1746 at about 449 nm corresponding to a small amount of “blue pass through”. The CIE chromaticity diagram of FIG. 17B shows the chromaticity (color point) 1776 (square) of red light generated by the PC Red LED, the chromaticity (color point) 1778 (diamond) of green light generated by the PC Green LED, the chromaticity (color point) 1780 (triangle) of blue light generated by the Blue LED, and the chromaticity (color point) 1782 (cross) of light generated by the White LED. Straight lines 1784 connecting the points 1776, 1778, and 1780 define a triangle that represents the gamut of colors/color temperatures (chromaticity) of light that lighting device Pack.1 can generate—i.e., the device can generate any color/color temperature of light lying on or within the triangle. It is to be noted that lowest CCT of light that the device can generate that lies on the black body locus (dashed line) is about 2240K which corresponds to the point of intersection 1786 (CIE 0.6540, 0.3085) of line 1784 connecting color points 1776 and 1778 with the black body locus.

The CIE chromaticity diagram of FIG. 17C illustrates calculation of color purity of light generated by the PC Red LED, PC Green LED, Blue LED, and White LED. As described herein, color purity, or color saturation, provides a measure of how close the color hue of light of a given color (chromaticity) is to a spectral (monochromatic) color corresponding to light of dominant wavelength λ_{d}. As shown in FIG. 17C, the chromaticity (color point) 1776, 1778, 1780 and 1782 for PC Red LED, PC Green, Blue LED and White LED are indicated on the chromaticity diagram by a cross and a “white standard illuminant”, CIE (1/3, 1/3), is indicated by dot 1736. A respective straight line 1738R, 1738G, 1738B, 1738W connecting each color point 1776, 1778, 1780 and 1782 to the “white standard illuminant” 1736 is extended so that it intersects the outer curved boundary (perimeter) of the CIE color space. The point of intersection 1740 nearer to the given color point corresponds to the dominant wavelength λ_{d} of the color as the wavelength of the pure spectral (monochromatic) color at that intersection point. The color purity of light of a given chromaticity plotted on the chromaticity diagram is the ratio of the distance from the “white standard illuminant” 1736 to the color point 1776, 1778, 1780 and 1782 to the distance from the “white standard illuminant” 1736 to the point of intersection 1740 (1740R, 1740G, 1740B and 1740W respectively) corresponding to the dominant wavelength λ_{d}. The color purity and dominant wavelength values (λ_{d}) are tabulated in TABLE 4.

TABLE 5 tabulates forward drive current (IF) for PC Red LED (R), PC Green LED (G), Blue LED (B), and White LED (W) of color-tunable multi-LED packaged lighting device Pack.1 for generating light of nominal general color rendering index CRI Ra 90 for nominal color temperatures (CCT) 2700K, 3000K, 4000K, 5000K, 5700K, and 6500K. TABLE 6 tabulates the measured optical and electrical characteristics for the device Pack.1 when operated to generate light of nominal CRI Ra of 90 for nominal color temperatures (CCT) from 2700K to 6500K. As can be seen from TABLE 5, the CCT of light generated by device Pack.1 is increased by a combination of: (i) increasing the blue light content generated by the blue LED, (ii) increasing the green light content generated by the PC Green LED, (iii) decreasing the red-light content generated by the PC Red LED, and (iv) decreasing white light generated by the White LED. TABLE 6 demonstrates that by selection of the drive currents to the PC Red LED, PC Green LED, Blue LED, and White LED, the color-tunable multi-LED packaged lighting device (Pack.1) can generate white light with a CCT from 2700 K to 6500K with a general color rendering index CRI Ra of 90 and CRI R9 of at least 50 with a luminous efficacy from about 114 to about 124 lm/W. TABLE 5 also includes the measured CCT of light generated by Pack.1.

TABLE 5
Pack. 1: Forward drive current I_{F} for PC Red LED (Red), PC Green
LED (Green), Blue LED (Blue), and White LED (White) for
generating light of nominal CRI Ra 90 for nominal CCTs from
2700K to 6500K

| CCT | Forward drive current I_{F} (mA) | | | |
|---|---|---|---|---|
| (K) | Red | Green | Blue | White |
| 2700 | 133 | 43 | 0 | 156 |
| 3000 | 114 | 49 | 8 | 162 |
| 4000 | 71 | 68 | 32 | 156 |
| 5000 | 48 | 79 | 54 | 142 |
| 5700 | 41 | 86 | 68 | 139 |
| 6500 | 35 | 91 | 80 | 126 |

TABLE 6
Pack. 1: Measured characteristics for generating light
of nominal CRI Ra 90 for nominal color temperatures (CCT) from 2700K to 6500K

| CCT | Flux | Power | LE | CIE | | CCT | CRI | | |
|---|---|---|---|---|---|---|---|---|---|
| (K) | (lm) | (W) | (lm/W) | x | Y | (K) | Ra | R9 | Δuv |
| 2700 | 112.2 | 0.99 | 113.7 | 0.4569 | 0.4121 | 2754 | 93.9 | 70.1 | 0.0008 |
| 3000 | 116.0 | 0.99 | 117.6 | 0.4351 | 0.4027 | 3020 | 93.0 | 64.7 | −0.0003 |
| 4000 | 120.7 | 0.97 | 124.1 | 0.3809 | 0.3796 | 4009 | 91.2 | 56.1 | 0.0012 |
| 5000 | 118.8 | 0.96 | 123.9 | 0.3458 | 0.3566 | 4991 | 90.0 | 51.0 | 0.0022 |
| 5700 | 121.6 | 0.99 | 122.6 | 0.3290 | 0.3429 | 5652 | 90.2 | 50.1 | 0.0025 |
| 6500 | 118.2 | 0.99 | 119.6 | 0.3127 | 0.3287 | 6507 | 90.4 | 54.4 | 0.0031 |

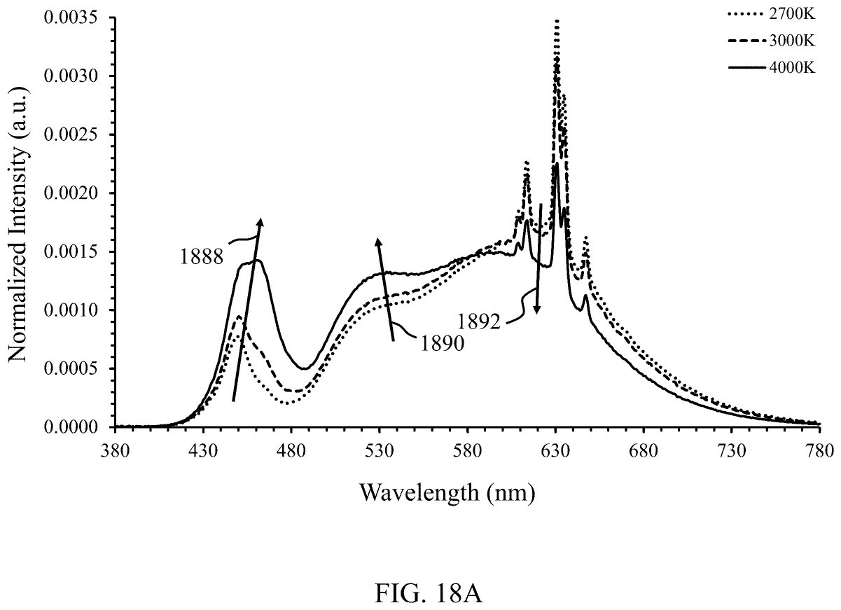

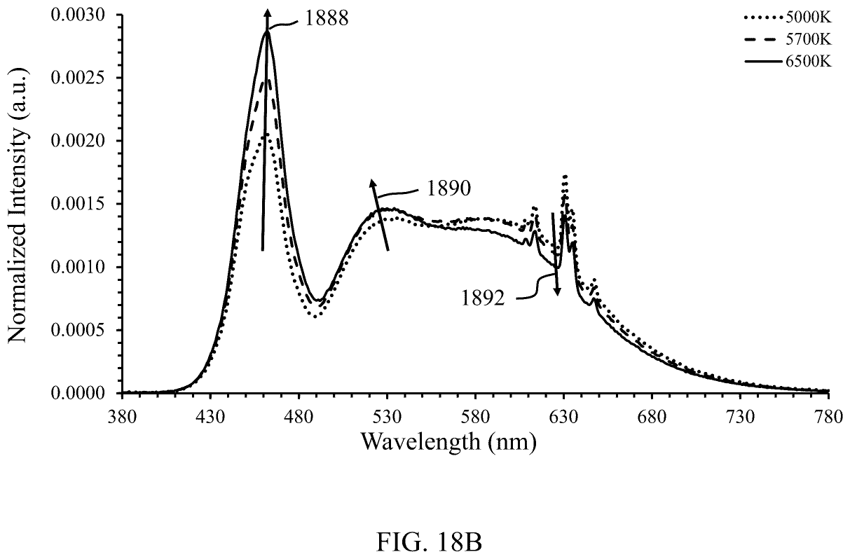

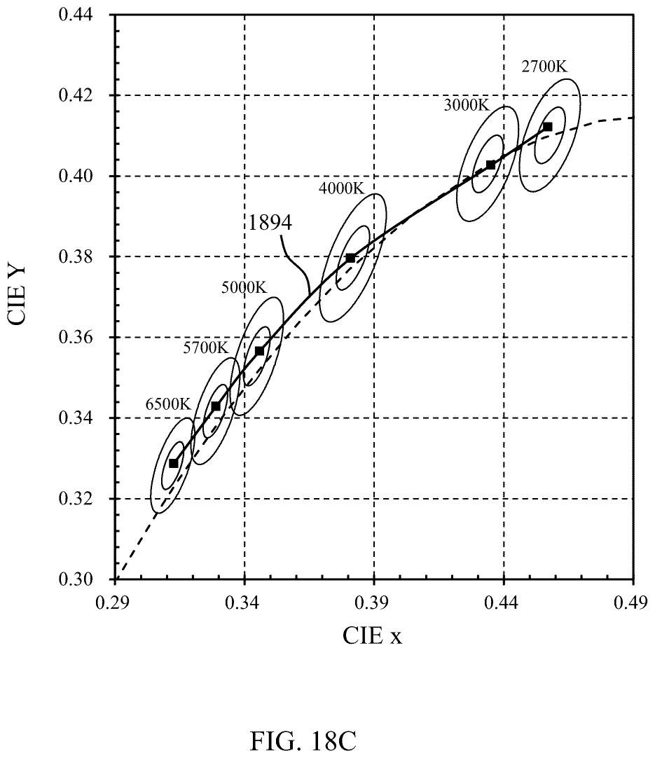

FIG. 18A to 18C are measured emission characteristics for the color-tunable multi-LED packaged lighting device (Pack.1) operable to generate light with a CCT from 2700K to 6500K and a CRI Ra of 90 in which FIG. 18A shows spectra, normalized emission intensity (a.u.) versus wavelength (nm), for a CCT of 2700K (dotted line), a CCT of 3000K (dashed line), and a CCT of 4000K (solid line), FIG. 18B shows spectra, normalized emission intensity (a.u.) versus wavelength (nm), for a CCT of 5000K (dotted line), a CCT of 5700K (dashed line), and a CCT of 6500K (solid line), and FIG. 18C is a CIE 1931 chromaticity diagram illustrating the chromaticity (color point) of light generated by the color-tunable multi-LED packaged lighting device (Pack.1) for nominal CCTs of 2700K, 3000K, 4000K, 5000K, 5700K, and 6500K, light emission locus (solid line) for nominal CCTs from 2700K to 6500K, black body locus (dashed line), and Mac Adam ellipses.

As described herein, the CCT of light generated by device Pack.1 is increased by a combination of: (i) increasing the blue light content generated by the blue LED, (ii) increasing the green light content generated by the PC Green LED, (iii) decreasing the red-light content generated by the PC Red LED, and (iv) decreasing white light generated by the White LED. As can be seen from spectra of FIGS. 18A and 18B, the CCT of light generated by device Pack.1 is increased by a combination of: (i) increasing the blue light content generated by the blue LED as indicated by arrow 1888, (ii) increasing the green light content generated by the PC Green LED as indicated by arrow 1890, and (iii) decreasing the red light content generated by the PC Red LED as indicated by arrow 1892. This being the provision of a synergistic effect.

Referring to FIG. 18C, it is to be noted that light emission locus (solid line 1894)—the chromaticity of light that device Pack.1 is capable of generating—is a curved line that closely follows the black body locus (dashed line). As described herein, Δuv (Delta uv) is a metric that quantifies how close light of a given color temperature is to the black body locus. TABLE 6 tabulates Δuv values for the device Pack.1 operated to generate light with a nominal CRI Ra of 90for nominal CCTs of 2700K, 3000K, 4000K, 5000K, 5700K, and 6500K. As can be seen from the table, Δuv varies from −0.0003 to 0.0031.

TABLE 7 tabulates forward drive current (IF) for PC Red LED (R), PC Green LED (G), Blue LED (B), and White LED (W) of color-tunable multi-LED packaged lighting device Pack.1 for generating light of general color rendering index CRI Ra 95 for nominal color temperatures (CCT) 2700K, 3000K, 4000K, 5000K, 5700K, and 6500K. TABLE 8 tabulates the measured optical and electrical characteristics for the device Pack.1 when operated to generate light of nominal CRI Ra 95 for nominal color temperatures (CCT) from 2700K to 6500K.

As can be seen from TABLE 7, the CCT of light generated by device Pack.1 is increased by a combination of: (i) increasing the blue light content generated by the blue LED, (ii) increasing the green light content generated by the PC Green LED, (iii) decreasing the red-light content generated by the PC Red LED, and (iv) decreasing white light generated by the White LED. TABLE 8 demonstrates that by selection of the drive current to the PC Red LED, PC Green LED, Blue LED, and White LED, the color-tunable multi-LED packaged lighting device (Pack.1) can generate light with a CCT from 2700 K to 6500K with a general color rendering index CRI Ra of 95 and CRI R9 of at least 80 with a luminous efficacy from about 110 to about 115 lm/W.

TABLE 7
Pack. 1: Forward drive current I_{F} for PC Red LED (Red), PC Green LED
(Green), Blue LED (Blue), and White LED (White) for generating
light of nominal CRI Ra 95 for nominal CCTs from 2700K to 6500K

| CCT | Forward drive current I_{F} (mA) | | | |
|---|---|---|---|---|
| (K) | Red | Green | Blue | White |
| 2700 | 143 | 48 | 0 | 144 |
| 3000 | 130 | 58 | 11 | 136 |
| 4000 | 100 | 78 | 34 | 120 |
| 5000 | 78 | 88 | 54 | 106 |
| 5700 | 70 | 92 | 65 | 101 |
| 6500 | 60 | 95 | 78 | 97 |

TABLE 8
Pack. 1: Measured characteristics for generating light
of nominal CRI Ra 95 for nominal color temperatures (CCT) from 2700K to 6500K

| CCT | Flux | Power | LE | CIE | | CCT | CRI | | |
|---|---|---|---|---|---|---|---|---|---|
| (K) | (lm) | (W) | (lm/W) | x | Y | (K) | Ra | R9 | Δuv |
| 2700 | 109.8 | 0.99 | 110.7 | 0.4595 | 0.4140 | 2731 | 95.6 | 79.8 | 0.0013 |
| 3000 | 110.0 | 0.98 | 111.7 | 0.4334 | 0.4024 | 3047 | 96.7 | 86.6 | −0.0002 |
| 4000 | 112.4 | 0.98 | 114.7 | 0.3824 | 0.3805 | 3975 | 97.3 | 92.8 | 0.0012 |
| 5000 | 110.2 | 0.98 | 113.9 | 0.3459 | 0.3553 | 4983 | 96.0 | 94.2 | 0.0015 |
| 5700 | 110.3 | 0.97 | 113.5 | 0.3299 | 0.3434 | 5612 | 96.0 | 92.9 | 0.0023 |
| 6500 | 109.7 | 0.98 | 112.0 | 0.3133 | 0.3275 | 6483 | 95.0 | 93.3 | 0.0021 |

TABLE 8 tabulates Δuv values for the device Pack.1 operated to generate light with a nominal CRI Ra of 95 for nominal CCTs of 2700K, 3000K, 4000K, 5000K, 5700K, and 6500K. As can be seen from the table, Δuv varies from −0.0002 to 0.0023.

It will be evident from the foregoing that color-tunable multi-LED lighting devices according to embodiments of the invention can generate white light of different CCTs and different CRI Ra (e.g., CRI Ra 90 and CRI Ra 95) by changing the forward drive current to the four LEDs (i.e., Red, Green, Blue, and White). Moreover, devices according to the invention have a high luminous efficacy compared with current color-tunable multi-LED packaged lighting devices. This combination of features represents a considerable breakthrough in lighting industry. and significantly reduces the number of SKUs (Stock Keeping Units) of LED devices needed for different lighting applications.

A color-tunable multi-LED packaged lighting device, denoted Pack.2, comprises the device of FIGS. 13A to 13C and comprises a 3838 four cavity package containing a PC Red LED in a first cavity, a PC Green LED in the second cavity, a blue LED in the third cavity, and a PC white LED in the fourth cavity. Details of the PC Red LED, PC Green LED, blue LED, and PC white LED are the same as that of color-tunable multi-LED packaged lighting device Pack.1. In contrast to Pack.1, each InGaN violet to blue LED chip comprises a multi-junction LED chip comprising six junctions, that is each LED chip comprises six LEDs connected in series. The LED chip has a nominal power of 0.5W and a forward drive voltage of about 18V.

TABLE 9 tabulates measured optical characteristics of the PC Red LED (R), PC Green LED (G), Blue LED (B), and White LED (W) of lighting device Pack.2. As will be noted from TABLE 9, the PC Red LED generates red light with a dominant wavelength (λ_{d}) of 619 nm and a flux of 14.9 lm (LE=33.1 lm/W), the PC Green LED generates green light with a dominant wavelength of 547 nm and a flux of 85.8 lm (LE=190.7 lm/W), and the blue LED generates blue light with a dominant wavelength of 456 nm and a flux of 7.6 lm (LE=16.7 lm/W). The white LED generates warm white (WW) light with a nominal CCT of 3000K (actual CCT 2990K, Δuv=0.0015), a General Color Rendering Index (CRI Ra) of about 70, and a flux of 66.0 lm (LE=143.8 lm/W).

TABLE 9
Pack. 2: Measured optical characteristics of PC Red LED (R),
PC Green LED (G), Blue LED (B), and White LED (W)
Measurement: 0.5 W and I_{F} = 25 mA

| | λ_{d} | CIE | | Flux | LE |
|---|---|---|---|---|---|
| LED | (nm) | x | y | (lm) | (lm/W) |
| R | 619 | 0.6598 | 0.3133 | 14.9 | 33.1 |
| G | 547 | 0.2890 | 0.6331 | 85.8 | 190.7 |
| B | 456 | 0.1518 | 0.0279 | 7.6 | 16.7 |
| W | 585 | 0.4399 | 0.4089 | 66.0 | 143.8 |

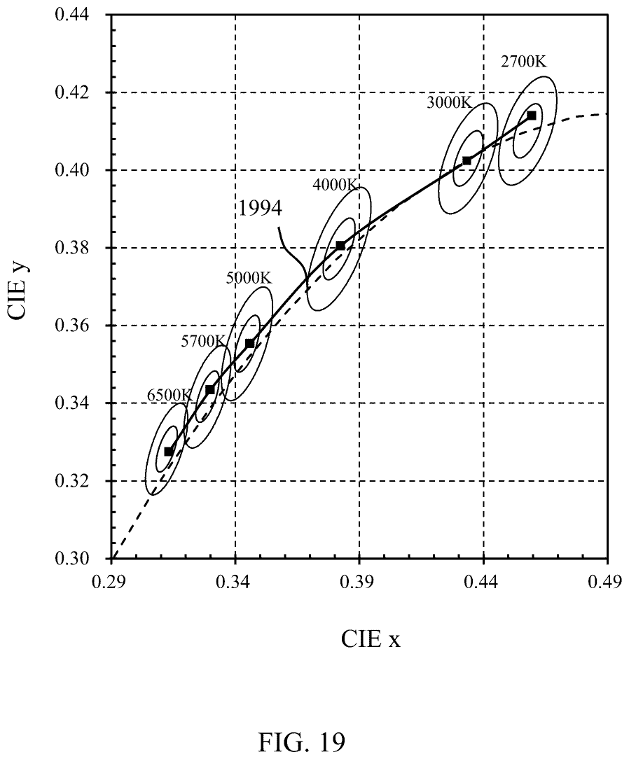

FIG. 19 is a CIE 1931 chromaticity diagram illustrating the chromaticity (color point) of light generated by the PC Red LED (square), the PC Green LED (diamond), the Blue LED (triangle), the White LED (cross), ANSI CCT center points (solid circle), color gamut of device (solid line), and black body locus (dashed line).

The CIE chromaticity diagram of FIG. 19 shows the chromaticity (color point) 1976 (square) of red light generated by the PC Red LED, the chromaticity (color point) 1978 (diamond) of green light generated by the PC Green LED, the chromaticity (color point) 1980 (triangle) of blue light generated by the Blue LED, and the chromaticity (color point) 1982 (cross) of light generated by the White LED. Straight lines 1984 connecting the points 1976, 1978, and 1980 define a triangle that represents the gamut of colors/color temperatures (chromaticity) of light that lighting device Pack.2 can generate—i.e., the device can generate any color/color temperature of light lying on or within the triangle. It is to be noted that lowest CCT of light that the device can generate that lies on the black body locus (dashed line) is about 1762K which corresponds to the point of intersection 1986 (CIE 0.5530, 0.4060) of line 1984 connecting color points 1976 and 1978 with the black body locus.

TABLE 10 tabulates forward drive current (IF) for PC Red LED (R), PC Green LED (G), Blue LED (B), and White LED (W) of lighting device Pack.2 for generating light of nominal general color rendering index CRI Ra 90 for nominal color temperatures (CCT) 2700K, 3000K, 3500K, 4000K, 5000K, 5700K, and 6500K. TABLE 11 tabulates the measured optical and electrical characteristics for the device Pack.2 when operated to generate light of nominal CRI Ra of 90 for nominal color temperatures (CCT) from 2700K to 6500K. As can be seen from TABLE 10, the CCT of light generated by device Pack.2 is increased by a combination of: (i) increasing the blue light content generated by the blue LED, (ii) increasing the green light content generated by the PC Green LED, (iii) decreasing the red-light content generated by the PC Red LED, and (iv) decreasing white light generated by the White LED. TABLE 11 demonstrates that by selection of the drive voltages to the PC Red LED, PC Green LED, Blue LED, and White LED, the color-tunable multi-LED packaged lighting device (Pack.2) can generate white light with a CCT from 2700 K to 6500K with a general color rendering index CRI Ra of 90 and CRI R9 of at least 50 with a luminous efficacy from about 124 lm/W to about 145 lm/W. TABLE 11 also includes the measured CCT of light generated by Pack.2.

TABLE 10
Pack.2: Forward drive current I_{F} for PC Red LED (Red), PC Green LED
(Green), Blue LED (Blue), and White LED (White) for generating light
of nominal CRI Ra 90 for nominal CCTs from 2700K to 6500K
Measurement: 0.5 W and V_{F} ≈ 18 V

| CCT | Forward drive current I_{F} (mA) | | | |
|---|---|---|---|---|
| (K) | Red | Green | Blue | White |
| 2700 | 12.5 | 2.8 | 0.16 | 14.2 |
| 3000 | 11.1 | 3.7 | 0.70 | 14.2 |
| 3500 | 8.9 | 4.4 | 1.30 | 13.2 |
| 4000 | 7.9 | 5.2 | 1.95 | 11.6 |
| 5000 | 7.0 | 6.8 | 3.25 | 9.6 |
| 5700 | 6.1 | 7.5 | 4.00 | 9.0 |
| 6500 | 6.0 | 8.1 | 4.80 | 7.7 |

TABLE 11
Pack. 2: Measured characteristics for generating light
of nominal CRI Ra 90 for nominal color temperatures (CCT) from 2700K to 6500K

| CCT | Flux | Power | LE | CIE | | CCT | CRI | | |
|---|---|---|---|---|---|---|---|---|---|
| (K) | (lm) | (W) | (lm/W) | x | Y | (K) | Ra | R9 | Δuv |
| 2700 | 63.0 | 0.507 | 124.2 | 0.4572 | 0.4136 | 2761 | 90.8 | 55.4 | 0.0013 |
| 3000 | 65.7 | 0.506 | 129.8 | 0.4329 | 0.4052 | 3078 | 90.7 | 56.5 | 0.0010 |
| 3500 | 64.7 | 0.469 | 138.0 | 0.4079 | 0.3941 | 3471 | 90.6 | 58.4 | 0.0009 |
| 4000 | 63.0 | 0.446 | 141.2 | 0.3841 | 0.3805 | 3930 | 91.0 | 64.1 | 0.0007 |
| 5000 | 64.0 | 0.443 | 144.6 | 0.3466 | 0.3577 | 4965 | 90.9 | 71.4 | 0.0024 |
| 5700 | 64.3 | 0.443 | 145.2 | 0.3294 | 0.3439 | 5633 | 90.1 | 71.5 | 0.0028 |
| 6500 | 63.3 | 0.441 | 143.6 | 0.3130 | 0.3289 | 6489 | 90.5 | 80.7 | 0.0030 |

As described herein, Δuv (Delta uv) is a metric that quantifies how close light of a given color temperature is to the black body locus. TABLE 11 tabulates Δuv values for the device Pack.2 operated to generate light with a nominal CRI Ra of 90 for nominal CCTs of 2700K, 3000K, 3500K, 4000K, 5000K, 5700K, and 6500K. As can be seen from the table, Δuv varies from 0.0007to 0.003.

### Multi-LED Packages

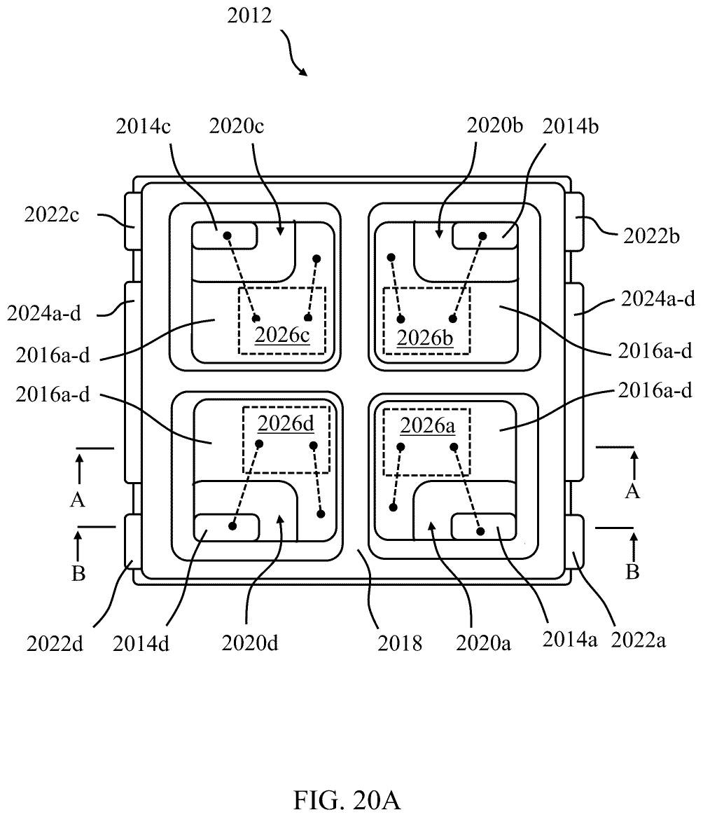

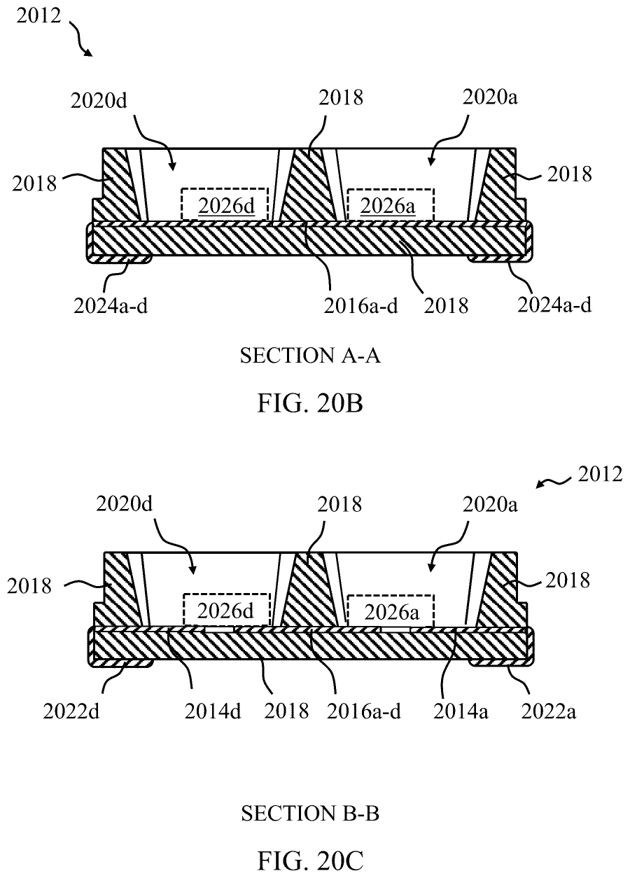

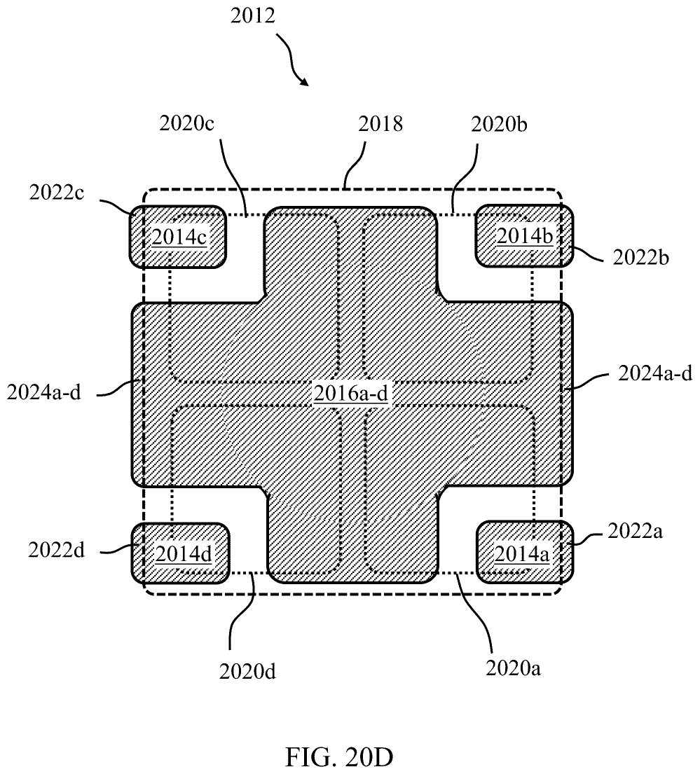

FIGS. 20A to 20D are schematic representation of a multi-LED, multi-cavity, package 2012 in accordance with an embodiment of the invention comprising a common cathode terminal arrangement in which FIG. 20A shows a top view, FIG. 20B shows a sectional side view through A-A, FIG. 20C shows a sectional side view through B-B, and FIG. 20D is a top view of the lead frame of the multi-LED package.

As shown in FIGS. 20A to 20D, the multi-LED package 2012 comprises a lead frame 2014a-2014d, 2016a-d and a housing 2018 molded onto the lead frame. The housing 2018 comprises a first cavity (cup) 2020a for receiving a respective first LED chip 2026a, a second cavity (cup) 2020b for receiving a respective second LED chip 2026b, a third cavity (cup) 2020c for receiving a respective third LED chip 2026c, and a fourth cavity 2020d for receiving a respective fourth LED chip 2026d. The LED chips 2026a-2026d are indicated in FIG. 20A-20C by a dashed rectangle and bond wires connecting the LED chips to the lead frame are indicated by dashed lines.

Referring to FIG. 20D, the various regions of the lead frame 2014a-2014d, 2016a-d are indicated by cross-hatching and the relative position of the housing 2018 and the cavities 2020a-2020d are respectively indicated by dashed and dotted lines. The lead frame comprises a central cross-shaped cathode region 2016a-d and four rectangular anode regions 2014a-2014d located at the empty corners of the cross-shaped region 2016a-d. As can be seen from FIG. 20D, each cavity 2020a-2220d comprises on its floor, a respective L-shaped region of the cross-shaped cathode region 2016a-d which constitutes a common cathode connection to each cavity. The L-shaped cathode region on the floor of each cavity, in addition to providing a common (shared) cathode connection, provides a thermally conductive mounting pad for the LED chip, thereby improving thermal dissipation from the LED chips. As can be seen from FIG. 20D, each cavity 2020a-2020d comprises on its floor, a respective rectangular anode region 2014a-2014d which constitutes an anode connection to the cavity. As illustrated in FIGS. 20A-20D, each respective anode region of the lead frame 2014a-2014d extends beyond an outer edge of the housing 2018 and provides a respective anode electrical terminal 2022a-2022d for each cavity 2020a-2020d. Similarly, the cathode region of the lead frame 2016a-d extends beyond opposing edges of the housing and provides a common cathode electrical terminal 2024a-d on opposite edges of the housing.

As described herein, in embodiments, the multi-LED (e.g., four-LED) package may comprise a single cathode electrical terminal 2024a-d that is common to each LED chip and a respective anode electrical terminal 2022a-2022d for each LED chip. In other embodiments of the invention, the multi-LED package may comprise a respective pair of anode and cathode electrical terminals for each LED. Such an arrangement can be beneficial when using multiple multi-LED packages as it allows the LED chips to be connected in series.

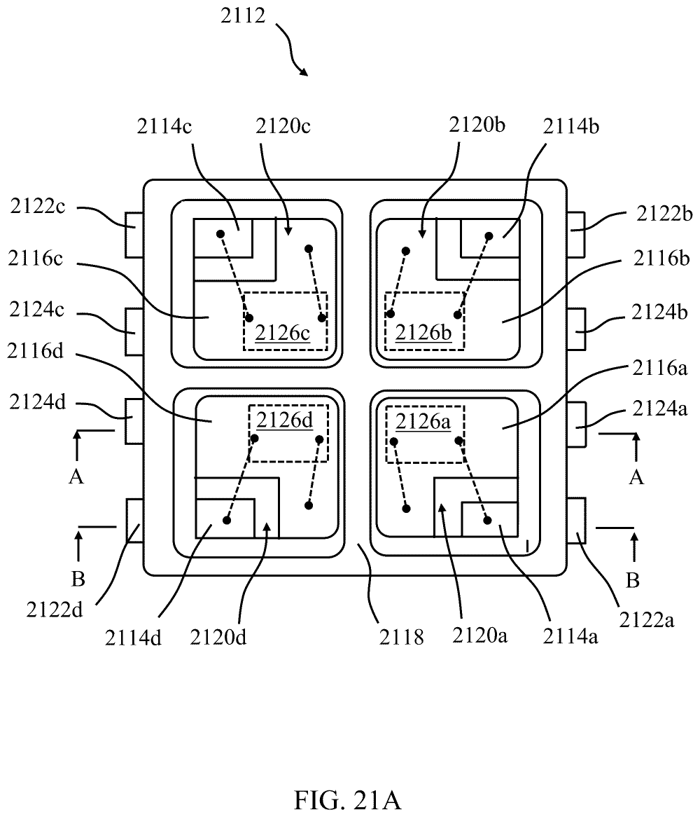

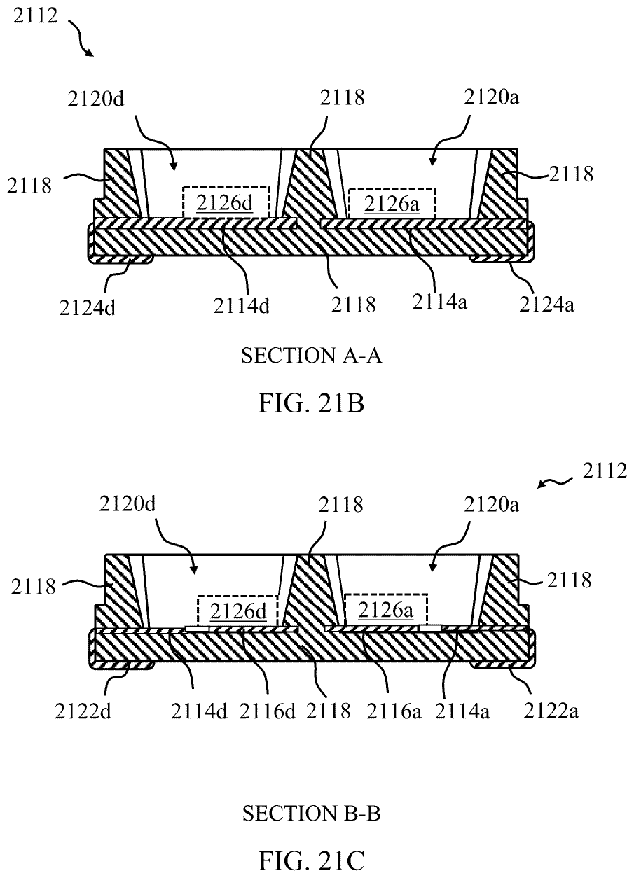

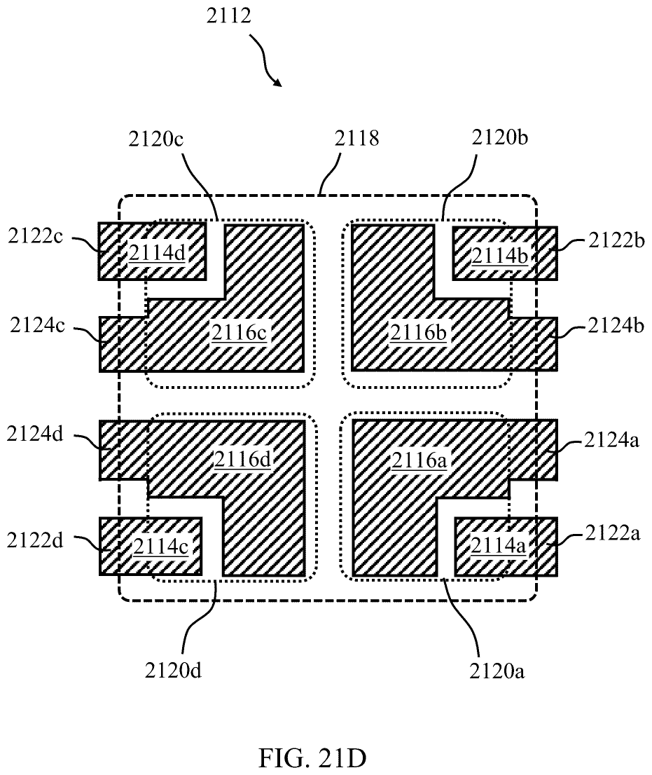

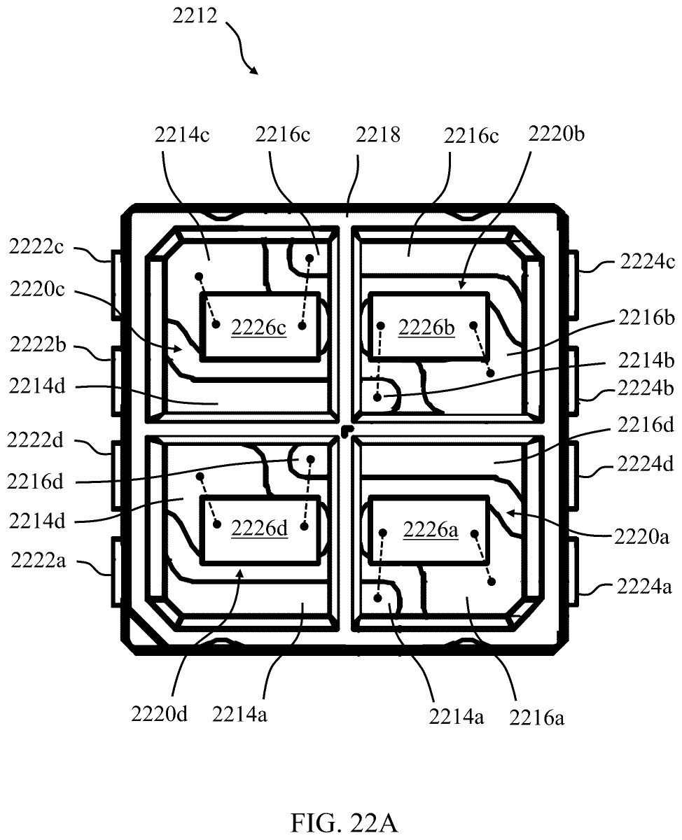

FIGS. 21A to 21D are schematic representations of a multi-LED, four-LED, package in accordance with an embodiment of the invention comprising a respective pair of anode and cathode electrical terminals for each LED in which FIG. 21A shows a top view, FIG. 21B shows a sectional side view through A-A, FIG. 21C shows a sectional side view through B-B, and FIG. 21D is a plan view of the lead frame of the multi-LED package.

As shown in FIGS. 21A to 21D, the multi-LED package 2112 comprises a lead frame 2114a-2114d, 2116a-2116d and a housing 2118 molded onto the lead frame. The housing 2118 comprises a first cavity 2120a for receiving a respective first LED chip 2126a, a second cavity 2120b for receiving a respective second LED chip 2126b, a third cavity 2120c for receiving a respective third LED chip 2126c, and a fourth cavity 2120d for receiving a respective fourth LED chip 2126d. The LED chips 2126a-2126d are indicated in FIG. 21A to 21C by a dashed rectangle and bond wires connecting the LED chips to the lead frame are indicated by dashed lines.

Referring to FIG. 21D, the various regions of the lead frame 2114a-2114d, 2116a-2116d are indicated by cross-hatching and the relative position of the housing 2118 and the cavities 2120a-2120d are respectively indicated by dashed and dotted lines. The lead frame comprises four L-shaped cathode region 2116a-2116d arranged as a cross and four rectangular anode regions 2114a-2114d with a respective anode region located at the empty corners of a respective L-shaped region. As can be seen from FIG. 21D, each cavity 2120a-2120d comprises on its floor, a respective L-shaped cathode region 2116a-2116d and a respective rectangular shaped anode region 2114a-2114d. The L-shaped cathode region on the floor of each cavity, in addition to providing a cathode connection, provides a thermally conductive mounting pad for the LED chip, thereby improving thermal dissipation from the LED chips. As can be seen from FIG. 21D, each cavity 2120a-2120d comprises on its floor, a respective rectangular anode region 2114a-2114d which constitutes an anode connection to the cavity. As illustrated in FIGS. 21A to 21D, each anode region of the lead frame 2114a-2114d extends beyond an outer edge of the housing 2118 and provides a respective anode electrical terminal 2122a-2122d for each cavity 2120a-2120d. Similarly, each cathode region of the lead frame 2116-2116d extends beyond the outer edge of the housing 2118 and provides a respective cathode electrical terminal 2124a-2124d on the same edge of the housing as the anode electrical terminal.

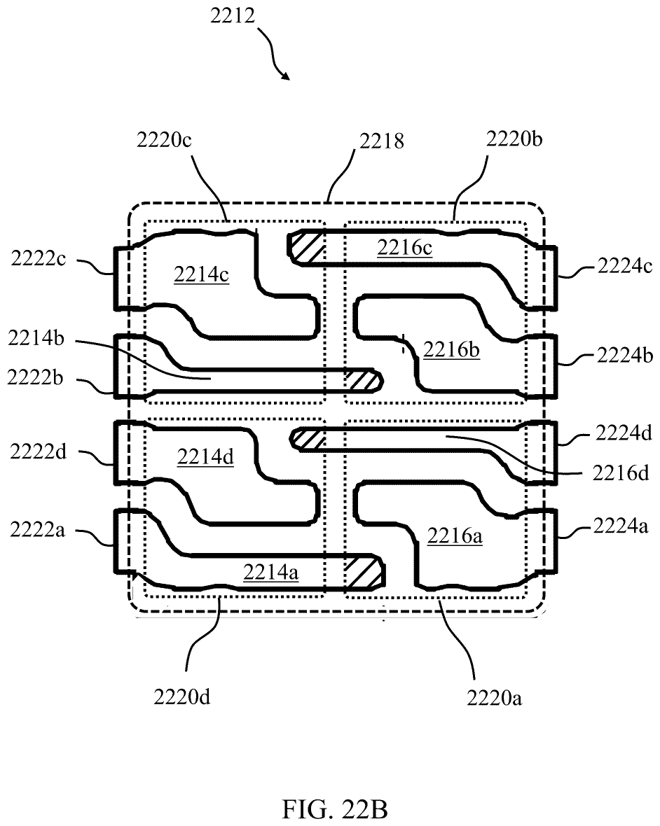

FIGS. 22A and 22B are schematic representations of a multi-LED (Four-LED) package in accordance with another embodiment of the invention in which FIG. 22A shows a top view, and FIG. 22B is top view of the lead frame of the multi-LED package 2212. This embodiment is similar to the multi-LED package of FIGS. 21A-21D, except that the lead frame regions 2214a-2214d and 2216a-2216d are configured such that each anode terminal 2222a-2222d is aligned with and located on an opposing edge of the housing to its respective cathode terminal 2224a-2224d. Such a packaging arrangement can be advantageous in linear lighting arrangements utilizing a plurality of multi-LED packages in which it is preferred to serially connect LEDs of each cavity.

As shown in FIGS. 22A and 22B the multi-LED package 2212 comprises a lead frame 2214a-2214d, 2216a-2216d and a housing 2218 molded onto the lead frame. The housing 2218 comprises a first cavity 2220a for receiving a respective first LED chip 2226a, a second cavity 2220b for receiving a respective second LED chip 2226b, a third cavity 2220c for receiving a respective third LED chip 2226c, and a fourth cavity 2220d for receiving a respective fourth LED chip 2226d. The LED chips 2226a-2226d are indicated in FIGS. 22A and 22B by a dashed rectangle and bond wires connecting the LED chips to the lead frame are indicated by dashed lines. Referring to FIG. 22B, the various regions of the lead frame 2214a-2214d, 2216a-2216d are shown and the relative position of the housing 2218 and the cavities 2220a-2220d are respectively indicated by dashed and dotted lines. The lead frame comprises four cathode regions 2216a-2216d and four anode regions 2214a-2214d. For the first and second cavities 2220a and 2220b, the cathode regions 2216a and 2216b are zigzag shaped and the anode regions 2214a and 2214b are elongate in form. The first and second cavities 2220a and 2220b comprise on their floor, a respective zigzag shaped cathode region 2216a and 2216b and a respective square shaped end portion (indicated by cross hatching) of the elongate anode region 2214a and 2214b. In this embodiment, the elongate anode region 2214a extends from the first cavity 2220a through the fourth cavity 2220d to the opposite edge of the package to that of the corresponding cathode region 2216a. Similarly, the elongate anode region 2214b extends from the second cavity 2220b through the third cavity 2220c to the opposite edge of the package to that of the corresponding cathode region 2216b. In this way, an anode region (for instance, elongate) extends from one cavity to an adjacent cavity. It may be that an anode region is able to extend between at least two, three or more cavities. For the third and fourth cavities 2220c and 2220d, the cathode regions 2216c and 2216d are elongate in form and the anode regions 2214c and 2214d are zigzag shaped. The third and fourth cavities 2220c and 2220d comprise on their floor, a respective square shaped end portion (indicated by cross hatching) of the elongate cathode region 2216c and 2216d. In this embodiment, the elongate cathode region 2216c extends from the third cavity 2220c through the second cavity 2220b to the opposite edge of the package to that of the corresponding anode region 2212c. Similarly, in this embodiment, the elongate cathode region 2216d extends from the fourth cavity 2220d through the first cavity 2220a to the opposite edge of the package to that of the corresponding anode region 2222a. In this way, a cathode region (for instance, elongate) is able to extend from one cavity to an adjacent cavity. The zigzag shaped region on the floor of each cavity, in addition to providing an electrical connection, provides a thermally conductive mounting pad for the LED chip, thereby improving thermal dissipation from the LED chips. As illustrated in FIGS. 22A and 22B, each anode region of the lead frame extends beyond an outer edge of the housing 2218 and provides a respective anode electrical terminal 2222a-2222d for each cavity 2220a-2220d. As illustrated, each of the anode terminals 2222a-2222d is located along the lefthand edge of the package. Similarly, each cathode region of the lead frame extends beyond the outer edge of the housing and provides a respective cathode electrical terminal 2224a-2224d on the opposite edge of the housing to that of the anode electrical terminal. As illustrated, each of the cathode terminals 2224a-2224d is located along the righthand edge of the package. In at least this embodiment, for example, the anode and cathode terminals are aligned (or in the same linear path, for instance).

Multiple Package Color-Tunable Multi-LED Lighting Devices

As described, color-tunable Multi-LED lighting devices in accordance with embodiments of the invention may comprise a Multi-LED (at least Four-LED), Multi-Cavity (at least Four-Cavity) package (e.g., FIGS. 13A to 13C) comprising a Red LED, a Green LED, a blue LED, and a White LED. In other embodiments, color-tunable Multi-LED lighting devices may comprise multiple (e.g., two) Multi-LED (e.g., Two-LED) packages which in combination comprise the Red LED, Green LED, Blue LED, and White LED. Compared with a single Four-LED packaged device, two Two-LED packaged devices can provide a number of benefits including greater reliability and improved thermal management.

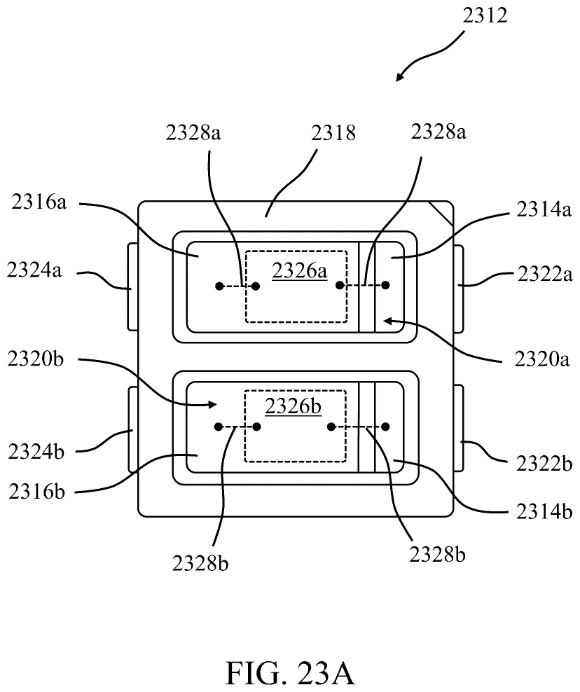

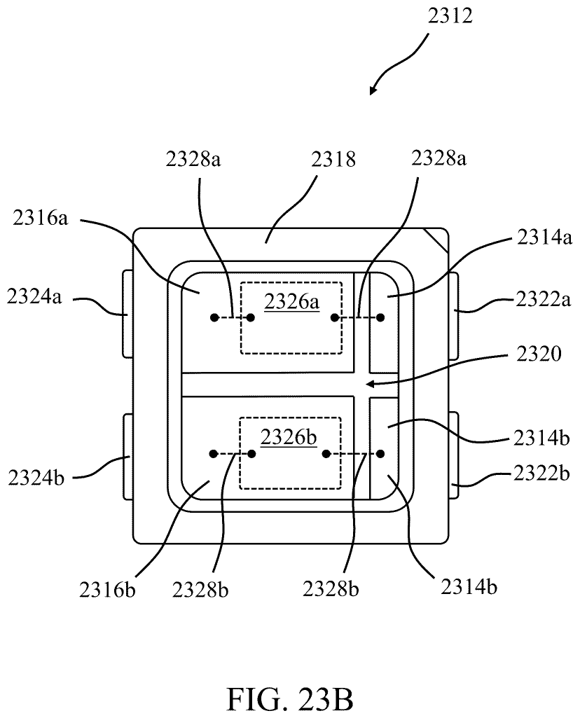

FIGS. 23A and 23B are schematic representations of Two-LED packages in which FIG. 23A shows a top view of a Two-cavity (Dual-cavity) Two-LED package, and FIG. 23B shows a top view of a Single-Cavity Two-LED package.

Referring to FIG. 23A, a Two-Cavity, Two-LED package 2312 comprises a lead frame and a housing 2318 molded onto the lead frame. The housing 2318 comprises a First-Cavity (cup) 2320a for receiving a first LED chip 2326a and a second cavity (cup) 2320b for receiving a second LED chip 2326b. In the figure, the LED chips 2326a and 2326b are indicated by a dashed line rectangle and bond wires 2328 connecting the LED chips to respective anode lead frame regions 2314a, 2314b and cathode lead frame regions 2316a, 2316b located on the floor of a respective cavity are indicated by dashed lines. As illustrated, the package may comprise a first pair of anode and cathode electrical terminals 2322a, 2324a connected to the anode and cathode lead frame regions 2314a, 2316a of the first cavity 2320a and a second pair of anode and cathode electrical terminals 2322b, 2324b connected the anode and cathode lead frame regions 2314b, 2316b of the second cavity 2320b for independently applying electrical power to the first and second LED chips 2326a and 2326b.

Referring to FIG. 23B, a Single-Cavity, Two-LED package 2312 comprises a lead frame and a housing 2318 molded onto the lead frame. The Single-Cavity package of FIG. 23B is essentially the same as the Two-Cavity package of FIG. 23A except that the housing 2318 comprises a single cavity (cup) 2320 for receiving first and second LED chips 2326a, 2326b. In the figure, the LED chips 2326a and 2326b are indicated by a dashed line rectangle and bond wires 2328 connecting the LED chips to respective anode lead frame regions 2314a, 2314b and cathode lead frame regions 2316a, 2316b located on the floor of the cavity 2320 are indicated by dashed lines. The package 2312 may comprise two pairs of anode and cathode electrical terminals 2322a, 2324a and 2314b, 2316b connected to respective anode and cathode lead frame regions 2314a, 2316a and 2314b, 2316b for independently applying electrical power to the first and second LED chips 2326a and 2326b.

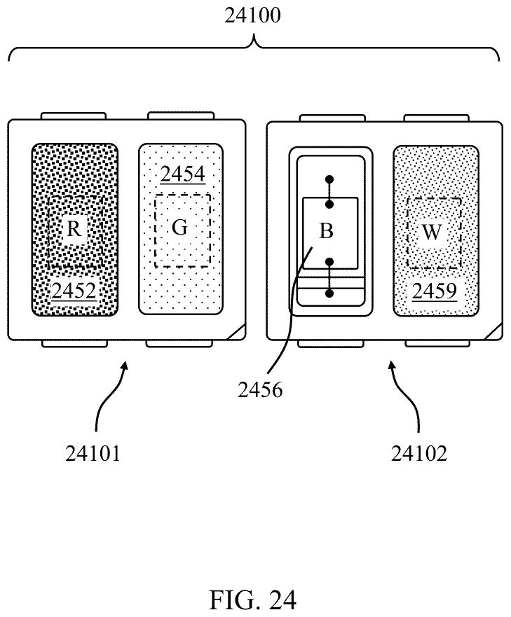

In embodiments, color-tunable Multi-LED lighting devices may comprise first and second Multi-LED (Two-LED) devices using the 2-LED packages of FIGS. 23A and 23B. In an embodiment, as shown in FIG. 24, a color tunable Multi-LED lighting device 24100 can comprise a combination of a first Two-LED packaged device 24101 comprising Red and Green LEDs 2452, 2454 and a second Two-LED packaged device 24102 comprising Blue and White LEDs 2456, 2459.

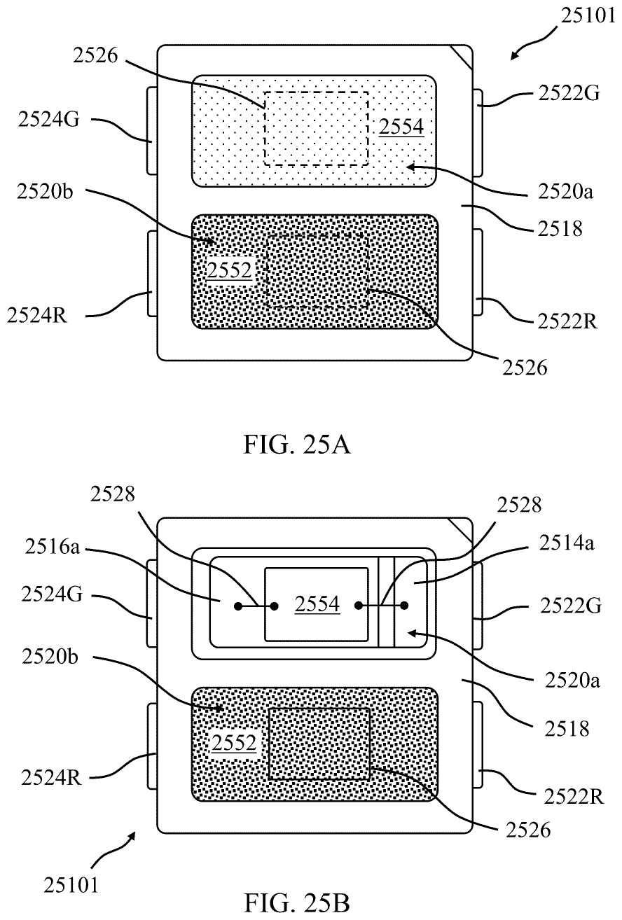

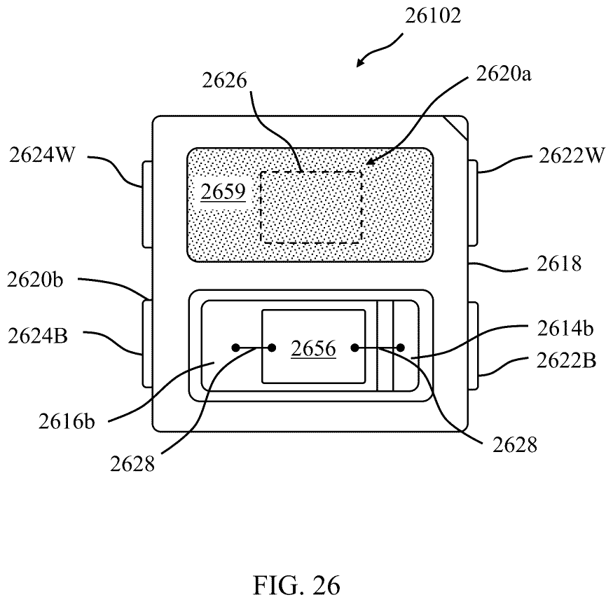

FIGS. 25A and 25B are schematic representations of first Two-LED packaged devices 25101 comprising Red and Green LEDs in which FIG. 25A shows a top view of a first Two-Cavity Two-LED packaged device comprising a PC (Phosphor Converted) Red LED 2552 and a PC (Phosphor Converted) Green LED 2554, and FIG. 25B shows a top view of a first Two-Cavity Two-LED packaged device 25101 comprising a PC (Phosphor Converted) Red LED 2552 and a Direct Emitting Green LED 2554. FIG. 26 shows a schematic top view of a second Two-Cavity Two-LED packaged device 26102 comprising a Direct-Emitting Blue LED 2656 and a PC (Phosphor Converted) White LED 2659.

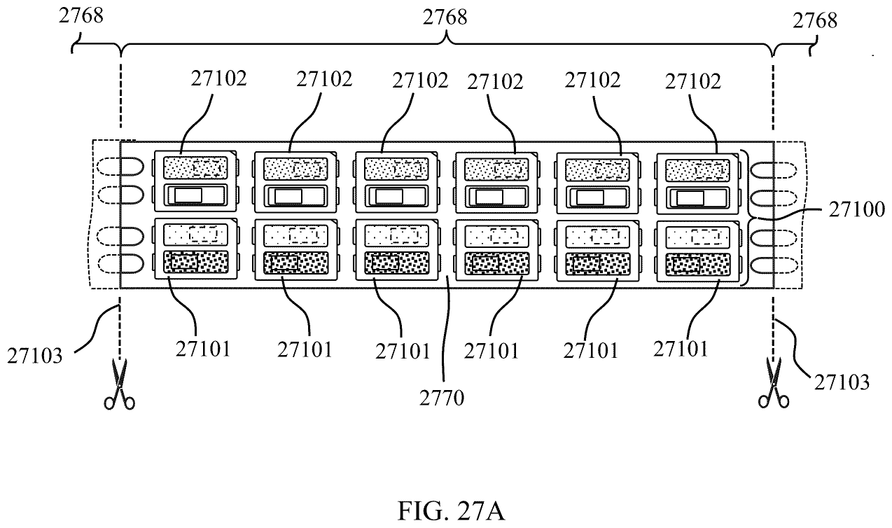

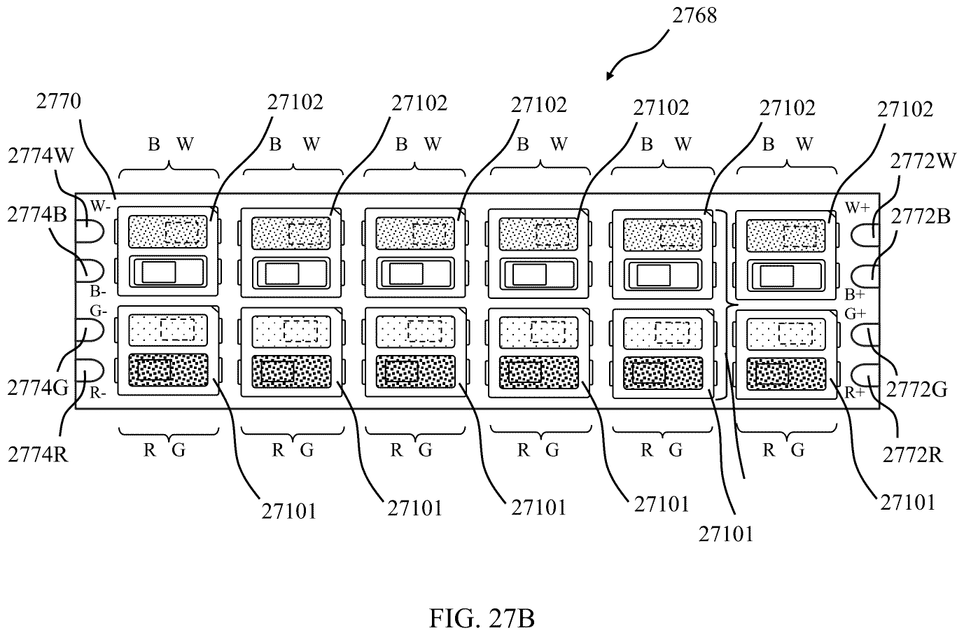

FIGS. 27A and 27B are schematic representations of color-tunable linear lighting devices 2768 in accordance with an embodiment of the invention comprising a plurality of color-tunable Multi-LED lighting devices 27100 (Same as 24100 of FIG. 24) each comprising a combination of the first and second Two-LED packaged devices of FIGS. 25A and 26. The color-tunable linear lighting device 2768 comprises a linear (elongate) substrate 2770, such as for example a tape (strip) of flexible circuit board, and a plurality of first Two-LED packaged devices 27101 and second Two-LED packaged devices 27102 mounted on and electrically connected to the substrate. The first and second Two-LED packaged devices 27101 and 27102 can be arranged as pairs as a linear array in a direction of elongation of the substrate with each LED of a given color being electrically connected in series. As illustrated, each color-tunable linear lighting device 2768 may comprise six pairs of first and second Two-LED packaged devices 27101 and 27102, which when the LEDs of a given color are connected in series gives a nominal forward drive voltage of 18 V. As indicated in FIG. 27A, the tape (flexible substrate) 2770 may comprise a plurality of color-tunable linear lighting device 2768 disposed along the length of the tape (in series or parallel) that can be divided into individual lighting devices by cutting the along cut lines 27103 (dashed line) that passes through the anode electrical connectors 2772R, 2772G, 2772B, and 2772W and cathode electrical connectors 2774R, 2774G, 2774B, and 2774W at distal ends of the substrate 2770 (FIG. 27B). The tape can also be cut into sections comprising multiple color-tunable linear lighting device 2768, for example comprising two lighting devices which may have a forward drive voltage of 36V or 18V depending on whether the section are connected in series or parallel.

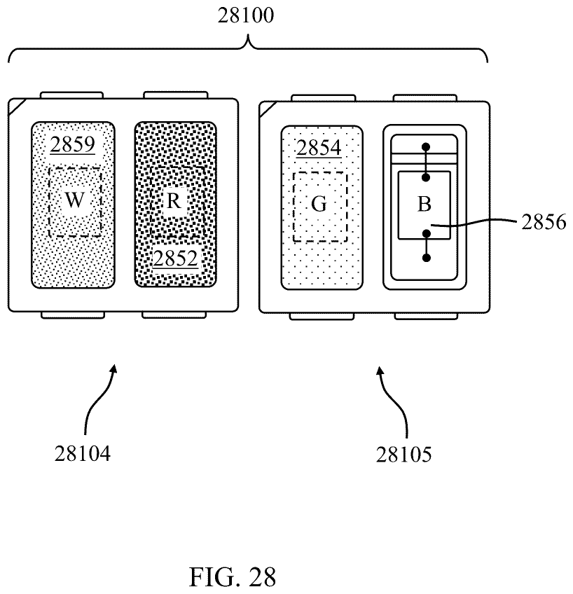

In other embodiments, as shown in FIG. 28, a color tunable Multi-LED lighting device 28100 can comprise a combination of a first Two-LED packaged device 28104 comprising White and Red LEDs 2859, 2852 and a second Two-LED packaged device 28105 comprising Green and Blue LEDs 2854, 2856.

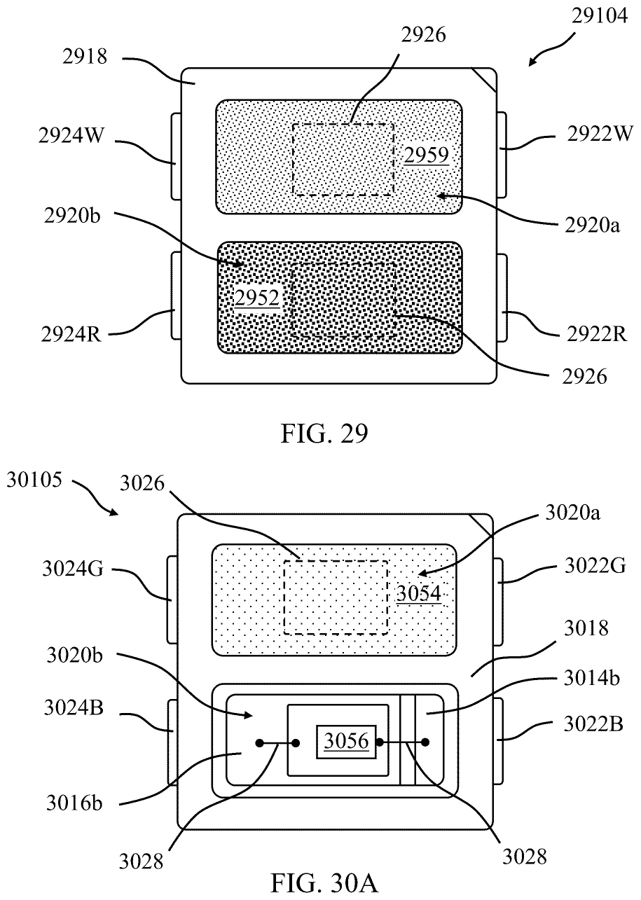

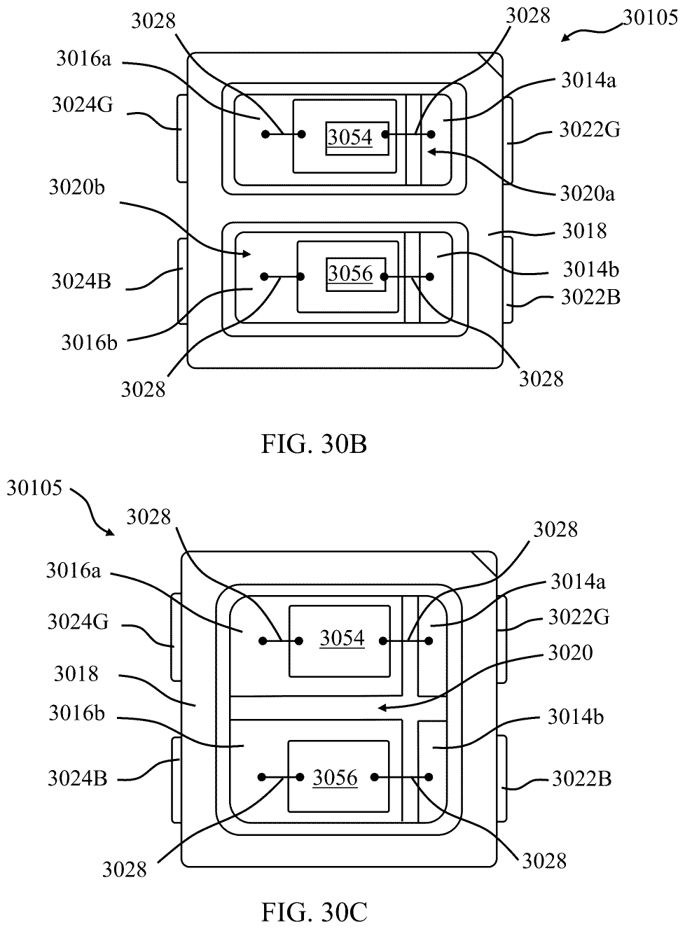

FIG. 29 shows a schematic top view of a first Two-LED packaged device 29104 comprising a PC (Phosphor Converted) White LED 2959 and a PC (Phosphor Converted) Red LED 2952. FIGS. 30A to 30C are schematic representations of second Two-LED packaged devices 30105 in which FIG. 30A shows a top view of second Dual-Cavity Two-LED packaged device 30105 comprising a PC (Phosphor Converted) Green LED 3054 and a Direct Emitting Blue LED 3056, FIG. 30B shows a top view of a second Dual-Cavity Two-LED packaged device 30105 comprising a Direct Emitting Green LED 3054 and a Direct Emitting Blue LED 3056, and FIG. 30C shows a top view of a second Single-Cavity Two-LED packaged device 30105 comprising a Direct Emitting Green LED 3054 and a Direct Emitting Blue LED 3056.

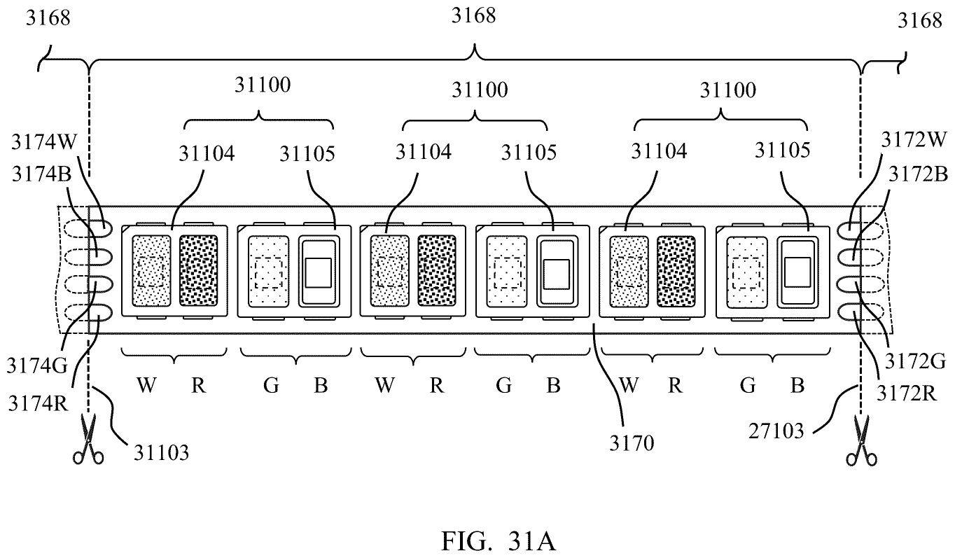

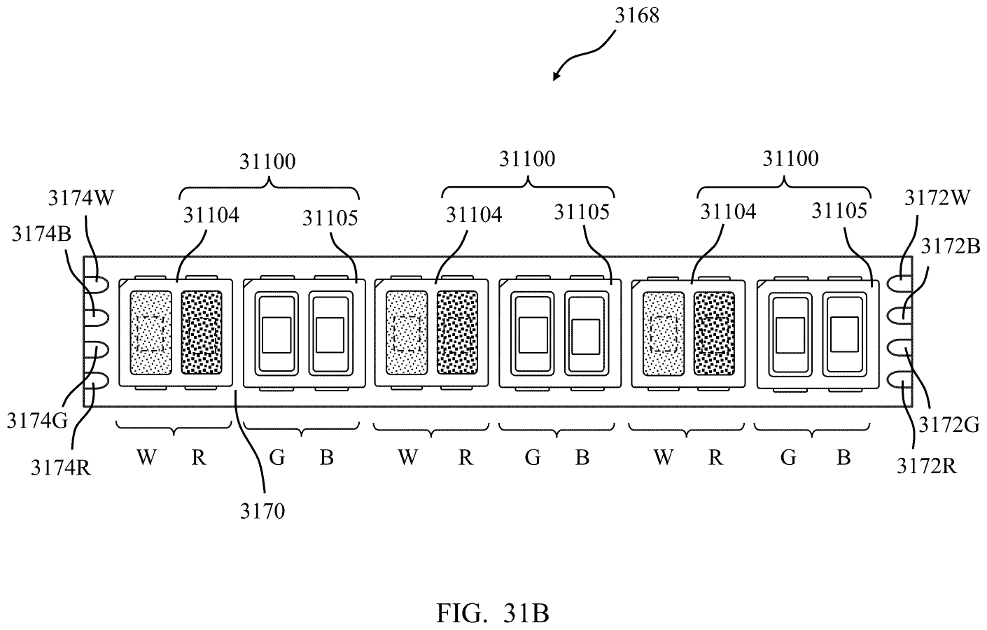

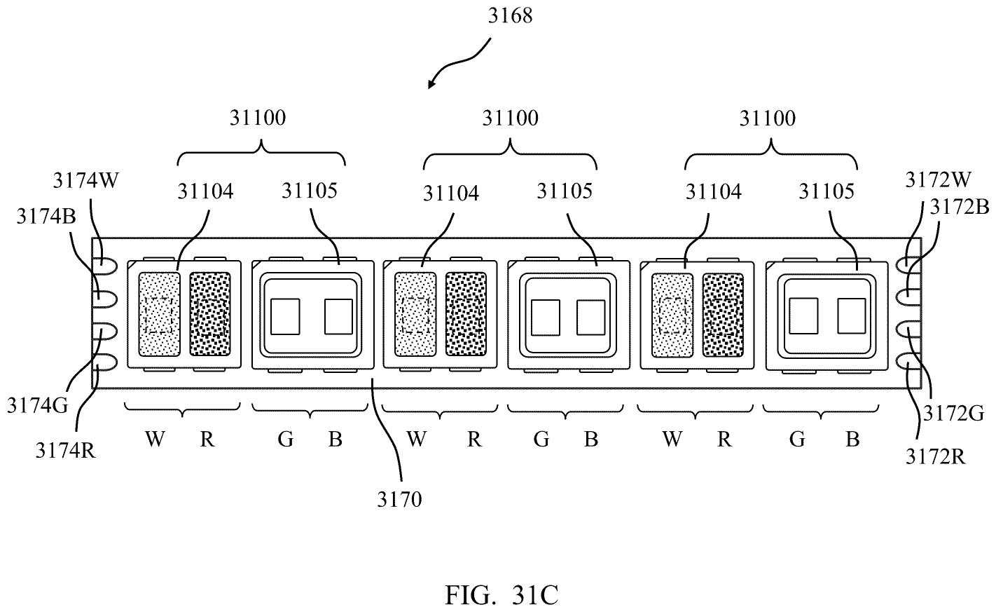

FIG. 31A to 31C are schematic representations of color-tunable linear lighting devices 3168 in accordance with an embodiment of the invention comprising a plurality of color-tunable Multi-LED lighting devices 31100 each comprising a combination of first and second Two-LED packaged devices. FIGS. 31A shows a top view of a color-tunable linear lighting device 3168 comprising a color-tunable Multi-LED lighting device 31100 composed of the Dual-Cavity Two-LED packaged devices of FIGS. 29 and 30A, FIG. 31B shows a top view of a color-tunable linear lighting device 3168 comprising a color-tunable Multi-LED lighting device 31100 composed of the Dual-Cavity Two-LED packaged devices of FIGS. 29 and FIG. 30B, and FIG. 31C shows a top view of a color-tunable linear lighting device 3168 comprising a color-tunable Multi-LED lighting device 31100 composed of the Dual-Cavity Two-LED packaged devices of FIGS. 29 and 30C.

As shown in FIG. 31A a color-tunable linear lighting devices 3168 may comprise a linear (elongate) substrate 3170, such as for example a tape (strip) of flexible circuit board, and a plurality of first Two-LED packaged devices 31104 and second Two-LED packaged devices 31105 mounted on and electrically connected to the substrate 3170. The first and second Two-LED packaged devices 31104 and 31105 can be arranged as pairs as a linear array in a direction of elongation of the substrate with each LED of a given color being electrically connected in series. As illustrated, each color-tunable linear lighting device 3168 may comprise three pairs of first and second Two-LED packaged devices 31104 and 31105, which when the LEDs of a given color are connected in series gives a nominal forward drive voltage of 9 V. As indicated in FIG. 31A, the tape (flexible substrate) 3170 may comprise a plurality of color-tunable linear lighting device 3168 disposed along the length of the tape that can be divided into individual lighting devices by cutting the along cut lines 31103 (dashed line) that passes through the anode electrical connectors 3172R, 3172G, 3172B, and 3172W and cathode electrical connectors 3174R, 3174G, 3174B, and 3174W at distal ends of the substrate (FIG. 31A). FIGS. 31B and 31C are similar to FIG. 31A, and disclose color-tunable linear lighting devices 3168—except that the color-tunable linear lighting devices 3168 of FIG. 31B comprise a color-tunable Multi-LED lighting device 31100 composed of the Dual-Cavity Two-LED packaged devices of FIG. 29 and FIG. 30B, and the color-tunable linear lighting devices 3168 of FIG. 31C comprise a color-tunable Multi-LED lighting device 31100 composed of the Dual-Cavity Two-LED packaged devices of FIGS. 29 and 30C.

While in the illustrated embodiments the Red, Green, Blue, and White LEDs are shown as being singular it is contemplated that LED of each color may comprise multiple LED chips or multiple junction chips.

As described, compared with a color-tunable Multi-LED lighting device comprising a single Four-LED packaged device comprising Red, Green, Blue, and White (RGBW) LEDs, color-tunable Multi-LED lighting devices comprising two Two-LED packaged devices comprising RGBW LEDs can provide a number of benefits including providing greater reliability as well as improved thermal management.

To independently provide power to the RGBW LEDs, Four-LED packages can comprise between 6 (e.g., 2 cathode and 4 anode—FIGS. 20A-20D) and 8 electrical terminals (4 cathode and 4 anode—FIGS. 21 and 22). In comparison, Two-LED packages require only 4 electrical terminals (2 cathode and 2 anode—FIGS. 23A and 23B) and are physically smaller for a given chip (cavity) size. Due to the physically smaller size of Two-LED packages as well as fewer electrical terminals, this can improve the integrity and reliability of the electrical connection of the device to a circuit board, especially a flexible circuit board where flexing of the board may compromise the integrity of the bond/electrical connection.

As is now described, the choice of LED colors in the first and second Two-LED packages can be used to improve the thermal characteristics of the color tunable Multi-LED lighting device. For example, TABLE 12A tabulates Power for Red, Green, Blue, White LEDs, and Total (RGBW) for generating light of a nominal CRI Ra 90 for nominal CCTs from 2700K to 6500K. TABLE 12B tabulates power for Device 1 (1^{st} Package R+G, 2^{nd} Package B+W, and Total RGBW), and Device 2 (1^{st} Package W+R, 2^{nd} Package G+B, and Total RGBW) for generating light of nominal CRI Ra 90 for nominal CCTs from 2700K to 6500K. In TABLE 12B, the percentage values in parentheses represent the percentage of the total power (RGBW) for each of the first (1^{st}) and second (2^{nd}) Packages. Device 1 is represented in FIG. 24 while Device 2 is represented in FIG. 28. It can be seen from TABLE 12B and FIG. 24 that Device 1 comprises a color tunable Multi-LED lighting device 24100 having a combination of a first Two-LED packaged device 24101 comprising Red and Green LEDs 2452, 2454 and a second Two-LED packaged device 24102 comprising Blue and White LEDs 2456, 2459. Moreover, it can be seen from TABLE 12B and FIG. 28 that Device 2 comprises a color tunable Multi-LED lighting device 28100 having a combination of a first Two-LED packaged device 28104 comprising White and Red LEDs 2859, 2852 and a second Two-LED packaged device 28105 comprising Green and Blue LEDs 2854, 2856.

TABLE 12A
Power for PC Red LED (Red), PC Green LED (Green), Blue LED
(Blue), White LED (White), and Total (RGBW) for generating light
of nominal CRI Ra 90 for nominal CCTs from 2700K to 6500K
V_{F} ≈ 18 V

| CCT | LED Power (mW) | | | | |
|---|---|---|---|---|---|
| (K) | Red (R) | Green (G) | Blue (B) | White (W) | Total (RGBW) |
| 2700 | 225 | 50 | 3 | 256 | 534 |
| 3000 | 200 | 67 | 13 | 256 | 536 |
| 3500 | 160 | 79 | 23 | 238 | 500 |
| 4000 | 142 | 94 | 35 | 209 | 480 |
| 5000 | 126 | 122 | 59 | 173 | 480 |
| 5700 | 110 | 135 | 72 | 162 | 479 |
| 6500 | 108 | 146 | 86 | 139 | 479 |

TABLE 12B
Power for Device 1 (1^{st} Package R + G, 2^{nd} Package B + W, and Total RGBW), and
Device 2 (1^{st} Package W + R, 2^{nd} Package G + B, and Total RGBW) for generating light
of nominal CRI Ra 90 for nominal CCTs from 2700K to 6500K

| | LED Power (mW) | | | | | |
|---|---|---|---|---|---|---|
| | Device 1 | | | Device 2 | | |
| CCT | 1^{st} Package | 2^{nd} Package | Total | 1^{st} Package | 2^{nd} Package | Total |
| (K) | R + G | B + W | RGBW | W + R | G + B | RGBW |
| 2700 | 275 (51%) | 259 (49%) | 534 | 481 (90%) | 53 (10%) | 534 |
| 3000 | 267 (50%) | 269 (50%) | 536 | 456 (85%) | 80 (15%) | 536 |
| 3500 | 239 (48%) | 261 (52%) | 500 | 398 (80%) | 102 (20%) | 500 |
| 4000 | 236 (49%) | 244 (51%) | 480 | 351 (73%) | 129 (27%) | 480 |
| 5000 | 248 (52%) | 232 (48%) | 480 | 299 (62%) | 181 (38%) | 480 |
| 5700 | 245 (51%) | 234 (49%) | 479 | 272 (57%) | 207 (43%) | 479 |
| 6500 | 254 (53%) | 225 (47%) | 479 | 247 (52%) | 232 (48%) | 479 |

V_{F}≈18 V

Comparing Devices 1 and 2 of TABLE 12B, for instance, the thermal characteristics of Device 1 are found to be superior to those of Device 2 due to the color choice of LEDs in the first and second LED packages. For instance, the power applied to (received by) the 1^{st} and 2^{nd} packages of Device 1 is balanced, that is the total device power RGBW for each color temperature over the full range of CCTs from 2700K to 6500K is shared substantially equally between the 1^{st} and 2^{nd} LED packages. As can be seen from the table, each package has about 50% of the total power for each color temperature (Percentage of total power RGBW of 1^{st} LED package is 48% to 53%, and percentage of total power RGBW of 2^{nd} LED package is 52% to 47%). Since each of the LED packages has to be able to dissipate heat of about the same amount (up to 275 mW), the same packages can be used for the 1^{st} and 2^{nd} LED packages. The same package may be in terms of the size of lead frame, for instance. That is the 1^{st} and 2^{nd} LED packages having the same size lead frame may be utilized in the manufacture of the light emitting device and/or lighting arrangement. This is advantageous in that it significantly reduces complexity of manufacturing, thereby reducing overall manufacturing costs, material costs, and assembly time and costs of the light emitting device and/or lighting arrangement.

In comparison, the power for the first and second packages of Device 2 are unbalanced, that is the total device power RGBW for each color temperature over the full range of CCTs from 2700K to 6500K is shared unequally/unevenly between the 1^{st} and 2^{nd} LED packages. As can be seen from TABLE 12B for Device 2, the 1^{st} LED package receives between 90% and 52% of the total device power RGBW for CCTs from 2700K to 6500K, while the 2^{nd} LED package receives between 10% and 48% of the total device power RGBW for CCTs from 2700K to 6500K. The imbalance of power between the 1^{st} and 2^{nd} LED packages would require LED packages of different sizes to handle the different power requirements. For example, the 1^{st} package would need to be able to dissipate heat generated by powers up to 481 mW, whereas the 2^{nd} package would need to be able to dissipate of powers up to only 232 mW. It is, therefore, desirable that the light emitting device and/or lighting arrangement be such that the 1^{st} and 2^{nd} packages are required to dissipate the same/substantially similar amount of energy (heat), dictated by the power for instance, thereby allowing the use of a smaller package (per Device 1). The same (smaller) package may be in terms of a smaller size of lead frame, for instance. That is packages that have the same smaller size in lead frame may be utilized in the manufacture of the light emitting device and/or lighting arrangement. This is advantageous in that it significantly reduces complexity of manufacturing, thereby reducing overall manufacturing costs, material costs, and assembly time and costs of the light emitting device and/or lighting arrangement.

The inventors have identified, therefore, that the provision of a light emitting device and/or lighting arrangement in which the 1^{st} package comprises a Red and Green LED, and in which the 2^{nd} package comprises a Blue and White LED exhibits benefits by way of enhanced thermal management, reduced manufacturing costs due to the sufficiency of substantially equally sized 1^{st} and 2^{nd} smaller LED packages/lead frames to provide the desired performance.

TABLE 13A
Power for PC Red LED (Red), PC Green LED (Green), Blue LED
(Blue), White LED (White), and Total (RGBW) for generating light
of nominal CRI Ra 95 for nominal CCTs from 1800K to 6500K
V_{F} ≈ 3 V

| CCT | LED Power (mW) | | | | |
|---|---|---|---|---|---|
| (K) | Red (R) | Green (G) | Blue (B) | White (W) | Total (RGBW) |
| 1800 | 248 | 13 | 0 | 190 | 451 |
| 2200 | 188 | 29 | 1 | 232 | 450 |
| 2700 | 137 | 50 | 11 | 253 | 451 |
| 3000 | 112 | 63 | 18 | 257 | 450 |
| 3500 | 89 | 77 | 27 | 256 | 449 |
| 4000 | 70 | 93 | 39 | 248 | 450 |
| 5000 | 49 | 116 | 59 | 225 | 449 |
| 5700 | 38 | 122 | 71 | 219 | 450 |
| 6500 | 29 | 133 | 83 | 205 | 450 |

TABLE 13B
Power for Device 1 (1^{st} Package R + G, 2^{nd} Package B + W, and Total RGBW), and
Device 2 (1^{st} Package W + R, 2^{nd} Package G + B, and Total RGBW) for generating
light of nominal CRI Ra 95 for nominal CCTs from 1800K to 6500K

| | LED Power (mW) | | | | | |
|---|---|---|---|---|---|---|
| | Device 1 | | | Device 2 | | |
| CCT | 1^{st} Package | 2^{nd} Package | Total | 1^{st} Package | 2^{nd} Package | Total |
| (K) | R + G | B + W | RGBW | W + R | G + B | RGBW |
| 1800 | 261 (58%) | 190 (42%) | 451 | 438 (97%) | 13 (3%) | 451 |
| 2200 | 217 (48%) | 233 (52%) | 450 | 420 (93%) | 30 (7%) | 450 |
| 2700 | 187 (41%) | 264 (59%) | 451 | 390 (86%) | 61 (14%) | 451 |
| 3000 | 175 (39%) | 275 (61%) | 450 | 369 (82%) | 81 (18%) | 450 |
| 3500 | 166 (37%) | 283 (63%) | 449 | 345 (77%) | 104 (23%) | 449 |
| 4000 | 163 (36%) | 287 (64%) | 450 | 318 (71%) | 132 (29%) | 450 |
| 5000 | 165 (37%) | 284 (63%) | 449 | 274 (61%) | 175 (39%) | 449 |
| 5700 | 160 (36%) | 290 (64%) | 450 | 257 (57%) | 193 (43%) | 450 |
| 6500 | 162 (36%) | 288 (64%) | 450 | 234 (52%) | 216 (48%) | 450 |

V_{F}≈3 V

The same trend is demonstrated in TABLE 13A (as that described in relation to TABLE 12A) and TABLE 13B (as that described in relation to TABLE 12B). TABLE 13A tabulates Power for Red, Green, Blue, White LEDs, and Total (RGBW) for generating light of a nominal CRI Ra 95 for nominal CCTs from 1800K to 6500K. TABLE 13B tabulates power for Device 1 (1^{st} Package R+G, 2^{nd} Package B+W, and Total RGBW), and Device 2 (1^{st} Package W+R, 2^{nd} Package G+B, and Total RGBW) for generating light of nominal CRI Ra 95 for nominal CCTs from 1800K to 6500K. In TABLE 13B, the percentage values in parentheses represent the percentage of the total power (RGBW) for each of the first (1^{st}) and second (2^{nd}) Packages.

Comparing Devices 1 and 2 of TABLE 13B, for instance, the thermal characteristics of Device 1 are found to be superior to those of Device 2 due to the color choice of LEDs in the 1^{st} and 2^{nd} LED packages. For instance, the power applied to (received by) the 1^{st} and 2^{nd} packages of Device 1 is balanced, that is the total device power RGBW for each color temperature over the full range of CCTs from 1800K to 6500K is shared substantially equally between the 1^{st} and 2^{nd} LED packages. As can be seen from the table, each package has between 40% and 60% of the total power for each color temperature (Percentage of total power RGBW of 1^{st} LED package is 36% to 58%, and percentage of total power RGBW of 2^{nd} LED package is 42% to 64%). Since each of the LED packages has to be able to dissipate heat of about the same amount (up to 261 mW), the same packages can be used for the 1^{st} and 2^{nd} LED packages. The same package may be in terms of the size of lead frame, for instance. That is the 1^{st} and 2^{nd} LED packages having the same size lead frame may be utilized in the manufacture of the light emitting device and/or lighting arrangement. This is advantageous in that it significantly reduces complexity of manufacturing, thereby reducing overall manufacturing costs, material costs, and assembly time and costs of the light emitting device and/or lighting arrangement.

In comparison, the power for the first and second packages of Device 2 are unbalanced, that is the total device power RGBW for each color temperature over the full range of CCTs from 1800K to 6500K is shared unequally/unevenly between the 1^{st} and 2^{nd} LED packages. As can be seen from TABLE 13B for Device 2, the 1^{st} LED package receives between 97% and 52% of the total device power RGBW for CCTs from 1800K to 6500K, while the 2^{nd} LED package receives between 3% and 48% of the total device power RGBW for CCTs from 1800K to 6500K. The imbalance of power between the 1^{st} and 2^{nd} LED packages would require LED packages of different sizes to handle the different power requirements. For example, the 1^{st} package would need to be able to dissipate heat generated by powers up to 438 mW, whereas the 2^{nd} package would need to be able to dissipate of powers up to only 216 mW. It is, therefore, desirable that the light emitting device and/or lighting arrangement be such that the 1^{st} and 2^{nd} packages are required to dissipate the same/substantially similar amount of energy (heat), dictated by the power for instance, by the provision of a light emitting device having the same packages in the 1^{st} and 2^{nd} LED packages, for example. The same (smaller) package may be in terms of a smaller size of lead frame, for instance. That is packages that have the same smaller size in lead frame may be utilized in the manufacture of the light emitting device and/or lighting arrangement. This is advantageous in that it significantly reduces complexity of manufacturing, thereby reducing overall manufacturing costs, material costs, and assembly time and costs of the light emitting device and/or lighting arrangement.

The inventors have identified, therefore, that the provision of a light emitting device and/or lighting arrangement in which the 1^{st} package comprises a Red and Green LED, and in which the 2^{nd} package comprises a Blue and White LED exhibits benefits by way of enhanced thermal management, reduced manufacturing costs due to the sufficiency of substantially equally sized 1^{st} and 2^{nd} smaller LED packages/lead frames to provide the desired performance.

Now described are further benefits of the color-tunable linear light emitting device, as defined herein, is the provision of a lighting arrangement comprising, for instance, a linear (elongate) substrate, such as for example a tape (strip) of flexible circuit board, and a plurality of Multi-Package Color tunable Multi-LED lighting devices (light emitting devices) each comprising first and second Two-LED packaged devices mounted on and electrically connected to the substrate. The first and second Two-LED packaged devices can be arranged as pairs as a linear array in a direction of elongation of the substrate with each LED of a given color being electrically connected in series. Since the first Two-LED packaged devices and second Two-LED packaged devices have, for instance, only four terminals (respective four anode and cathode terminals), this provides superior connection of the packages with the substrate compared with a Four-LED packaged device which has eight terminals and is larger in size and the connectivity of the package is more likely prone to failure. The robustness and integrity of the connection can be maintained to a far greater extent with such a color-tunable linear light emitting device comprising the linear flexible substrate, and a plurality of first Two-LED packaged devices and second Two-LED packaged devices mounted on the substrate, compared with a larger packaged device having more points of connection (eight terminals, for instance) over a larger area.

### LIST OF REFERENCE NUMERALS

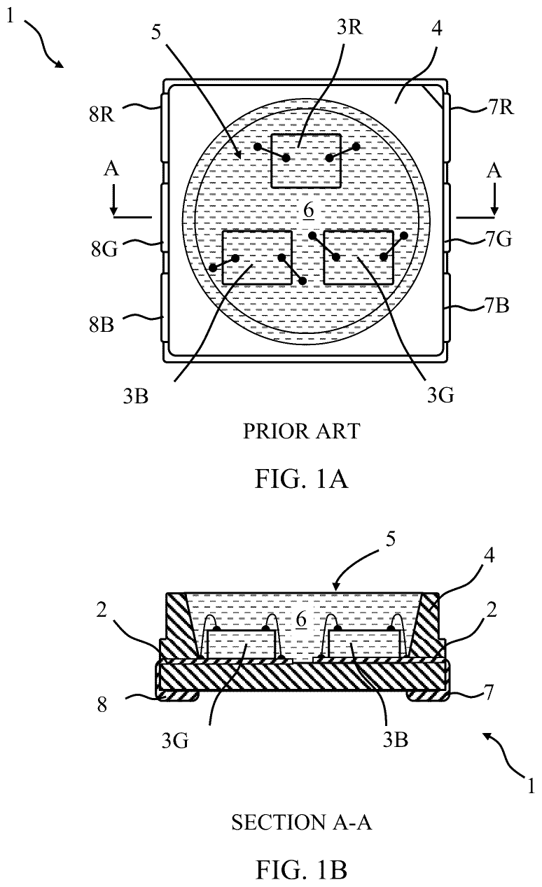

FIG. 1:
1 Multi-LED package
2 Lead frame
3 Direct-Emitting LED chip
3R Direct-Emitting Red LED chip
3G Direct-Emitting Green LED chip
3B Direct-Emitting Blue LED chip
4 Housing
5 Cavity, cup, recess
6 Light-transmissive encapsulant
7 Anode electrical terminal
7R Anode electrical terminal Red LED
7G Anode electrical terminal Green LED
7B Anode electrical terminal Blue LED
8 Cathode electrical terminal
8R Cathode electrical terminal Red LED
8G Cathode electrical terminal Green LED
8B Cathode electrical terminal Blue LED
FIGS. 2 to 22 (#=Figure Number)
#10 Red-light emitting device
#12 Package
#14 Anode lead frame
#14a Anode lead frame—first cavity
#14b Anode lead frame—second cavity
#14c Anode lead frame—third cavity
#14d Anode lead frame—fourth cavity
#14e Common cathode lead frame—cavities 1-4
#16 Cathode lead frame
#16a-d Cathode lead frame—common to cavities 1-4
#16a Cathode lead frame—first cavity
#16b Cathode lead frame—second cavity
#16c Cathode lead frame—third cavity
#16d Cathode lead frame—fourth cavity
#18 Housing
#18A Housing base portion
#18B Housing side wall portion
#20 Cavity, cup, recess
#20a First cavity (First recess)
#20b Second cavity (Second recess)
#20c Third cavity (Third Recess)
#20d Fourth cavity (Fourth Recess)
#22 Anode electrical terminal
#22a Anode electrical terminal first cavity
#22b Anode electrical terminal second cavity
#22c Anode electrical terminal third cavity
#22d Anode electrical terminal fourth cavity
#24 Cathode electrical terminal
#24a Cathode electrical terminal first cavity
#24b Cathode electrical terminal second cavity
#24c Cathode electrical terminal third cavity
#24d Cathode electrical terminal fourth cavity
#26 Violet to blue LED chip
#28 Bond wire
#30 Red photoluminescence layer
#30A First red photoluminescence layer
#30B Second red photoluminescence layer
#32 Light reflective layer
#34 Chromaticity (color point)
#36 White standard illuminant CIE (1/3, 1/3)
#38 Line
#40 Dominant wavelength λ_{d}
#42 Complimentary wavelength λ_{c}
#44 Blue peak—Com 2—Single-Layer PC Red LED (KSF only)
#45 Red peak—Com 2—Single-Layer PC Red LED (KSF only)
#46 Blue peak—Dev.1—Single-Layer PC Red LED
#47 Red peak—Dev.1—Single-Layer PC Red LED
#48 Blue peak—Dev.2—Double-Layer PC Red LED
#49 Red peak—Dev.2—Double-Layer PC Red LED
#50 Color-tunable multi-LED packaged light emitting device
#52 Red LED
#54 Green LED
#56 Blue LED
#57 Chromaticity (color point)
#57R Chromaticity (color point)—Red LED
#57G Chromaticity (color point)—Green LED
#57B Chromaticity (color point)—Red LED
#57W Chromaticity (color point)—White LED
#57CW Chromaticity (color point)—Cool White (CW) LED
#57WW Chromaticity (color point)—Warm White (WW) LED
#58 Straight line connecting chromaticity (color points)
#59 White LED
#60 Green photoluminescence layer
#62 Green to Red photoluminescence layer
#64 CW (Cool White) LED
#66a First LED
#66b Second LED
#66c Third LED
#66d Fourth LED
#68 Color-tunable linear light emitting device
#70 Substrate (circuit board)
#72 Anode electrical connector
#74 Cathode electrical connector
#76 Chromaticity (color point)—Red PC LED (Pack.1)
#78 Chromaticity (color point)—Green PC LED (Pack.1)
#80 Chromaticity (color point)—Blue LED (Pack.1)

1#82 Chromaticity (color point)—White LED (Pack.1)
#84 Straight line connecting chromaticity (color points)
#86 Chromaticity (color point) of lowest CCT
#88 Arrow—Blue region of spectrum
#90 Arrow—Green region of spectrum
#92 Arrow—Red region of spectrum
#94 Light emission locus
#96 Chromaticity (color point) of highest CCT
#100 Multi-Package Color tunable Multi-LED lighting device
#101 Red and Green LED Package
#102 Blue and White LED Package
#103 Cut line
#104 Red and White LED Package
#105 Blue and Green LED Package

1. A light emitting device comprising:
at least one first LED for generating red light;
at least one second LED for generating green light;
at least one third LED for generating blue light;
at least one fourth LED for generating light of a CCT in a range from 1800K to 5000K; and
a first package and a second package that in combination comprise the at least one first LED, the at least one second LED, the at least one third LED, and the at least one fourth LED, and
wherein the at least one first LED comprises a phosphor-converted LED comprising a narrowband red phosphor with a FWHM less than 55 nm.

2. The device of claim 1, wherein the first package comprises the at least one first and second LEDs, and the second package comprises the at least one third and fourth LEDs.

3. The device of claim 1, wherein the first package comprises the at least one first and fourth LEDs, and the second package comprises the at least one second and third LEDs.

4. The device of claim 1, wherein at least one of the first and second packages comprise:
two cups for receiving a respective color LED; or
one cup for receiving at least two color LEDs.

5. The device of claim 1, wherein the at least one second LED comprises a phosphor-converted LED comprising a green phosphor.

6. The device of claim 1, wherein the narrowband red phosphor is selected from the group consisting of: K₂SiF₆:Mn⁴⁺, K₂GeF₆:Mn⁴⁺, and K₂TiF₆: Mn⁴⁺.

7. The device of claim 6, wherein the at least one first LED further comprises a broadband red phosphor.

8. The device of claim 7, wherein the narrowband red phosphor and the broadband red phosphor are constituted in a single layer, or wherein the narrowband red phosphor and the broadband red phosphor are constituted in a respective layer.

9. The device of claim 1, wherein the at least one first LED is for generating light with a color purity of least 90%.

10. The device of claim 1, wherein at least one of the at least one first LED, the at least one second LED, the at least one third LED, or the at least one fourth LED comprises an LED flip chip.

11. A lighting arrangement comprising:
a substrate and a plurality of light emitting devices,
wherein each of the plurality of light emitting devices comprises:
at least one first LED for generating red light;
at least one second LED for generating green light;
at least one third LED for generating blue light;
at least one fourth LED for generating light of a CCT in a range from 1800K to 5000K; and
a first package and a second package that in combination comprise the at least one first LED, the at least one second LED, the at least one third LED, and the at least one fourth LED, and
wherein the at least one first LED comprises a phosphor-converted LED comprising a narrowband red phosphor with a FWHM less than 55 nm.

12. The lighting arrangement of claim 11, wherein the circuit board comprises a flexible circuit board.

13. The lighting arrangement of claim 11, wherein the first package comprises the at least one first and second LEDs, and the second package comprises the at least one third and fourth LEDs.

14. The lighting arrangement of claim 11, wherein the first package comprises the at least one first and fourth LEDs, and the second package comprises the at least one second and third LEDs.

15. The lighting arrangement of claim 11, wherein at least one of the first and second packages comprise:
two cups for receiving a respective color LED; or
one cup for receiving at least two color LEDs.

16. The lighting arrangement of claim 11, wherein the at least one second LED comprises a phosphor-converted LED comprising a green phosphor.

17. The lighting arrangement of claim 11, wherein the narrowband red phosphor is selected from the group consisting of: K₂SiF₆:Mn⁴⁺, K₂GeF₆:Mn⁴⁺, and K₂TiF₆: Mn⁴⁺.

18. The lighting arrangement of claim 11, wherein the at least one first LED further comprises a broadband red phosphor.

19. The lighting arrangement of claim 18, wherein the narrowband red phosphor and the broadband red phosphor are constituted in a single layer, or wherein the narrowband red phosphor and the broadband red phosphor are constituted in a respective layer.

20. The lighting arrangement of claim 11, wherein the at least one first LED is for generating light with a color purity of least 90%.
